(19) United States
(12) Patent Application Publication
(10) Pub. No.: US 2023/0016098 A1
(43) Pub. Date: Jan. 19, 2023

(54) FIELD REPLACEABLE FAN ASSEMBLIES FOR PERIPHERAL PROCESSING UNITS AND RELATED SYSTEMS AND METHODS

(71) Applicant: Intel Corporation, Santa Clara, CA (US)

(72) Inventors: Navneeth Jayaraj, Bengaluru (IN); Prabhakar Subrahmanyam, San Jose, CA (US); Nagaraj K, Bangalore (IN); Gopinath K, Bangalore (IN); Paniraj Gururaja, Bangalore (IN); Mahammad Yaseen Mulla, Bangalore (IN); Nitesh Gupta, Bangalore (IN); Ying-Feng Pang, San Jose, CA (US)

(21) Appl. No.: 17/957,698

(22) Filed: Sep. 30, 2022

(51) Int. Cl. G06F 1/20; H05K 7/20

(52) U.S. Cl. CPC G06F 1/206; H05K 7/20209; H05K 7/2039; G06F 1/20

(57) ABSTRACT

Example field replaceable fan assemblies for peripheral processing units and related systems and methods are disclosed. An example apparatus includes a temperature sensor; a fan having a base; at least one memory; machine readable instructions; and processor circuitry to execute operations corresponding to the machine readable instructions to determine a first temperature based on an output of the temperature sensor; and cause the base of the fan to move based on the first temperature.

### FIELD OF THE DISCLOSURE

This disclosure relates generally to peripheral processing units and, more particularly, to field replaceable fan assemblies for peripheral processing units and related systems and methods.

### BACKGROUND

Peripheral processing units such as infrastructure processing units (IPUs) or graphics cards including graphic processing units generate heat during operation. A peripheral processing unit can include a heat sink to absorb the heat and facilitate dissipation of the heat to regulate the temperature of the hardware. Some peripheral processing units include fans to increase airflow at the heat sink and, thus, the dissipation of the heat.

### BRIEF DESCRIPTION OF THE DRAWINGS

FIG. 1 illustrates one or more example environments in which teachings of this disclosure may be implemented.

FIG. 2 illustrates at least one example of a data center for executing workloads with disaggregated resources.

FIG. 3 illustrates at least one example of a pod that may be included in the data center of FIG. 2.

FIG. 4 is a perspective view of at least one example of a rack that may be included in the pod of FIG. 3.

FIG. 5 is a side elevation view of the rack of FIG. 4.

FIG. 6 is a perspective view of the rack of FIG. 4 having a sled mounted therein.

FIG. 7 is a is a block diagram of at least one example of a top side of the sled of FIG. 6.

FIG. 8 is a block diagram of at least one example of a bottom side of the sled of FIG. 7.

FIG. 9 is a block diagram of at least one example of a compute sled usable in the data center of FIG. 2.

FIG. 10 is a top perspective view of at least one example of the compute sled of FIG. 9.

FIG. 11 is a block diagram of at least one example of an accelerator sled usable in the data center of FIG. 2.

FIG. 12 is a top perspective view of at least one example of the accelerator sled of FIG. 10.

FIG. 13 is a block diagram of at least one example of a storage sled usable in the data center of FIG. 2.

FIG. 14 is a top perspective view of at least one example of the storage sled of FIG. 13.

FIG. 15 is a block diagram of at least one example of a memory sled usable in the data center of FIG. 2.

FIG. 16A is a block diagram of a system that may be established within the data center of FIG. 2 to execute workloads with managed nodes composed of disaggregated resources.

FIG. 16B is a block diagram of an example infrastructure processing unit

FIG. 16C is a block diagram an example graphics processing unit accelerator.

FIG. 17 illustrates an example peripheral including an example fan assembly in accordance with teachings of this disclosure.

FIGS. 18 and 19 illustrate the example fan assembly of FIG. 17.

FIG. 20 is a top view of the example peripheral of FIG. 17 including the example fan assembly of FIGS. 17-19, where the fan of the fan assembly is in a first location.

FIG. 21 is a top view of the example peripheral of FIG. 17 including the example fan assembly of FIGS. 17-19, where the fan of the fan assembly is in a second location.

FIG. 22 illustrates a peripheral including another example fan assembly in accordance with teachings of this disclosure.

FIG. 23 illustrates a peripheral including another example fan assembly in accordance with teachings of this disclosure.

FIG. 24 is a block diagram of example fan control circuitry.

FIG. 25 is a flowchart representative of example machine readable instructions and/or example operations that may be executed by example processor circuitry to implement the fan control circuitry of FIG. 24.

FIG. 26 is a block diagram of an example processing platform including processor circuitry structured to execute the example machine readable instructions and/or the example operations of FIG. 25 to implement the fan control circuitry of FIG. 24.

FIG. 27 is a block diagram of an example implementation of the processor circuitry of FIG. 26.

FIG. 28 is a block diagram of another example implementation of the processor circuitry of FIG. 26.

FIG. 29 is a block diagram of an example software distribution platform (e.g., one or more servers) to distribute software (e.g., software corresponding to the example machine readable instructions of FIG. 25) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

### DETAILED DESCRIPTION

A peripheral processing unit such as an infrastructure processing units (IPUs), processor circuitry, graphics cards including one or more graphic processing units (GPUs), and/or other types of peripherals such as peripheral component interconnect express (PCIe) cards generate heat during operation. The PCIe card can include a heat sink to absorb heat and facilitate dissipation of the heat to regulate the temperature of the electronic components of the PCIe card (e.g., processor circuitry such as an FPGA, a microprocessor, a controller, etc.). Some PCIe cards include fans to increase airflow at the heat sink and, thus, the dissipation of the heat. Some PCIe cards are disposed in a server chassis that includes fans.

Cooling at a known PCIe card is typically affected by the fan speed and the number of fans in the card. Also, the fan(s) of known PCIe cards are typically fixed with respect to location in the PCIe card (e.g., fixed on the heat sink). Thus, the fan(s) can provide for increased cooling at the location(s) where the fan(s) are located. However, power consumption and, thus, the amount of heat generated by the electronic components of the PCIe card can vary during operation of the PCIe card based on, for instance, a work load that is offloaded or accelerated on, for example, an IPU, a GPU, etc. In particular, during operation of the PCIe card, certain areas of the PCIe card may be associated with increased temperature relative to other areas of the PCIe card based on performance of the electronic components at those areas. Such areas of increased temperature are referred to herein as “hot spots.” If a fixed fan of the PCIe card is not proximate to the hot spot, the hot spot may not be efficiently cooled, which can affect performance of the electronic components associated with the increased thermal power. Also, if the fixed fan fails, the PCIe card is powered down to remove and replace the fan, which can substantially disrupt performance of the server including the PCIe card. Thus, the fixed fan can be a point of failure for a peripheral.

Disclosed herein are example fan assemblies that provide for increased airflow in a peripheral (e.g., a peripheral processing unit such as a PCIe card) while enabling a fan carried by the fan assembly to be removed from the peripheral (e.g., from the PCIe card) without disrupting operation of the peripheral (e.g., the PCIe card). Example fan assemblies disclosed herein include a tray that carries a fan. The tray can be removably inserted in peripheral (e.g., the PCIe card) via an opening formed in the card. As a result, the tray including the fan can be removed (e.g., for fan maintenance) without affecting or substantially affecting the operation of the other electronic components of the peripheral (e.g., the PCIe card). In other words, the fan is field replaceable or hot swappable). Some examples disclosed herein generate alerts to inform, for instance, a data center operator that a fan may need maintenance based on monitoring of fan performance (e.g., fan speed).

Some example fan assemblies disclosed herein enable the fan to translate or move (e.g., slide) relative to the tray to dynamically position the fan at two or more different locations relative to the heat sink. Examples disclosed herein monitor changes in temperature at the peripheral (e.g., the PCIe card) to detect areas of increased temperature, or hot spots, indicative of increased amounts of heat generated by certain electronic components. Examples disclosed herein cause the fan to translate (e.g., cause a base of the fan to move) to a location relative to the heat sink that is proximate to the hot spot. As a result, some examples disclosed herein provide dynamic, location-targeted augmented cooling during operation of the peripheral (e.g., the PCIe card). Some examples disclosed herein dynamically adjust operating parameters of the fan such as rotational speed and rotational direction based on the temperature of the peripheral (e.g., the PCIe card), performance of two or more fans in the peripheral (e.g., the PCIe card), etc. Thus, examples disclosed herein provide for augmented cooling of peripherals such as peripheral processing units to mitigate hot spots.

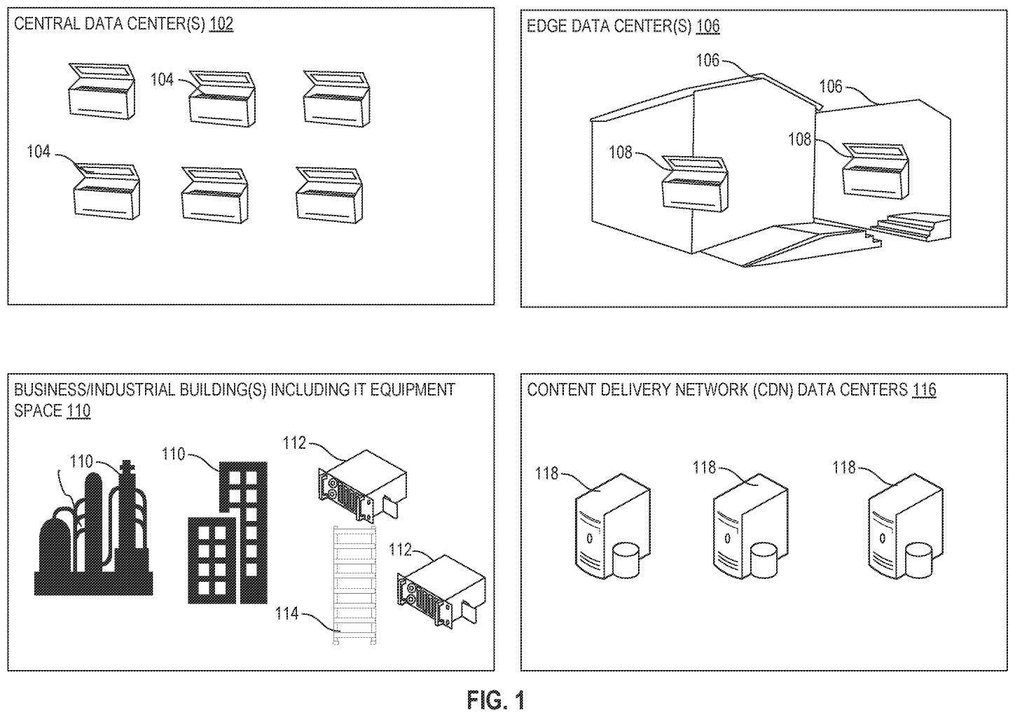

FIG. 1 illustrates one or more example environments in which teachings of this disclosure may be implemented. The example environment(s) of FIG. 1 can include one or more central data centers 102. The central data center(s) 102 can store a large number of servers used by, for instance, one or more organizations for data processing, storage, etc. As illustrated in FIG. 1, the central data center(s) 102 include a plurality of immersion tank(s) 104 to facilitate cooling of the servers and/or other electronic components stored at the central data center(s) 102. The immersion tank(s) 104 can provide for single-phase immersion cooling or two-phase immersion cooling.

The example environments of FIG. 1 can be part of an edge computing system. For instance, the example environments of FIG. 1 can include edge data centers or micro-data centers 106. The edge data center(s) 106 can include, for example, data centers located at a base of a cell tower. In some examples, the edge data center(s) 106 are located at or near a top of a cell tower and/or other utility pole. The edge data center(s) 106 include respective housings that store server(s), where the server(s) can be in communication with, for instance, the server(s) stored at the central data center(s) 102, client devices, and/or other computing devices in the edge network. Example housings of the edge data center(s) 106 may include materials that form one or more exterior surfaces that partially or fully protect contents therein, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs, AC/DC or DC/AC converter(s), power regulators, transformers, charging circuitry, batteries, wired inputs and/or wireless power inputs. As illustrated in FIG. 1, the edge data center(s) 106 can include immersion tank(s) 108 to store server(s) and/or other electronic component(s) located at the edge data center(s) 106.

The example environment(s) of FIG. 1 can include buildings 110 for purposes of business and/or industry that store information technology (IT) equipment in, for example, one or more rooms of the building(s) 110. For example, as represented in FIG. 1, server(s) 112 can be stored with server rack(s) 114 that support the server(s) 112 (e.g., in an opening of slot of the rack 114). In some examples, the server(s) 112 located at the buildings 110 include on-premise server(s) of an edge computing network, where the on-premise server(s) are in communication with remote server(s) (e.g., the server(s) at the edge data center(s) 106) and/or other computing device(s) within an edge network.

The example environment(s) of FIG. 1 include content delivery network (CDN) data center(s) 116. The CDN data center(s) 116 of this example include server(s) 118 that cache content such as images, webpages, videos, etc. accessed via user devices. The server(s) 118 of the CDN data centers 116 can be disposed in immersion cooling tank(s) such as the immersion tanks 104, 108 shown in connection with the data centers 102, 106.

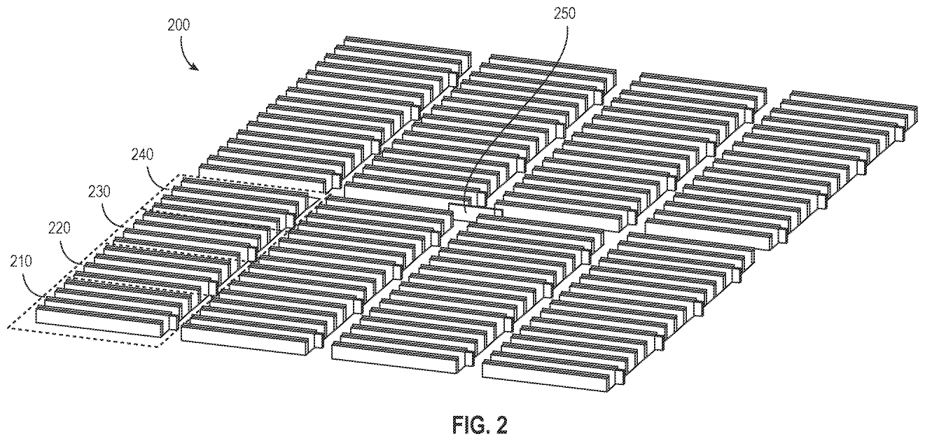

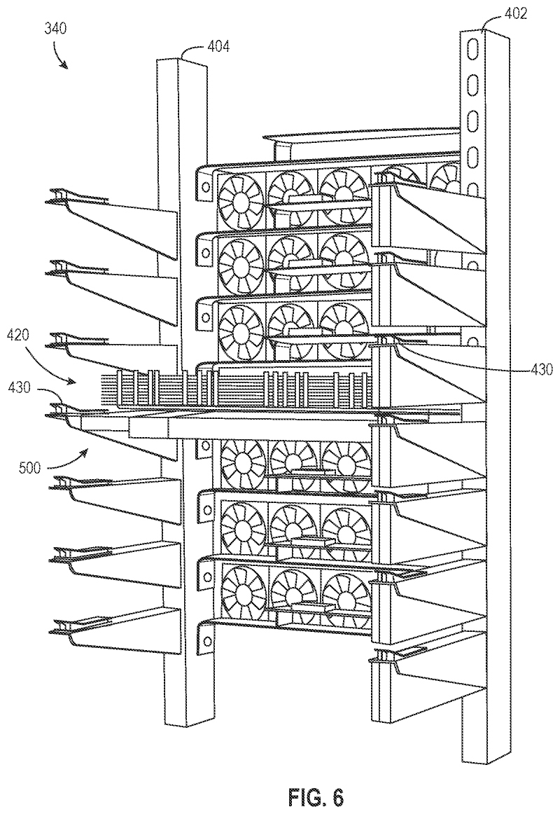

In some instances, the example data centers 102, 106, 116 and/or building(s) 110 of FIG. 1 include servers and/or other electronic components that are cooled independent of immersion tanks (e.g., the immersion tanks 104, 108) and/or an associated immersion cooling system. That is, in some examples, some or all of the servers and/or other electronic components in the data centers 102, 106, 116 and/or building(s) 110 can be cooled by air and/or liquid coolants without immersing the servers and/or other electronic components therein. Thus, in some examples, the immersion tanks 104, 108 of FIG. 1 may be omitted. Further, the example data centers 102, 106, 116 and/or building(s) 110 of FIG. 1 can correspond to, be implemented by, and/or be adaptations of the example data center 200 described in further detail below in connection with FIGS. 2-16.

Although a certain number of cooling tank(s) and other component(s) are shown in the figures, any number of such components may be present. Also, the example cooling data centers and/or other structures or environments disclosed herein are not limited to arrangements of the size that are depicted in FIG. 1. For instance, the structures containing example cooling systems and/or components thereof disclosed herein can be of a size that includes an opening to accommodate service personnel, such as the example data center(s) 106 of FIG. 1, but can also be smaller (e.g., a “doghouse” enclosure). For instance, the structures containing example cooling systems and/or components thereof disclosed herein can be sized such that access (e.g., the only access) to an interior of the structure is a port for service personnel to reach into the structure. In some examples, the structures containing example cooling systems and/or components thereof disclosed herein are be sized such that only a tool can reach into the enclosure because the structure may be supported by, for a utility pole or radio tower, or a larger structure.

FIG. 2 illustrates an example data center 200 in which disaggregated resources may cooperatively execute one or more workloads (e.g., applications on behalf of customers). The illustrated data center 200 includes multiple platforms 210, 220, 230, 240 (referred to herein as pods), each of which includes one or more rows of racks. Although the data center 200 is shown with multiple pods, in some examples, the data center 200 may be implemented as a single pod. As described in more detail herein, a rack may house multiple sleds. A sled may be primarily equipped with a particular type of resource (e.g., memory devices, data storage devices, accelerator devices, general purpose processors), i.e., resources that can be logically coupled to form a composed node. Some such nodes may act as, for example, a server. In the illustrative example, the sleds in the pods 210, 220, 230, 240 are connected to multiple pod switches (e.g., switches that route data communications to and from sleds within the pod). The pod switches, in turn, connect with spine switches 250 that switch communications among pods (e.g., the pods 210, 220, 230, 240) in the data center 200. In some examples, the sleds may be connected with a fabric using Intel Omni-Path™ technology. In other examples, the sleds may be connected with other fabrics, such as InfiniBand or Ethernet. As described in more detail herein, resources within the sleds in the data center 200 may be allocated to a group (referred to herein as a “managed node”) containing resources from one or more sleds to be collectively utilized in the execution of a workload. The workload can execute as if the resources belonging to the managed node were located on the same sled. The resources in a managed node may belong to sleds belonging to different racks, and even to different pods 210, 220, 230, 240. As such, some resources of a single sled may be allocated to one managed node while other resources of the same sled are allocated to a different managed node (e.g., first processor circuitry assigned to one managed node and second processor circuitry of the same sled assigned to a different managed node).

A data center including disaggregated resources, such as the data center 200, can be used in a wide variety of contexts, such as enterprise, government, cloud service provider, and communications service provider (e.g., Telco's), as well in a wide variety of sizes, from cloud service provider mega-data centers that consume over 200,000 sq. ft. to single- or multi-rack installations for use in base stations.

In some examples, the disaggregation of resources is accomplished by using individual sleds that include predominantly a single type of resource (e.g., compute sleds including primarily compute resources, memory sleds including primarily memory resources). The disaggregation of resources in this manner, and the selective allocation and deallocation of the disaggregated resources to form a managed node assigned to execute a workload, improves the operation and resource usage of the data center 200 relative to typical data centers. Such typical data centers include hyperconverged servers containing compute, memory, storage and perhaps additional resources in a single chassis. For example, because a given sled will contain mostly resources of a same particular type, resources of that type can be upgraded independently of other resources. Additionally, because different resource types (processors, storage, accelerators, etc.) typically have different refresh rates, greater resource utilization and reduced total cost of ownership may be achieved. For example, a data center operator can upgrade the processor circuitry throughout a facility by only swapping out the compute sleds. In such a case, accelerator and storage resources may not be contemporaneously upgraded and, rather, may be allowed to continue operating until those resources are scheduled for their own refresh. Resource utilization may also increase. For example, if managed nodes are composed based on requirements of the workloads that will be running on them, resources within a node are more likely to be fully utilized. Such utilization may allow for more managed nodes to run in a data center with a given set of resources, or for a data center expected to run a given set of workloads, to be built using fewer resources.

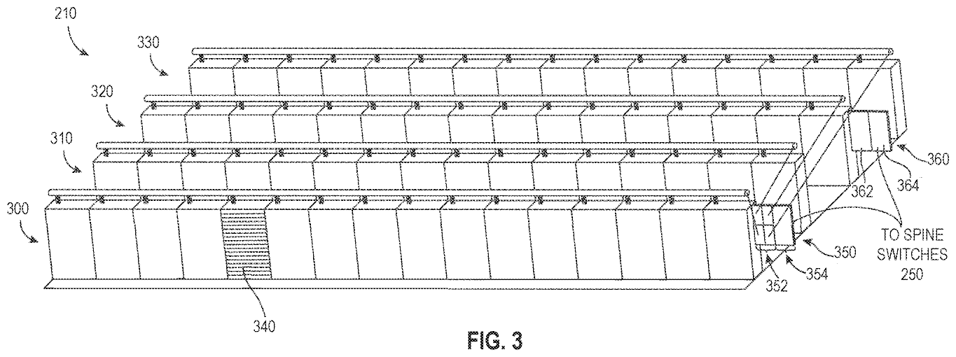

Referring now to FIG. 3, the pod 210, in the illustrative example, includes a set of rows 300, 310, 320, 330 of racks 340. Individual ones of the racks 340 may house multiple sleds (e.g., sixteen sleds) and provide power and data connections to the housed sleds, as described in more detail herein. In the illustrative example, the racks are connected to multiple pod switches 350, 360. The pod switch 350 includes a set of ports 352 to which the sleds of the racks of the pod 210 are connected and another set of ports 354 that connect the pod 210 to the spine switches 250 to provide connectivity to other pods in the data center 200. Similarly, the pod switch 360 includes a set of ports 362 to which the sleds of the racks of the pod 210 are connected and a set of ports 364 that connect the pod 210 to the spine switches 250. As such, the use of the pair of switches 350, 360 provides an amount of redundancy to the pod 210. For example, if either of the switches 350, 360 fails, the sleds in the pod 210 may still maintain data communication with the remainder of the data center 200 (e.g., sleds of other pods) through the other switch 350, 360. Furthermore, in the illustrative example, the switches 250, 350, 360 may be implemented as dual-mode optical switches, capable of routing both Ethernet protocol communications carrying Internet Protocol (IP) packets and communications according to a second, high-performance link-layer protocol (e.g., PCI Express) via optical signaling media of an optical fabric.

It should be appreciated that any one of the other pods 220, 230, 240 (as well as any additional pods of the data center 200) may be similarly structured as, and have components similar to, the pod 210 shown in and disclosed in regard to FIG. 3 (e.g., a given pod may have rows of racks housing multiple sleds as described above). Additionally, while two pod switches 350, 360 are shown, it should be understood that in other examples, a different number of pod switches may be present, providing even more failover capacity. In other examples, pods may be arranged differently than the rows-of-racks configuration shown in FIGS. 2 and 3. For example, a pod may include multiple sets of racks arranged radially, i.e., the racks are equidistant from a center switch.

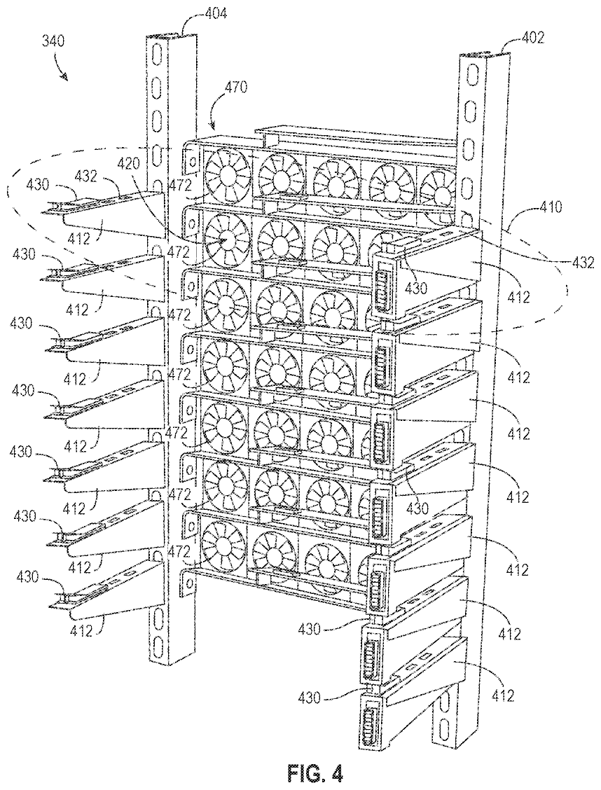

FIGS. 4-6 illustrate an example rack 340 of the data center 200. As shown in the illustrated example, the rack 340 includes two elongated support posts 402, 404, which are arranged vertically. For example, the elongated support posts 402, 404 may extend upwardly from a floor of the data center 200 when deployed. The rack 340 also includes one or more horizontal pairs 410 of elongated support arms 412 (identified in FIG. 4 via a dashed ellipse) configured to support a sled of the data center 200 as discussed below. One elongated support arm 412 of the pair of elongated support arms 412 extends outwardly from the elongated support post 402 and the other elongated support arm 412 extends outwardly from the elongated support post 404.

In the illustrative examples, at least some of the sleds of the data center 200 are chassis-less sleds. That is, such sleds have a chassis-less circuit board substrate on which physical resources (e.g., processors, memory, accelerators, storage, etc.) are mounted as discussed in more detail below. As such, the rack 340 is configured to receive the chassis-less sleds. For example, a given pair 410 of the elongated support arms 412 defines a sled slot 420 of the rack 340, which is configured to receive a corresponding chassis-less sled. To do so, the elongated support arms 412 include corresponding circuit board guides 430 configured to receive the chassis-less circuit board substrate of the sled. The circuit board guides 430 are secured to, or otherwise mounted to, a top side 432 of the corresponding elongated support arms 412. For example, in the illustrative example, the circuit board guides 430 are mounted at a distal end of the corresponding elongated support arm 412 relative to the corresponding elongated support post 402, 404. For clarity of FIGS. 4-6, not every circuit board guide 430 may be referenced in each figure. In some examples, at least some of the sleds include a chassis and the racks 340 are suitably adapted to receive the chassis.

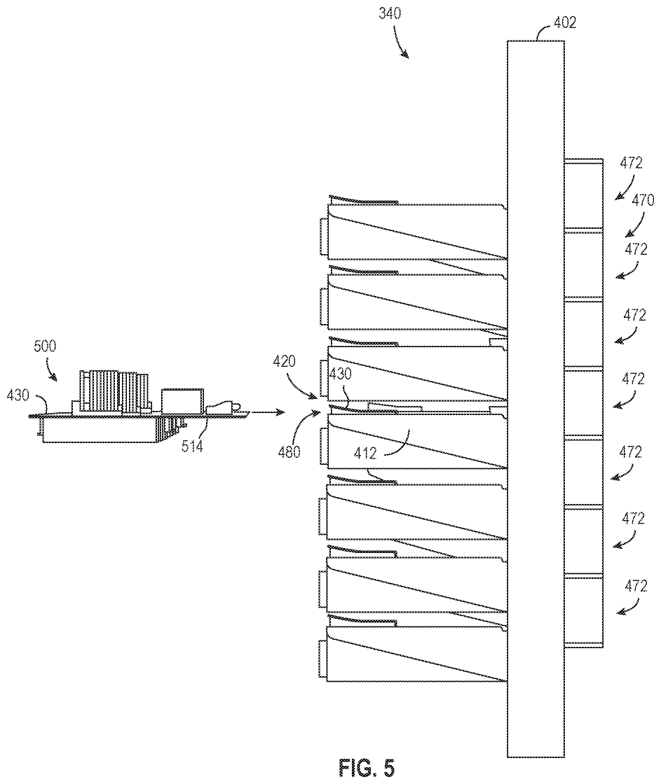

The circuit board guides 430 include an inner wall that defines a circuit board slot 480 configured to receive the chassis-less circuit board substrate of a sled 500 when the sled 500 is received in the corresponding sled slot 420 of the rack 340. To do so, as shown in FIG. 5, a user (or robot) aligns the chassis-less circuit board substrate of an illustrative chassis-less sled 500 to a sled slot 420. The user, or robot, may then slide the chassis-less circuit board substrate forward into the sled slot 420 such that each side edge 514 of the chassis-less circuit board substrate is received in a corresponding circuit board slot 480 of the circuit board guides 430 of the pair 410 of elongated support arms 412 that define the corresponding sled slot 420 as shown in FIG. 5. By having robotically accessible and robotically manipulable sleds including disaggregated resources, the different types of resource can be upgraded independently of one other and at their own optimized refresh rate. Furthermore, the sleds are configured to blindly mate with power and data communication cables in the rack 340, enhancing their ability to be quickly removed, upgraded, reinstalled, and/or replaced. As such, in some examples, the data center 200 may operate (e.g., execute workloads, undergo maintenance and/or upgrades, etc.) without human involvement on the data center floor. In other examples, a human may facilitate one or more maintenance or upgrade operations in the data center 200.

It should be appreciated that the circuit board guides 430 are dual sided. That is, a circuit board guide 430 includes an inner wall that defines a circuit board slot 480 on each side of the circuit board guide 430. In this way, the circuit board guide 430 can support a chassis-less circuit board substrate on either side. As such, a single additional elongated support post may be added to the rack 340 to turn the rack 340 into a two-rack solution that can hold twice as many sled slots 420 as shown in FIG. 4. The illustrative rack 340 includes seven pairs 410 of elongated support arms 412 that define seven corresponding sled slots 420. The sled slots 420 are configured to receive and support a corresponding sled 500 as discussed above. In other examples, the rack 340 may include additional or fewer pairs 410 of elongated support arms 412 (i.e., additional or fewer sled slots 420). It should be appreciated that because the sled 500 is chassis-less, the sled 500 may have an overall height that is different than typical servers. As such, in some examples, the height of a given sled slot 420 may be shorter than the height of a typical server (e.g., shorter than a single rank unit, referred to as “1U”). That is, the vertical distance between pairs 410 of elongated support arms 412 may be less than a standard rack unit “1U.” Additionally, due to the relative decrease in height of the sled slots 420, the overall height of the rack 340 in some examples may be shorter than the height of traditional rack enclosures. For example, in some examples, the elongated support posts 402, 404 may have a length of six feet or less. Again, in other examples, the rack 340 may have different dimensions. For example, in some examples, the vertical distance between pairs 410 of elongated support arms 412 may be greater than a standard rack unit “1U”. In such examples, the increased vertical distance between the sleds allows for larger heatsinks to be attached to the physical resources and for larger fans to be used (e.g., in the fan array 470 described below) for cooling the sleds, which in turn can allow the physical resources to operate at increased power levels. Further, it should be appreciated that the rack 340 does not include any walls, enclosures, or the like. Rather, the rack 340 is an enclosure-less rack that is opened to the local environment. In some cases, an end plate may be attached to one of the elongated support posts 402, 404 in those situations in which the rack 340 forms an end-of-row rack in the data center 200.

In some examples, various interconnects may be routed upwardly or downwardly through the elongated support posts 402, 404. To facilitate such routing, the elongated support posts 402, 404 include an inner wall that defines an inner chamber in which interconnects may be located. The interconnects routed through the elongated support posts 402, 404 may be implemented as any type of interconnects including, but not limited to, data or communication interconnects to provide communication connections to the sled slots 420, power interconnects to provide power to the sled slots 420, and/or other types of interconnects.

The rack 340, in the illustrative example, includes a support platform on which a corresponding optical data connector (not shown) is mounted. Such optical data connectors are associated with corresponding sled slots 420 and are configured to mate with optical data connectors of corresponding sleds 500 when the sleds 500 are received in the corresponding sled slots 420. In some examples, optical connections between components (e.g., sleds, racks, and switches) in the data center 200 are made with a blind mate optical connection. For example, a door on a given cable may prevent dust from contaminating the fiber inside the cable. In the process of connecting to a blind mate optical connector mechanism, the door is pushed open when the end of the cable approaches or enters the connector mechanism. Subsequently, the optical fiber inside the cable may enter a gel within the connector mechanism and the optical fiber of one cable comes into contact with the optical fiber of another cable within the gel inside the connector mechanism.

The illustrative rack 340 also includes a fan array 470 coupled to the cross-support arms of the rack 340. The fan array 470 includes one or more rows of cooling fans 472, which are aligned in a horizontal line between the elongated support posts 402, 404. In the illustrative example, the fan array 470 includes a row of cooling fans 472 for the different sled slots 420 of the rack 340. As discussed above, the sleds 500 do not include any on-board cooling system in the illustrative example and, as such, the fan array 470 provides cooling for such sleds 500 received in the rack 340. In other examples, some or all of the sleds 500 can include on-board cooling systems. Further, in some examples, the sleds 500 and/or the racks 340 may include and/or incorporate a liquid and/or immersion cooling system to facilitate cooling of electronic component(s) on the sleds 500. The rack 340, in the illustrative example, also includes different power supplies associated with different ones of the sled slots 420. A given power supply is secured to one of the elongated support arms 412 of the pair 410 of elongated support arms 412 that define the corresponding sled slot 420. For example, the rack 340 may include a power supply coupled or secured to individual ones of the elongated support arms 412 extending from the elongated support post 402. A given power supply includes a power connector configured to mate with a power connector of a sled 500 when the sled 500 is received in the corresponding sled slot 420. In the illustrative example, the sled 500 does not include any on-board power supply and, as such, the power supplies provided in the rack 340 supply power to corresponding sleds 500 when mounted to the rack 340. A given power supply is configured to satisfy the power requirements for its associated sled, which can differ from sled to sled. Additionally, the power supplies provided in the rack 340 can operate independent of each other. That is, within a single rack, a first power supply providing power to a compute sled can provide power levels that are different than power levels supplied by a second power supply providing power to an accelerator sled. The power supplies may be controllable at the sled level or rack level, and may be controlled locally by components on the associated sled or remotely, such as by another sled or an orchestrator.

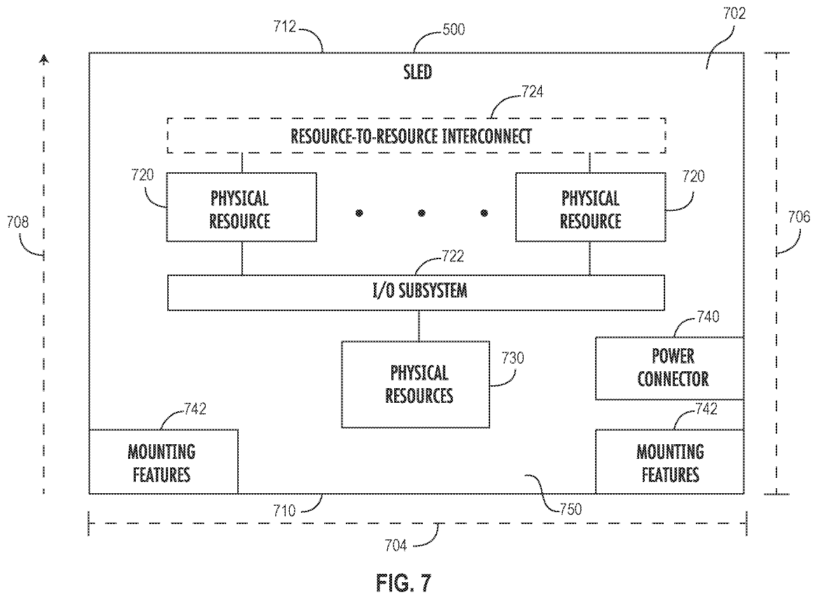

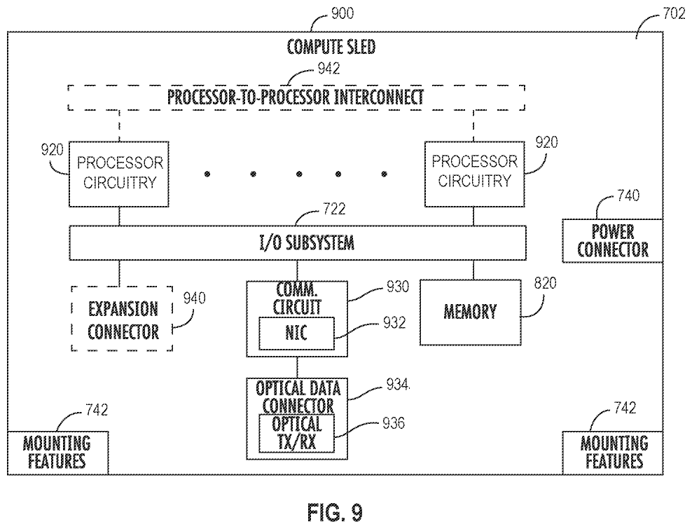

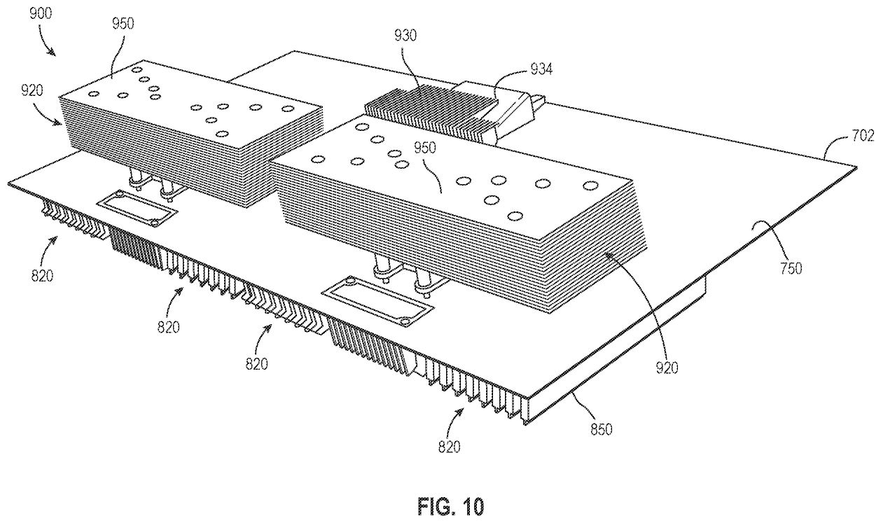

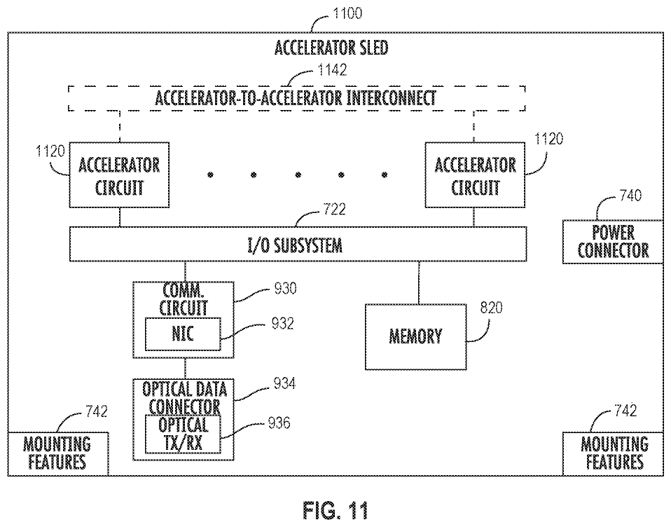

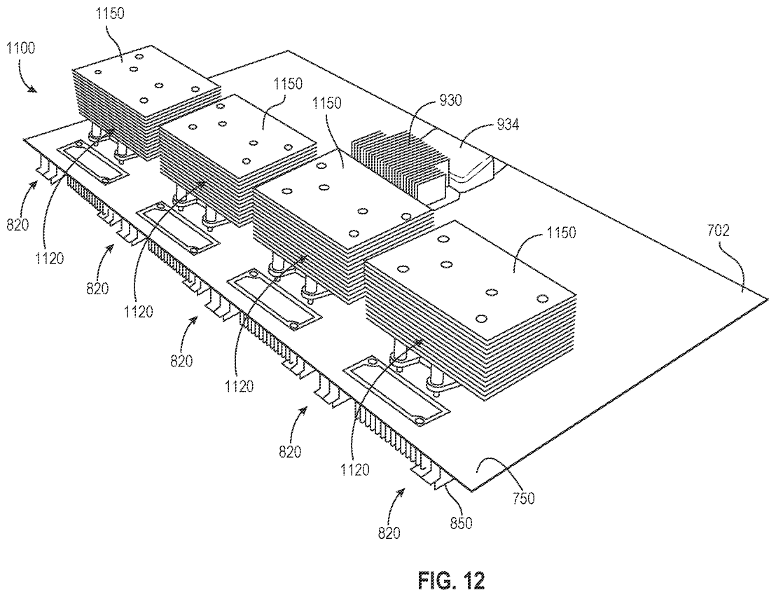

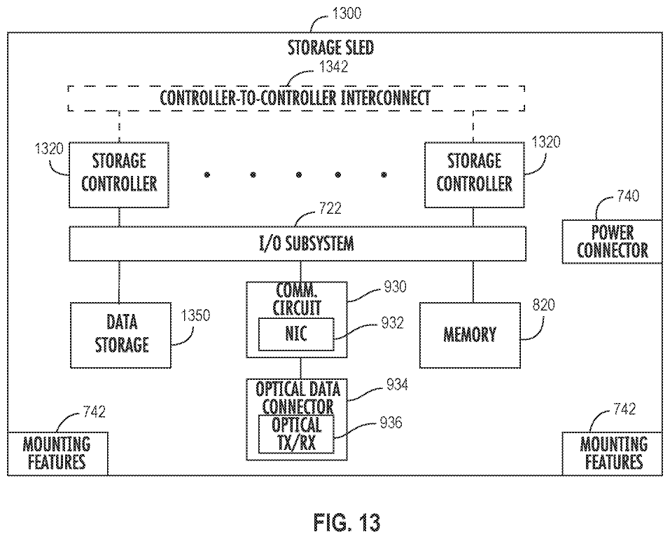

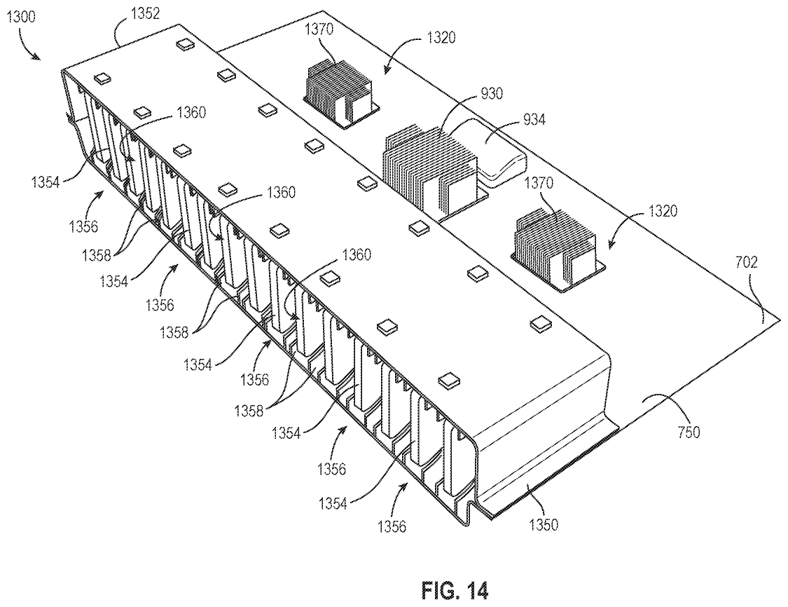

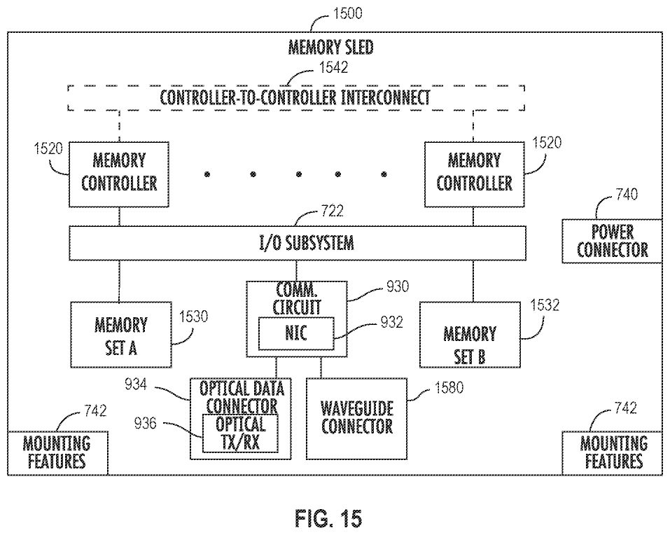

Referring now to FIG. 7, the sled 500, in the illustrative example, is configured to be mounted in a corresponding rack 340 of the data center 200 as discussed above. In some examples, a give sled 500 may be optimized or otherwise configured for performing particular tasks, such as compute tasks, acceleration tasks, data storage tasks, etc. For example, the sled 500 may be implemented as a compute sled 900 as discussed below in regard to FIGS. 9 and 10, an accelerator sled 1100 as discussed below in regard to FIGS. 11 and 12, a storage sled 1300 as discussed below in regard to FIGS. 13 and 14, or as a sled optimized or otherwise configured to perform other specialized tasks, such as a memory sled 1500, discussed below in regard to FIG. 15.

As discussed above, the illustrative sled 500 includes a chassis-less circuit board substrate 702, which supports various physical resources (e.g., electrical components) mounted thereon. It should be appreciated that the circuit board substrate 702 is “chassis-less” in that the sled 500 does not include a housing or enclosure. Rather, the chassis-less circuit board substrate 702 is open to the local environment. The chassis-less circuit board substrate 702 may be formed from any material capable of supporting the various electrical components mounted thereon. For example, in an illustrative example, the chassis-less circuit board substrate 702 is formed from an FR-4 glass-reinforced epoxy laminate material. Other materials may be used to form the chassis-less circuit board substrate 702 in other examples.

As discussed in more detail below, the chassis-less circuit board substrate 702 includes multiple features that improve the thermal cooling characteristics of the various electrical components mounted on the chassis-less circuit board substrate 702. As discussed, the chassis-less circuit board substrate 702 does not include a housing or enclosure, which may improve the airflow over the electrical components of the sled 500 by reducing those structures that may inhibit air flow. For example, because the chassis-less circuit board substrate 702 is not positioned in an individual housing or enclosure, there is no vertically-arranged backplane (e.g., a back plate of the chassis) attached to the chassis-less circuit board substrate 702, which could inhibit air flow across the electrical components. Additionally, the chassis-less circuit board substrate 702 has a geometric shape configured to reduce the length of the airflow path across the electrical components mounted to the chassis-less circuit board substrate 702. For example, the illustrative chassis-less circuit board substrate 702 has a width 704 that is greater than a depth 706 of the chassis-less circuit board substrate 702. In one particular example, the chassis-less circuit board substrate 702 has a width of about 21 inches and a depth of about 9 inches, compared to a typical server that has a width of about 17 inches and a depth of about 39 inches. As such, an airflow path 708 that extends from a front edge 710 of the chassis-less circuit board substrate 702 toward a rear edge 712 has a shorter distance relative to typical servers, which may improve the thermal cooling characteristics of the sled 500. Furthermore, although not illustrated in FIG. 7, the various physical resources mounted to the chassis-less circuit board substrate 702 in this example are mounted in corresponding locations such that no two substantively heat-producing electrical components shadow each other as discussed in more detail below. That is, no two electrical components, which produce appreciable heat during operation (i.e., greater than a nominal heat sufficient enough to adversely impact the cooling of another electrical component), are mounted to the chassis-less circuit board substrate 702 linearly in-line with each other along the direction of the airflow path 708 (i.e., along a direction extending from the front edge 710 toward the rear edge 712 of the chassis-less circuit board substrate 702). The placement and/or structure of the features may be suitable adapted when the electrical component(s) are being cooled via liquid (e.g., one phase or two phase immersion cooling).

As discussed above, the illustrative sled 500 includes one or more physical resources 720 mounted to a top side 750 of the chassis-less circuit board substrate 702. Although two physical resources 720 are shown in FIG. 7, it should be appreciated that the sled 500 may include one, two, or more physical resources 720 in other examples. The physical resources 720 may be implemented as any type of processor, controller, or other compute circuit capable of performing various tasks such as compute functions and/or controlling the functions of the sled 500 depending on, for example, the type or intended functionality of the sled 500. For example, as discussed in more detail below, the physical resources 720 may be implemented as high-performance processors in examples in which the sled 500 is implemented as a compute sled, as accelerator co-processors or circuits in examples in which the sled 500 is implemented as an accelerator sled, storage controllers in examples in which the sled 500 is implemented as a storage sled, or a set of memory devices in examples in which the sled 500 is implemented as a memory sled.

The sled 500 also includes one or more additional physical resources 730 mounted to the top side 750 of the chassis-less circuit board substrate 702. In the illustrative example, the additional physical resources include a network interface controller (NIC) as discussed in more detail below. Depending on the type and functionality of the sled 500, the physical resources 730 may include additional or other electrical components, circuits, and/or devices in other examples.

The physical resources 720 are communicatively coupled to the physical resources 730 via an input/output (I/O) subsystem 722. The I/O subsystem 722 may be implemented as circuitry and/or components to facilitate input/output operations with the physical resources 720, the physical resources 730, and/or other components of the sled 500. For example, the I/O subsystem 722 may be implemented as, or otherwise include, memory controller hubs, input/output control hubs, integrated sensor hubs, firmware devices, communication links (e.g., point-to-point links, bus links, wires, cables, waveguides, light guides, printed circuit board traces, etc.), and/or other components and subsystems to facilitate the input/output operations. In the illustrative example, the I/O subsystem 722 is implemented as, or otherwise includes, a double data rate 4 (DDR4) data bus or a DDR5 data bus.

In some examples, the sled 500 may also include a resource-to-resource interconnect 724. The resource-to-resource interconnect 724 may be implemented as any type of communication interconnect capable of facilitating resource-to-resource communications. In the illustrative example, the resource-to-resource interconnect 724 is implemented as a high-speed point-to-point interconnect (e.g., faster than the I/O subsystem 722). For example, the resource-to-resource interconnect 724 may be implemented as a QuickPath Interconnect (QPI), an UltraPath Interconnect (UPI), or other high-speed point-to-point interconnect dedicated to resource-to-resource communications.

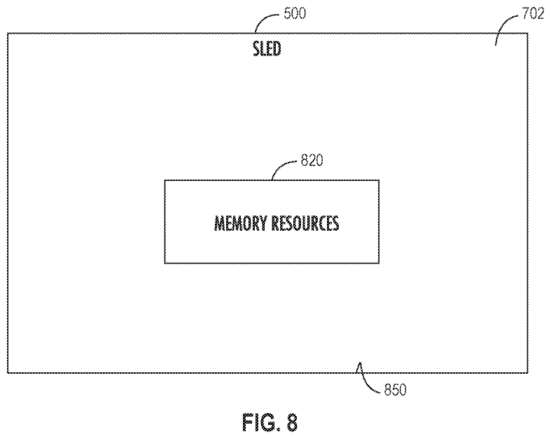

The sled 500 also includes a power connector 740 configured to mate with a corresponding power connector of the rack 340 when the sled 500 is mounted in the corresponding rack 340. The sled 500 receives power from a power supply of the rack 340 via the power connector 740 to supply power to the various electrical components of the sled 500. That is, the sled 500 does not include any local power supply (i.e., an on-board power supply) to provide power to the electrical components of the sled 500. The exclusion of a local or on-board power supply facilitates the reduction in the overall footprint of the chassis-less circuit board substrate 702, which may increase the thermal cooling characteristics of the various electrical components mounted on the chassis-less circuit board substrate 702 as discussed above. In some examples, voltage regulators are placed on a bottom side 850 (see FIG. 8) of the chassis-less circuit board substrate 702 directly opposite of processor circuitry 920 (see FIG. 9), and power is routed from the voltage regulators to the processor circuitry 920 by vias extending through the circuit board substrate 702. Such a configuration provides an increased thermal budget, additional current and/or voltage, and better voltage control relative to typical printed circuit boards in which processor power is delivered from a voltage regulator, in part, by printed circuit traces.

In some examples, the sled 500 may also include mounting features 742 configured to mate with a mounting arm, or other structure, of a robot to facilitate the placement of the sled 700 in a rack 340 by the robot. The mounting features 742 may be implemented as any type of physical structures that allow the robot to grasp the sled 500 without damaging the chassis-less circuit board substrate 702 or the electrical components mounted thereto. For example, in some examples, the mounting features 742 may be implemented as non-conductive pads attached to the chassis-less circuit board substrate 702. In other examples, the mounting features may be implemented as brackets, braces, or other similar structures attached to the chassis-less circuit board substrate 702. The particular number, shape, size, and/or make-up of the mounting feature 742 may depend on the design of the robot configured to manage the sled 500.

Referring now to FIG. 8, in addition to the physical resources 730 mounted on the top side 750 of the chassis-less circuit board substrate 702, the sled 500 also includes one or more memory devices 820 mounted to a bottom side 850 of the chassis-less circuit board substrate 702. That is, the chassis-less circuit board substrate 702 is implemented as a double-sided circuit board. The physical resources 720 are communicatively coupled to the memory devices 820 via the I/O subsystem 722. For example, the physical resources 720 and the memory devices 820 may be communicatively coupled by one or more vias extending through the chassis-less circuit board substrate 702. Different ones of the physical resources 720 may be communicatively coupled to different sets of one or more memory devices 820 in some examples. Alternatively, in other examples, different ones of the physical resources 720 may be communicatively coupled to the same ones of the memory devices 820.

The memory devices 820 may be implemented as any type of memory device capable of storing data for the physical resources 720 during operation of the sled 500, such as any type of volatile (e.g., dynamic random access memory (DRAM), etc.) or non-volatile memory. Volatile memory may be a storage medium that requires power to maintain the state of data stored by the medium. Non-limiting examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular examples, DRAM of a memory component may comply with a standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces.

In one example, the memory device is a block addressable memory device, such as those based on NAND or NOR technologies. A memory device may also include next-generation nonvolatile devices, such as Intel 3D XPointTM memory or other byte addressable write-in-place nonvolatile memory devices. In one example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory. The memory device may refer to the die itself and/or to a packaged memory product. In some examples, the memory device may include a transistor-less stackable cross point architecture in which memory cells sit at the intersection of word lines and bit lines and are individually addressable and in which bit storage is based on a change in bulk resistance.

Referring now to FIG. 9, in some examples, the sled 500 may be implemented as a compute sled 900. The compute sled 900 is optimized, or otherwise configured, to perform compute tasks. As discussed above, the compute sled 900 may rely on other sleds, such as acceleration sleds and/or storage sleds, to perform such compute tasks. The compute sled 900 includes various physical resources (e.g., electrical components) similar to the physical resources of the sled 500, which have been identified in FIG. 9 using the same reference numbers. The description of such components provided above in regard to FIGS. 7 and 8 applies to the corresponding components of the compute sled 900 and is not repeated herein for clarity of the description of the compute sled 900.

In the illustrative compute sled 900, the physical resources 720 include processor circuitry 920. Although only two blocks of processor circuitry 920 are shown in FIG. 9, it should be appreciated that the compute sled 900 may include additional processor circuits 920 in other examples. Illustratively, the processor circuitry 920 corresponds to high-performance processors 920 and may be configured to operate at a relatively high power rating. Although the high-performance processor circuitry 920 generates additional heat operating at power ratings greater than typical processors (which operate at around 155-230 W), the enhanced thermal cooling characteristics of the chassis-less circuit board substrate 702 discussed above facilitate the higher power operation. For example, in the illustrative example, the processor circuitry 920 is configured to operate at a power rating of at least 250 W. In some examples, the processor circuitry 920 may be configured to operate at a power rating of at least 350 W.

In some examples, the compute sled 900 may also include a processor-to-processor interconnect 942. Similar to the resource-to-resource interconnect 724 of the sled 500 discussed above, the processor-to-processor interconnect 942 may be implemented as any type of communication interconnect capable of facilitating processor-to-processor interconnect 942 communications. In the illustrative example, the processor-to-processor interconnect 942 is implemented as a high-speed point-to-point interconnect (e.g., faster than the I/O subsystem 722). For example, the processor-to-processor interconnect 942 may be implemented as a QuickPath Interconnect (QPI), an UltraPath Interconnect (UPI), or other high-speed point-to-point interconnect dedicated to processor-to-processor communications.

The compute sled 900 also includes a communication circuit 930. The illustrative communication circuit 930 includes a network interface controller (NIC) 932, which may also be referred to as a host fabric interface (HFI). The NIC 932 may be implemented as, or otherwise include, any type of integrated circuit, discrete circuits, controller chips, chipsets, add-in-boards, daughtercards, network interface cards, or other devices that may be used by the compute sled 900 to connect with another compute device (e.g., with other sleds 500). In some examples, the NIC 932 may be implemented as part of a system-on-a-chip (SoC) that includes one or more processors, or included on a multichip package that also contains one or more processors. In some examples, the NIC 932 may include a local processor (not shown) and/or a local memory (not shown) that are both local to the NIC 932. In such examples, the local processor of the NIC 932 may be capable of performing one or more of the functions of the processor circuitry 920. Additionally or alternatively, in such examples, the local memory of the MC 932 may be integrated into one or more components of the compute sled at the board level, socket level, chip level, and/or other levels.

The communication circuit 930 is communicatively coupled to an optical data connector 934. The optical data connector 934 is configured to mate with a corresponding optical data connector of the rack 340 when the compute sled 900 is mounted in the rack 340. Illustratively, the optical data connector 934 includes a plurality of optical fibers which lead from a mating surface of the optical data connector 934 to an optical transceiver 936. The optical transceiver 936 is configured to convert incoming optical signals from the rack-side optical data connector to electrical signals and to convert electrical signals to outgoing optical signals to the rack-side optical data connector. Although shown as forming part of the optical data connector 934 in the illustrative example, the optical transceiver 936 may form a portion of the communication circuit 930 in other examples.

In some examples, the compute sled 900 may also include an expansion connector 940. In such examples, the expansion connector 940 is configured to mate with a corresponding connector of an expansion chassis-less circuit board substrate to provide additional physical resources to the compute sled 900. The additional physical resources may be used, for example, by the processor circuitry 920 during operation of the compute sled 900. The expansion chassis-less circuit board substrate may be substantially similar to the chassis-less circuit board substrate 702 discussed above and may include various electrical components mounted thereto. The particular electrical components mounted to the expansion chassis-less circuit board substrate may depend on the intended functionality of the expansion chassis-less circuit board substrate. For example, the expansion chassis-less circuit board substrate may provide additional compute resources, memory resources, and/or storage resources. As such, the additional physical resources of the expansion chassis-less circuit board substrate may include, but is not limited to, processors, memory devices, storage devices, and/or accelerator circuits including, for example, field programmable gate arrays (FPGA), application-specific integrated circuits (ASICs), security co-processors, graphics processing units (GPUs), machine learning circuits, or other specialized processors, controllers, devices, and/or circuits.

Referring now to FIG. 10, an illustrative example of the compute sled 900 is shown. As shown, the processor circuitry 920, communication circuit 930, and optical data connector 934 are mounted to the top side 750 of the chassis-less circuit board substrate 702. Any suitable attachment or mounting technology may be used to mount the physical resources of the compute sled 900 to the chassis-less circuit board substrate 702. For example, the various physical resources may be mounted in corresponding sockets (e.g., a processor socket), holders, or brackets. In some cases, some of the electrical components may be directly mounted to the chassis-less circuit board substrate 702 via soldering or similar techniques.

As discussed above, the separate processor circuitry 920 and the communication circuit 930 are mounted to the top side 750 of the chassis-less circuit board substrate 702 such that no two heat-producing, electrical components shadow each other. In the illustrative example, the processor circuitry 920 and the communication circuit 930 are mounted in corresponding locations on the top side 750 of the chassis-less circuit board substrate 702 such that no two of those physical resources are linearly in-line with others along the direction of the airflow path 708. It should be appreciated that, although the optical data connector 934 is in-line with the communication circuit 930, the optical data connector 934 produces no or nominal heat during operation.

The memory devices 820 of the compute sled 900 are mounted to the bottom side 850 of the of the chassis-less circuit board substrate 702 as discussed above in regard to the sled 500. Although mounted to the bottom side 850, the memory devices 820 are communicatively coupled to the processor circuitry 920 located on the top side 750 via the I/O subsystem 722. Because the chassis-less circuit board substrate 702 is implemented as a double-sided circuit board, the memory devices 820 and the processor circuitry 920 may be communicatively coupled by one or more vias, connectors, or other mechanisms extending through the chassis-less circuit board substrate 702. Different processor circuitry 920 (e.g., different processors) may be communicatively coupled to a different set of one or more memory devices 820 in some examples. Alternatively, in other examples, different processor circuitry 920 (e.g., different processors) may be communicatively coupled to the same ones of the memory devices 820. In some examples, the memory devices 820 may be mounted to one or more memory mezzanines on the bottom side of the chassis-less circuit board substrate 702 and may interconnect with a corresponding processor circuitry 920 through a ball-grid array.

Different processor circuitry 920 (e.g., different processors) include and/or is associated with corresponding heatsinks 950 secured thereto. Due to the mounting of the memory devices 820 to the bottom side 850 of the chassis-less circuit board substrate 702 (as well as the vertical spacing of the sleds 500 in the corresponding rack 340), the top side 750 of the chassis-less circuit board substrate 702 includes additional “free” area or space that facilitates the use of heatsinks 950 having a larger size relative to traditional heatsinks used in typical servers. Additionally, due to the improved thermal cooling characteristics of the chassis-less circuit board substrate 702, none of the processor heatsinks 950 include cooling fans attached thereto. That is, the heatsinks 950 may be fan-less heatsinks. In some examples, the heatsinks 950 mounted atop the processor circuitry 920 may overlap with the heatsink attached to the communication circuit 930 in the direction of the airflow path 708 due to their increased size, as illustratively suggested by FIG. 10.

Referring now to FIG. 11, in some examples, the sled 500 may be implemented as an accelerator sled 1100. The accelerator sled 1100 is configured, to perform specialized compute tasks, such as machine learning, encryption, hashing, or other computational-intensive task. In some examples, for example, a compute sled 900 may offload tasks to the accelerator sled 1100 during operation. The accelerator sled 1100 includes various components similar to components of the sled 500 and/or the compute sled 900, which have been identified in FIG. 11 using the same reference numbers. The description of such components provided above in regard to FIGS. 7, 8, and 9 apply to the corresponding components of the accelerator sled 1100 and is not repeated herein for clarity of the description of the accelerator sled 1100.

In the illustrative accelerator sled 1100, the physical resources 720 include accelerator circuits 1120. Although only two accelerator circuits 1120 are shown in FIG. 11, it should be appreciated that the accelerator sled 1100 may include additional accelerator circuits 1120 in other examples. For example, as shown in FIG. 12, the accelerator sled 1100 may include four accelerator circuits 1120. The accelerator circuits 1120 may be implemented as any type of processor, co-processor, compute circuit, or other device capable of performing compute or processing operations. For example, the accelerator circuits 1120 may be implemented as, for example, field programmable gate arrays (FPGA), application-specific integrated circuits (ASICs), security co-processors, graphics processing units (GPUs), neuromorphic processor units, quantum computers, machine learning circuits, or other specialized processors, controllers, devices, and/or circuits.

In some examples, the accelerator sled 1100 may also include an accelerator-to-accelerator interconnect 1142. Similar to the resource-to-resource interconnect 724 of the sled 700 discussed above, the accelerator-to-accelerator interconnect 1142 may be implemented as any type of communication interconnect capable of facilitating accelerator-to-accelerator communications. In the illustrative example, the accelerator-to-accelerator interconnect 1142 is implemented as a high-speed point-to-point interconnect (e.g., faster than the I/O subsystem 722). For example, the accelerator-to-accelerator interconnect 1142 may be implemented as a QuickPath Interconnect (QPI), an UltraPath Interconnect (UPI), or other high-speed point-to-point interconnect dedicated to processor-to-processor communications. In some examples, the accelerator circuits 1120 may be daisy-chained with a primary accelerator circuit 1120 connected to the NIC 932 and memory 820 through the I/O subsystem 722 and a secondary accelerator circuit 1120 connected to the MC 932 and memory 820 through a primary accelerator circuit 1120.

Referring now to FIG. 12, an illustrative example of the accelerator sled 1100 is shown. As discussed above, the accelerator circuits 1120, the communication circuit 930, and the optical data connector 934 are mounted to the top side 750 of the chassis-less circuit board substrate 702. Again, the individual accelerator circuits 1120 and communication circuit 930 are mounted to the top side 750 of the chassis-less circuit board substrate 702 such that no two heat-producing, electrical components shadow each other as discussed above. The memory devices 820 of the accelerator sled 1100 are mounted to the bottom side 850 of the of the chassis-less circuit board substrate 702 as discussed above in regard to the sled 700. Although mounted to the bottom side 850, the memory devices 820 are communicatively coupled to the accelerator circuits 1120 located on the top side 750 via the I/O subsystem 722 (e.g., through vias). Further, the accelerator circuits 1120 may include and/or be associated with a heatsink 1150 that is larger than a traditional heatsink used in a server. As discussed above with reference to the heatsinks 950 of FIG. 9, the heatsinks 1150 may be larger than traditional heatsinks because of the “free” area provided by the memory resources 820 being located on the bottom side 850 of the chassis-less circuit board substrate 702 rather than on the top side 750.

Referring now to FIG. 13, in some examples, the sled 500 may be implemented as a storage sled 1300. The storage sled 1300 is configured, to store data in a data storage 1350 local to the storage sled 1300. For example, during operation, a compute sled 900 or an accelerator sled 1100 may store and retrieve data from the data storage 1350 of the storage sled 1300. The storage sled 1300 includes various components similar to components of the sled 500 and/or the compute sled 900, which have been identified in FIG. 13 using the same reference numbers. The description of such components provided above in regard to FIGS. 7, 8, and 9 apply to the corresponding components of the storage sled 1300 and is not repeated herein for clarity of the description of the storage sled 1300.

In the illustrative storage sled 1300, the physical resources 720 includes storage controllers 1320. Although only two storage controllers 1320 are shown in FIG. 13, it should be appreciated that the storage sled 1300 may include additional storage controllers 1320 in other examples. The storage controllers 1320 may be implemented as any type of processor, controller, or control circuit capable of controlling the storage and retrieval of data into the data storage 1350 based on requests received via the communication circuit 930. In the illustrative example, the storage controllers 1320 are implemented as relatively low-power processors or controllers. For example, in some examples, the storage controllers 1320 may be configured to operate at a power rating of about 75 watts.

In some examples, the storage sled 1300 may also include a controller-to-controller interconnect 1342. Similar to the resource-to-resource interconnect 724 of the sled 500 discussed above, the controller-to-controller interconnect 1342 may be implemented as any type of communication interconnect capable of facilitating controller-to-controller communications. In the illustrative example, the controller-to-controller interconnect 1342 is implemented as a high-speed point-to-point interconnect (e.g., faster than the I/O subsystem 722). For example, the controller-to-controller interconnect 1342 may be implemented as a QuickPath Interconnect (QPI), an UltraPath Interconnect (UPI), or other high-speed point-to-point interconnect dedicated to processor-to-processor communications.

Referring now to FIG. 14, an illustrative example of the storage sled 1300 is shown. In the illustrative example, the data storage 1350 is implemented as, or otherwise includes, a storage cage 1352 configured to house one or more solid state drives (SSDs) 1354. To do so, the storage cage 1352 includes a number of mounting slots 1356, which are configured to receive corresponding solid state drives 1354. The mounting slots 1356 include a number of drive guides 1358 that cooperate to define an access opening 1360 of the corresponding mounting slot 1356. The storage cage 1352 is secured to the chassis-less circuit board substrate 702 such that the access openings face away from (i.e., toward the front of) the chassis-less circuit board substrate 702. As such, solid state drives 1354 are accessible while the storage sled 1300 is mounted in a corresponding rack 304. For example, a solid state drive 1354 may be swapped out of a rack 340 (e.g., via a robot) while the storage sled 1300 remains mounted in the corresponding rack 340.

The storage cage 1352 illustratively includes sixteen mounting slots 1356 and is capable of mounting and storing sixteen solid state drives 1354. The storage cage 1352 may be configured to store additional or fewer solid state drives 1354 in other examples. Additionally, in the illustrative example, the solid state drives are mounted vertically in the storage cage 1352, but may be mounted in the storage cage 1352 in a different orientation in other examples. A given solid state drive 1354 may be implemented as any type of data storage device capable of storing long term data. To do so, the solid state drives 1354 may include volatile and non-volatile memory devices discussed above.

As shown in FIG. 14, the storage controllers 1320, the communication circuit 930, and the optical data connector 934 are illustratively mounted to the top side 750 of the chassis-less circuit board substrate 702. Again, as discussed above, any suitable attachment or mounting technology may be used to mount the electrical components of the storage sled 1300 to the chassis-less circuit board substrate 702 including, for example, sockets (e.g., a processor socket), holders, brackets, soldered connections, and/or other mounting or securing techniques.

As discussed above, the individual storage controllers 1320 and the communication circuit 930 are mounted to the top side 750 of the chassis-less circuit board substrate 702 such that no two heat-producing, electrical components shadow each other. For example, the storage controllers 1320 and the communication circuit 930 are mounted in corresponding locations on the top side 750 of the chassis-less circuit board substrate 702 such that no two of those electrical components are linearly in-line with each other along the direction of the airflow path 708.

The memory devices 820 (not shown in FIG. 14) of the storage sled 1300 are mounted to the bottom side 850 (not shown in FIG. 14) of the chassis-less circuit board substrate 702 as discussed above in regard to the sled 500. Although mounted to the bottom side 850, the memory devices 820 are communicatively coupled to the storage controllers 1320 located on the top side 750 via the I/O subsystem 722. Again, because the chassis-less circuit board substrate 702 is implemented as a double-sided circuit board, the memory devices 820 and the storage controllers 1320 may be communicatively coupled by one or more vias, connectors, or other mechanisms extending through the chassis-less circuit board substrate 702. The storage controllers 1320 include and/or are associated with a heatsink 1370 secured thereto. As discussed above, due to the improved thermal cooling characteristics of the chassis-less circuit board substrate 702 of the storage sled 1300, none of the heatsinks 1370 include cooling fans attached thereto. That is, the heatsinks 1370 may be fan-less heatsinks.

Referring now to FIG. 15, in some examples, the sled 500 may be implemented as a memory sled 1500. The storage sled 1500 is optimized, or otherwise configured, to provide other sleds 500 (e.g., compute sleds 900, accelerator sleds 1100, etc.) with access to a pool of memory (e.g., in two or more sets 1530, 1532 of memory devices 820) local to the memory sled 1300. For example, during operation, a compute sled 900 or an accelerator sled 1100 may remotely write to and/or read from one or more of the memory sets 1530, 1532 of the memory sled 1300 using a logical address space that maps to physical addresses in the memory sets 1530, 1532. The memory sled 1500 includes various components similar to components of the sled 500 and/or the compute sled 900, which have been identified in FIG. 15 using the same reference numbers. The description of such components provided above in regard to FIGS. 7, 8, and 9 apply to the corresponding components of the memory sled 1500 and is not repeated herein for clarity of the description of the memory sled 1500.

In the illustrative memory sled 1500, the physical resources 720 include memory controllers 1520. Although only two memory controllers 1520 are shown in FIG. 15, it should be appreciated that the memory sled 1500 may include additional memory controllers 1520 in other examples. The memory controllers 1520 may be implemented as any type of processor, controller, or control circuit capable of controlling the writing and reading of data into the memory sets 1530, 1532 based on requests received via the communication circuit 930. In the illustrative example, the memory controllers 1520 are connected to corresponding memory sets 1530, 1532 to write to and read from memory devices 820 (not shown) within the corresponding memory set 1530, 1532 and enforce any permissions (e.g., read, write, etc.) associated with sled 500 that has sent a request to the memory sled 1500 to perform a memory access operation (e.g., read or write).

In some examples, the memory sled 1500 may also include a controller-to-controller interconnect 1542. Similar to the resource-to-resource interconnect 724 of the sled 500 discussed above, the controller-to-controller interconnect 1542 may be implemented as any type of communication interconnect capable of facilitating controller-to-controller communications. In the illustrative example, the controller-to-controller interconnect 1542 is implemented as a high-speed point-to-point interconnect (e.g., faster than the I/O subsystem 722). For example, the controller-to-controller interconnect 1542 may be implemented as a QuickPath Interconnect (QPI), an UltraPath Interconnect (UPI), or other high-speed point-to-point interconnect dedicated to processor-to-processor communications. As such, in some examples, a memory controller 1520 may access, through the controller-to-controller interconnect 1542, memory that is within the memory set 1532 associated with another memory controller 1520. In some examples, a scalable memory controller is made of multiple smaller memory controllers, referred to herein as “chiplets”, on a memory sled (e.g., the memory sled 1500). The chiplets may be interconnected (e.g., using EMIB (Embedded Multi-Die Interconnect Bridge) technology). The combined chiplet memory controller may scale up to a relatively large number of memory controllers and I/O ports, (e.g., up to 16 memory channels). In some examples, the memory controllers 1520 may implement a memory interleave (e.g., one memory address is mapped to the memory set 1530, the next memory address is mapped to the memory set 1532, and the third address is mapped to the memory set 1530, etc.). The interleaving may be managed within the memory controllers 1520, or from CPU sockets (e.g., of the compute sled 900) across network links to the memory sets 1530, 1532, and may improve the latency associated with performing memory access operations as compared to accessing contiguous memory addresses from the same memory device.

Further, in some examples, the memory sled 1500 may be connected to one or more other sleds 500 (e.g., in the same rack 340 or an adjacent rack 340) through a waveguide, using the waveguide connector 1580. In the illustrative example, the waveguides are 74 millimeter waveguides that provide 16 Rx (i.e., receive) lanes and 16 Tx (i.e., transmit) lanes. Different ones of the lanes, in the illustrative example, are either 16 GHz or 32 GHz. In other examples, the frequencies may be different. Using a waveguide may provide high throughput access to the memory pool (e.g., the memory sets 1530, 1532) to another sled (e.g., a sled 500 in the same rack 340 or an adjacent rack 340 as the memory sled 1500) without adding to the load on the optical data connector 934.

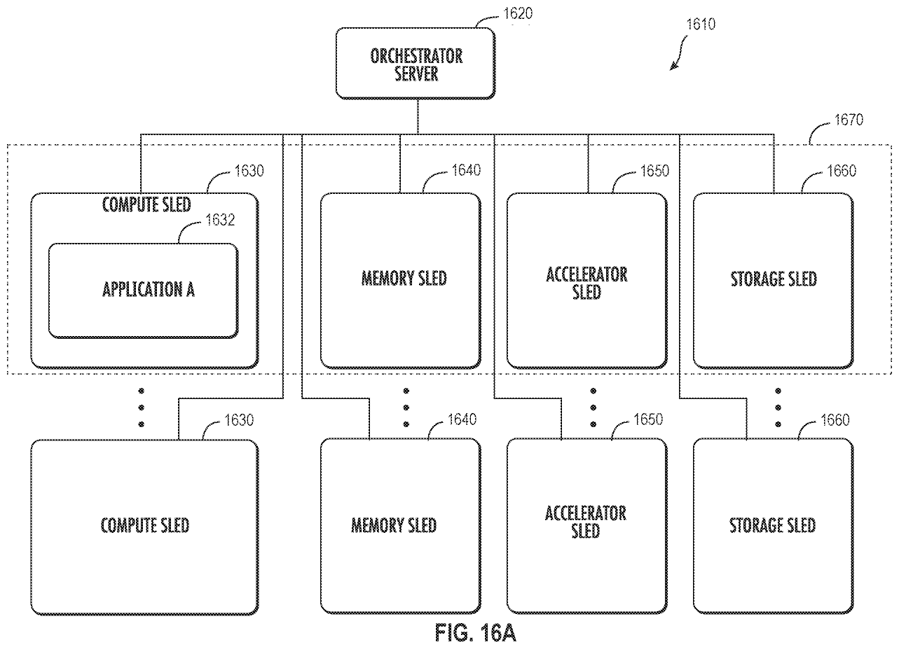

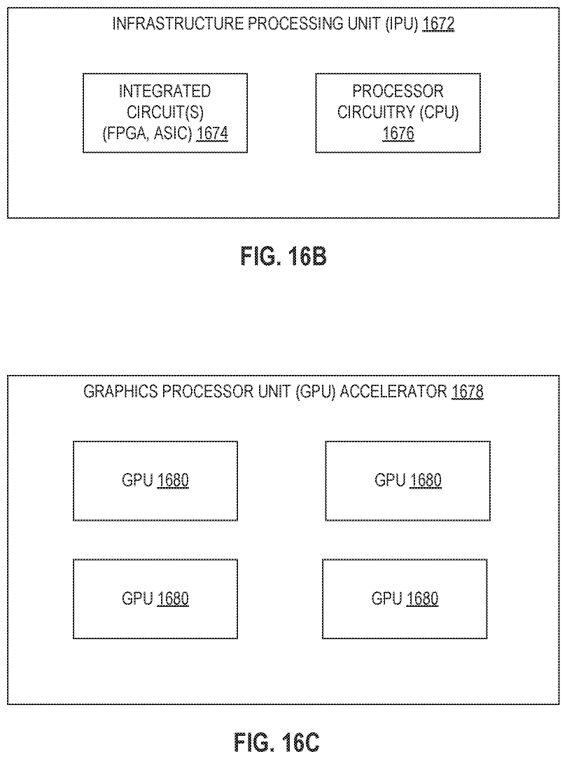

Referring now to FIG. 16A, a system for executing one or more workloads (e.g., applications) may be implemented in accordance with the data center 200. In the illustrative example, the system 1610 includes an orchestrator server 1620, which may be implemented as a managed node including a compute device (e.g., processor circuitry 920 on a compute sled 900) executing management software (e.g., a cloud operating environment, such as OpenStack) that is communicatively coupled to multiple sleds 500 including a large number of compute sleds 1630 (e.g., similar to the compute sled 900), memory sleds 1640 (e.g., similar to the memory sled 1500), accelerator sleds 1650 (e.g., similar to the memory sled 1000), and storage sleds 1660 (e.g., similar to the storage sled 1300). One or more of the sleds 1630, 1640, 1650, 1660 may be grouped into a managed node 1670, such as by the orchestrator server 1620, to collectively perform a workload (e.g., an application 1632 executed in a virtual machine or in a container). The managed node 1670 may be implemented as an assembly of physical resources 720, such as processor circuitry 920, memory resources 820, accelerator circuits 1120, or data storage 1350, from the same or different sleds 500. Further, the managed node may be established, defined, or “spun up” by the orchestrator server 1620 at the time a workload is to be assigned to the managed node or at any other time, and may exist regardless of whether any workloads are presently assigned to the managed node. In the illustrative example, the orchestrator server 1620 may selectively allocate and/or deallocate physical resources 720 from the sleds 500 and/or add or remove one or more sleds 500 from the managed node 1670 as a function of quality of service (QoS) targets (e.g., a target throughput, a target latency, a target number of instructions per second, etc.) associated with a service level agreement for the workload (e.g., the application 1632). In doing so, the orchestrator server 1620 may receive telemetry data indicative of performance conditions (e.g., throughput, latency, instructions per second, etc.) in different ones of the sleds 500 of the managed node 1670 and compare the telemetry data to the quality of service targets to determine whether the quality of service targets are being satisfied. The orchestrator server 1620 may additionally determine whether one or more physical resources may be deallocated from the managed node 1670 while still satisfying the QoS targets, thereby freeing up those physical resources for use in another managed node (e.g., to execute a different workload). Alternatively, if the QoS targets are not presently satisfied, the orchestrator server 1620 may determine to dynamically allocate additional physical resources to assist in the execution of the workload (e.g., the application 1632) while the workload is executing. Similarly, the orchestrator server 1620 may determine to dynamically deallocate physical resources from a managed node if the orchestrator server 1620 determines that deallocating the physical resource would result in QoS targets still being met.

Additionally, in some examples, the orchestrator server 1620 may identify trends in the resource utilization of the workload (e.g., the application 1632), such as by identifying phases of execution (e.g., time periods in which different operations, having different resource utilizations characteristics, are performed) of the workload (e.g., the application 1632) and pre-emptively identifying available resources in the data center 200 and allocating them to the managed node 1670 (e.g., within a predefined time period of the associated phase beginning). In some examples, the orchestrator server 1620 may model performance based on various latencies and a distribution scheme to place workloads among compute sleds and other resources (e.g., accelerator sleds, memory sleds, storage sleds) in the data center 200. For example, the orchestrator server 1620 may utilize a model that accounts for the performance of resources on the sleds 500 (e.g., FPGA performance, memory access latency, etc.) and the performance (e.g., congestion, latency, bandwidth) of the path through the network to the resource (e.g., FPGA). As such, the orchestrator server 1620 may determine which resource(s) should be used with which workloads based on the total latency associated with different potential resource(s) available in the data center 200 (e.g., the latency associated with the performance of the resource itself in addition to the latency associated with the path through the network between the compute sled executing the workload and the sled 500 on which the resource is located).

In some examples, the orchestrator server 1620 may generate a map of heat generation in the data center 200 using telemetry data (e.g., temperatures, fan speeds, etc.) reported from the sleds 500 and allocate resources to managed nodes as a function of the map of heat generation and predicted heat generation associated with different workloads, to maintain a target temperature and heat distribution in the data center 200. Additionally or alternatively, in some examples, the orchestrator server 1620 may organize received telemetry data into a hierarchical model that is indicative of a relationship between the managed nodes (e.g., a spatial relationship such as the physical locations of the resources of the managed nodes within the data center 200 and/or a functional relationship, such as groupings of the managed nodes by the customers the managed nodes provide services for, the types of functions typically performed by the managed nodes, managed nodes that typically share or exchange workloads among each other, etc.). Based on differences in the physical locations and resources in the managed nodes, a given workload may exhibit different resource utilizations (e.g., cause a different internal temperature, use a different percentage of processor or memory capacity) across the resources of different managed nodes. The orchestrator server 1620 may determine the differences based on the telemetry data stored in the hierarchical model and factor the differences into a prediction of future resource utilization of a workload if the workload is reassigned from one managed node to another managed node, to accurately balance resource utilization in the data center 200. In some examples, the orchestrator server 1620 may identify patterns in resource utilization phases of the workloads and use the patterns to predict future resource utilization of the workloads.

To reduce the computational load on the orchestrator server 1620 and the data transfer load on the network, in some examples, the orchestrator server 1620 may send self-test information to the sleds 500 to enable a given sled 500 to locally (e.g., on the sled 500) determine whether telemetry data generated by the sled 500 satisfies one or more conditions (e.g., an available capacity that satisfies a predefined threshold, a temperature that satisfies a predefined threshold, etc.). The given sled 500 may then report back a simplified result (e.g., yes or no) to the orchestrator server 1620, which the orchestrator server 1620 may utilize in determining the allocation of resources to managed nodes.

FIG. 16B is a block diagram of an example infrastructure processing unit (IPU) 1672. The example IPU 1672 includes integrated circuit(s) 1674. The integrated circuit(s) 1674 can include, for example, Field Programmable Gate Arrays (FPGAs) and/or Application Specific Integrated Circuits (ASICs). The example IPU 1672 includes processor circuitry 1676 such as a central processing unit (CPU).

FIG. 16C is a block diagram of an example graphics processing unit (GPU) accelerator 1678. The GPU accelerator 1678 includes one or more GPUs 1680 to perform graphics-related workloads.

The IPU 1672 and the GPU accelerator 1678 can be peripherals or plug-in systems (e.g., card(s) plugged into slot(s) of, for instance, a server. During operation of the server, workloads can be performed by one or more of the integrated circuit(s) 1674, the processor circuitry 1676, and/or the GPUs 1680 of the GPU accelerator 1678. Power consumed by, for instance, the IPU 1672 and the GPU accelerator 1678 can be proportional to the workload(s) performed by these peripherals.

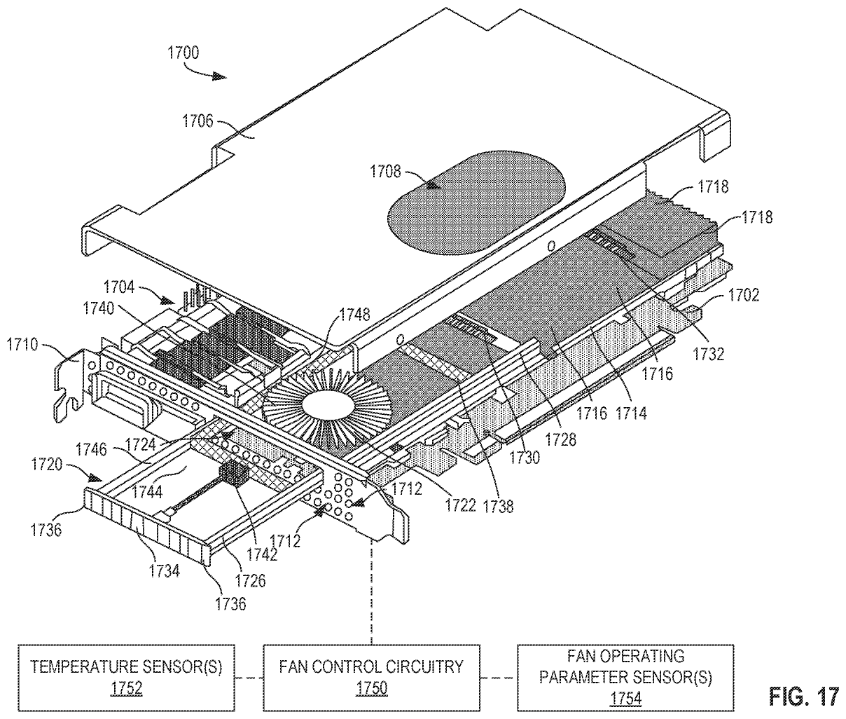

FIG. 17 illustrates an example peripheral 1700 including a field replaceable fan assembly in accordance with teachings of this disclosure. In the example of FIG. 17, the peripheral 1700 is a peripheral interconnect express (PCIe) card that implements an infrastructure processing unit (IPU). In the foregoing discussion of FIG. 17, the PCIe card 1700 will be referred to as the IPU 1700. However, other types of PCIe cards could be used in connection with the example of FIG. 17, such as a graphics processing unit (GPU), a data processing unit (DPU), a smart network interface card (NIC), an Open Compute Project (OCP) add-in card, etc.

The IPU 1700 includes a substrate or board 1702 (e.g., a printed circuit board) including electronic components 1704 of the IPU 1700 such as, for example, processor circuitry such as microprocessor(s) and/or field-programmable gate array(s) (FPGA), memory, etc. The example IPU 1700 of FIG. 17 includes a housing 1706 (e.g., a cover) to at least partially enclose a heat sink 1714, which is proximate (e.g., in contact with) the electronic component(s) 1704 of the IPU 1700. For illustrative purposes, the housing 1706 is shown as uncoupled from the IPU 1700 in FIG. 17 to show an interior of the IPU 1700. The housing 1706 includes an aperture or opening 1708 defined therein to enable air to enter the IPU 1700. A shape and/or size of the housing 1706 and/or the opening 1708 can differ from the example shown in FIG. 17.

The example IPU 1700 also includes a side panel 1710 (e.g., an I0 bracket) that further services to at least partially enclose the electronic components 1704 of the IPU 1700. As shown in FIG. 17, the side panel 1710 includes a plurality of apertures or openings 1712 defined therein to facilitate air flow through the IPU 1700. A shape and/or size of the side panel 1710 and/or the openings 1712 can differ from the example shown in FIG. 17.

The electronic components 1704 generate heat during operation of the IPU 1700. To absorb and dissipate the heat generated by the electronic components 1704, the IPU 1700 includes one or more heat sinks 1714. The heat sink(s) 1714 can include a thermally conductive material such as aluminum or copper. The heat sink(s) 1714 include plates or fins that receive heat transferred from the electronic components 1704 and dissipate the heat into air flowing through the fins. In the example of FIG. 17, the heat sink 1714 of the IPU 1700 includes first fins 1716 having a first height and a second fins 1718 having a second height different than (e.g., greater than) the first fins 1716. The heat sink 1714 and/or the fins 1716, 1718 can have different sizes and/or shapes that the examples shown in FIG. 17. In some examples, the fins 1716, 1718 have the same height.

The heat sink 1714 is disposed over one or more of the electronic components 1704 such as a FPGA and a processor (e.g., a microprocessor) of the IPU 1700. Put another way, in the example orientation of the IPU 1700 shown in FIG. 17, the heat sink 1714 is above one or more of the electronic components 1704.

In the example of FIG. 17, a fan tray 1720 including a fan 1722 is removably coupled to the IPU 1700 to facilitate airflow over the heat sink 1714 (i.e., the fan 1722 provides means for circulating air). Although examples disclosed herein refer to fans to facilitate circulation of air, the fans can facilitate circulation of other mediums such as other types of gases (e.g., inert gases such nitrogen, helium, noble gases, etc.). For instance, the fans could facilitate flow of gases having a lower temperature than ambient temperature to cool the compute devices, where the low temperature gases can include air and/or other types of gases. The fan tray 1720 (also sometimes referred to herein as a fan assembly 1720) can be slidingly inserted or removed from the IPU 1700 via a slot 1724 defined in the side panel 1710 of the IPU 1700. In the example of FIG. 17, the fan tray 1720 can be moved (e.g., slid) over the portion of the heat sink 1714 including the first fins 1716. As disclosed herein, the example first fins 1716 of FIG. 17 have a lower height than the second fins 1718 of the heat sink 1714. Thus, in some examples, the lower height first fins 1716 define a travel path for the fan tray 1720 in the IPU 1700.

The slot 1724 can be defined in the side panel 1710 based on the location of the heat sink 1714 in the IPU 1700. Although the example IPU 1700 of FIG. 17 includes one slot 1724 to receive one fan assembly 1720, in some examples, the IPU 1700 can include one or more additional slots and/or slots sized to receive more than one fan assembly 1720. The number of slots 1724 and, thus, the number of fan assemblies 1720 carried by the IPU 1700, can be based on, for example, a size of the IPU 1700, an arrangement of the electronic components 1704 in the IPU 1700, a size and/or position of the heat sink(s) 1714 of the IPU 1700, etc.

The fan tray 1720 includes a first frame 1726 that defines a perimeter of the fan tray 1720. As disclosed herein, the first frame 1726 supports a second frame, housing, or shuttle 1738 including the fan 1722. As disclosed herein, the shuttle 1738 serves as means for transporting the fan 1722 in the PCIe card 1700. For example, the shuttle 1738 can use mechanical means or electromagnetic means to translate the fan 1722. The first frame 1726 can include a metal, a plastic, etc. A size and/or shape of the first frame 1726 can differ from the example shown in FIG. 17. The width and/or length of the first frame 1726 can be selected based on a size of the IPU 1700 (e.g., a six inch PCIe card, a 12 inch PCIe card).

The IPU 1700 includes electrical connectors that facilitate alignment of the fan tray 1720 in the IPU 1700 while providing power to the fan 1722 and/or other electronic components of the fan tray 1720 disclosed herein. In the example of FIG. 17, the electrical connectors include magnetic pogo pin connectors. For example, a first end 1728 of the first frame 1726 of the fan tray 1720 includes a connector or socket 1730. The IPU 1700 includes pins 1732 to couple with the connector 1730. As shown in FIG. 17, the pins 1732 can be coupled to a portion of the heat sink 1714 including the second fins 1718. In the example of FIG. 17, the pins 1732 include magnetic pogo pin contacts. Magnetic forces generated by the magnetic pogo pin contacts 1732 guide or facilitate alignment of the first frame 1726 in the IPU 1700 as the first frame 1726 is slid into the IPU 1700. Electrical connections (e.g., power connections) are established between the IPU 1700 and the electronic components of the fan tray 1720 when the magnetic pogo pin contacts 1732 are coupled to the connector 1730 of the fan tray 1720. For instance, power is provided to the fan 1722 based on the electrical coupling between the magnetic pogo pin contacts 1732 and the connector of the first frame 1726 (e.g., via cables or wires carried by the first frame 1726 and coupled to, for instance, a motor of the fan 1722).

A second end 1734 of the first frame 1726 includes one or more fasteners 1736 to further facilitate alignment and/or coupling of the fan tray 1720 to the IPU 1700. For example, the fastener(s) 1736 can include magnet(s) to mate with magnets on the side panel 1710. In some examples, fastener(s) 1736 include mechanical fastener(s) (e.g., screws, latches) to removably couple the first frame 1726 to the side panel 1710.

In the example of FIG. 17, the magnetic pogo pin connection and the fastener(s) 1736 are quick release connectors that permit the fan assembly 1720 to be removed from the IPU 1700 without affecting or substantially affecting an operational status of the electronic components 1704 of the IPU 1700 (e.g., without affecting operation of a processor of the IPU 1700). For example, the fan tray 1720 can be removed from the IPU 1700 to repair or replace the fan 1722 without disrupting or substantially disrupting performance of the IPU 1700. Rather than powering off the IPU 1700 to remove the fan 1722, the first frame 1726 of the fan tray 1720 can be pulled from the IPU 1700 via the slot 1724 defined in the side panel 1710 of the IPU 1700. Thus, the example fan tray 1720 of FIG. 17 provides for field replacement (e.g., “hot swapping”) of the fan 1722 without interfering or substantially interfering with operation of the IPU 1700, operation of the host server, etc.

In some examples, the IPU 1700 could additionally or alternatively include tracks disposed along the travel path of the fan tray 1720 in the IPU 1700 to facilitate movement and alignment of the fan tray 1720. In such examples, one or more exterior surfaces of the first frame 1726 could include, for instance, rollers to move along the tracks.

When the fan tray 1720 is disposed in the IPU 1700 and the fan 1722 is operating such that blades 1740 of the fan 1722 are rotating, the fan 1722 pulls in air from the ambient environment via the opening 1708 in the housing 1706 and the openings 1712 in the side panel 1710 (e.g., an IO bracket) to increase airflow over and/or through the heat sink 1714. The blades 1740 of the fane 1722 can have a paddle board shape to push air through the IPU 1700. A size and/or shape of the fan 1722 or the fan blades 1740 can differ from the example shown in FIG. 17.

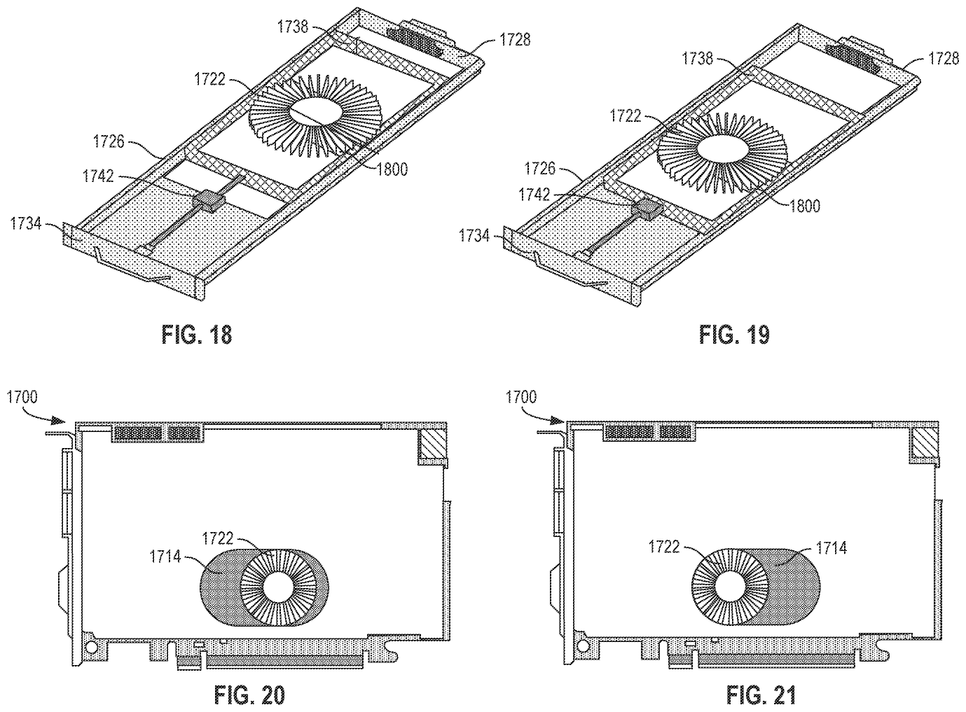

The fan 1722 is carried by the second frame or shuttle 1738 of the fan tray 1720. A transverse material or base 1800 (FIG. 18) extends across a portion of a width of the shuttle 1738 support the fan 1722. As disclosed herein, the shuttle 1738 is moveable (e.g., slidable) relative to the first frame 1726 of the fan tray 1720 to enable the base 1800 of the fan 1722 to be positioned (e.g., moved or translated along an X-Y plane) and, thus, the fan 1722 to positioned, at different locations along the heat sink 1714 (e.g., the portion of the heat sink 1714) including the first fins 1716. In particular, the fan 1722 can be positioned at location(s) relative to area(s) of the heat sink 1714 for which increased airflow would enhance cooling of the electronic component(s) 1704 of the IPU 1700.

The example fan tray 1720 includes means for moving the shuttle 1738 and, thus, the fan 1722 (i.e., the base 1800 of the fan 1722). In the example of FIG. 17, the fan tray 1720 includes an actuator 1742 to move the shuttle 1738. The actuator 1742 can include a linear actuator, a stepper motor, a servo motor, etc. A portion of the first frame 1726 of the fan tray 1720 supports a base 1744 to support the actuator 1742. The actuator 1742 can push or pull the shuttle 1738 to position the fan 1722 (e.g., the base 1800 of the fan 1722) at particular locations relative to the heat sink 1714. For instance, an interior surface 1746 of the first frame 1726 can include tracks (e.g., power rails) along which the shuttle 1738 slides. In some examples, an opposing exterior surface 1748 of the shuttle 1738 includes rollers to move along the tracks on the first frame 1726 to facilitate movement of the shuttle 1738 via the actuator 1742. In some examples, the tracks of the first frame 1726 include electromagnets that generate a magnetic field in response to current provided by the coupling of magnetic pogo contacts 1732 with the connector 1730 of the first frame 1726. The electromagnets can be selectively activated or deactivated to cause the shuttle 1738 to move based on attractive magnetic forces in addition to or as an alternative to the actuator 1742.

Although the example fan tray 1720 of FIG. 17 includes one fan 1722, the fan tray 1720 could include more than one fan 1722. For instance, two fans 1722 could be carried by the shuttle 1738. The number of fans 1722 of the fan assembly 1720 can be selected based on a size of the IPU 1700, a size of the heat sink 1714, etc. Also, a size and/or shape of the fan shuttle 1738 can differ from the example shown in FIG. 17.

The example IPU 1700 includes fan control circuitry 1750. The fan control circuitry 1750 generates instructions to control operational parameters of the fan 1722 such as speed at which the fan rotates. In the example of FIG. 17, the fan control circuitry 1750 generates instructions to cause the actuator 1742 to move the shuttle 1738 and, thus, the fan 1722 relative to the heat sink 1714. The fan control circuitry 1750 can be implemented by processor circuitry (e.g., dedicated processor circuitry) of the IPU 1700. The fan control circuitry 1750 can communicate with the components of the fan tray 1720 (e.g., a motor of the fan 1722, the actuator 1742) via wireless or wired communication protocols (e.g., wired connections established between the IPU 1700 and the fan tray 1720 as a result of the magnetic pogo pin coupling).

The example IPU 1700 includes temperature sensors 1752 to monitor a temperature of the electronic component(s) 1704 of the IPU 1700 such as a FPGA, a microprocessor, etc. The temperature sensors 1752 can be carried by the board 1702, can be coupled to or integral with the electronic component(s) 1704 and/or the heat sink 1714, etc. In some examples, the temperature sensor(s) 1752 are carried by one or more of the first frame 1720 or the second frame 1738 of the tray 1720. In some examples, the temperature sensors 1752 are carried by the board 1702 and/or the tray 1720 such that the temperature sensors 1752 are in communication with the electronic component(s) 1704 and/or the heat sink 1714 (e.g., detect air temperature of an area including the electronic component(s) 1704 and/or the heat sink 1714). Power consumption and, thus, heat generated, can increase based on workloads performed by, for instance, the FPGA, the processors, etc. of the IPU 1700. The fan control circuitry 1750 analyzes the signals output by the temperature sensors 1752 indicative of temperatures at different locations of the IPU 1700. In some examples, the signals output by the temperature sensor(s) 1752 are indicative of local temperature associated with the IPU 1700 (e.g., a temperature of a particular electronic component 1704, a temperature of a portion of the IPU 1700). In some examples, the signals output by the temperature sensor(s) 1752 can be used to determine a bulk temperature of the IPU 1700. In some examples, the fan control circuitry 1750 determines a temperature gradient across the portion of the IPU board 1702 covered by the heat sink 1714 (e.g., which can include the portion of the board 1702 that carries the FPGA and/or the processor(s)) based on outputs of the temperature sensors 1752. The fan control circuitry 1750 identifies area(s) of the IPU 1700 associated with increased temperature (i.e., heat) relative to other area(s) of the IPU 1700. The area(s) of the example peripheral card(s) disclosed herein (e.g., the IPU 1700) that are associated with increase temperature relative to other area(s) of the peripheral card(s) are sometimes referred to herein as hot spot(s).

The fan control circuitry 1750 generates instructions to cause the actuator 1742 to move the shuttle 1738 to position the fan 1722 (e.g., the base 1800 of the fan 1722) relative to the area(s) of the heat sink 1714 that are proximate to (e.g., disposed over) the electronic components 1704 of the IPU 1700 that are responsible for the increased heat. In some examples, the fan control circuitry 1750 instructs the actuator 1742 to position the fan 1722 at a particular location relative to the heat sink 1714 in response to determining that certain area(s) of the IPU 1700 are associated with a temperature that exceeds a temperature threshold (e.g., a predefined temperature threshold). When the fan 1722 is located proximate to the hot spot(s), the fan 1722 augments airflow over the heat sink 1714 at those locations, thereby providing for increased cooling of the electronic component(s) 1704 associated with the hot spot(s).

In some examples, the fan tray 1720 includes one or more fan operating parameters sensors 1754 to output signals indicative of operating parameters of the fan 1722. The fan operating parameters sensor(s) 1754 can include, for instance, a tachometer to measure rotational speed of the fan 1722. The fan operating parameters sensor(s) 1754 can include, for instance, position sensor(s) to identify a location of the fan 1722 relative to the IPU 1700. The fan control circuitry 1750 can generate instructions to control the rotational speed of the fan 1722 based on outputs from the fan operating parameters sensor(s) 1754 and in view of, for instance, the temperature measurements for the IPU 1700.

The fan control circuitry 1750 monitors changes in temperature at the IPU 1700 over time and determines if the rotational speed of the fan 1722 and/or the location of the fan 1722 relative to the heat sink 1714 should be adjusted. For example, the fan control circuitry 1750 can detect changes in the area(s) of the IPU board 1702 associated with increased heat due to workloads performed by the electronic component(s) 1704 of the IPU 1700 at those area(s). Thus, the fan control circuitry 1750 detects changes in the locations of the hot spots at the IPU 1700 over time. In some examples, the fan control circuitry 1750 determines average temperatures of different areas of the IPU 1700 over time and selects a location(s) for the fan 1722 to be positioned at based on the average temperatures. The fan control circuitry 1750 outputs instructions to cause the actuator 1742 to move (e.g., reposition) the shuttle 1738 and, thus, the fan 1722, based on changes in the location(s) of the hot spot(s). Additionally or alternatively, the fan control circuitry 1750 can instruct the fan 1722 to move to different location relative to the heat sink 1714 based on a duration of time for which the fan 1722 has been at particular location.

The example fan control circuitry 1750 can also control a direction of rotation of the fan 1722 to maximize airflow through the IPU 1700. In some examples, the IPU 1700 can be coupled to a server supported by a rack (e.g., the IPU 1700 is inserted into a slot or card receiver of the server). The rack can include fan(s) to cool the server. In some examples, based on the mounting configuration of the IPU 1700 in the server and/or the rotational direction of the rack fan(s), air is pulled into the IPU 1700 via the openings 1712 of the side panel 1710 (e.g., a front panel) and travels across the IPU 1700 in a first direction. In some examples, air enters via a side (e.g., a rear panel, not shown) of the IPU 1700 opposite the side panel 1710 and travels across the IPU 1700 in a second direction opposite the first direction.

The IPU 1700 can include the temperature sensors 1752 located proximate to the side panel 1710 (e.g., the front panel) of the IPU 1700 and at the opposite side (e.g., the rear panel). Based on the outputs of the temperature sensors 1752, the fan control circuitry 1750 detects a direction of the airflow through the IPU 1700. For example, when a temperature gradient across the IPU board 1702 indicates that the temperature of the IPU 1700 at the front or side panel 1710 (is lower than the temperature of the IPU 1700 at the rear panel, the fan control circuitry 1750 determines that the air is being pulled into the IPU 170 via the openings 1712 in the side panel 1710. The fan control circuitry 1750 outputs instructions to cause the blades 1740 of the fan 1722 to rotate in a particular direction (e.g., clockwise or counter clockwise) based on the direction of airflow through the IPU 1700. The rotational direction of the blades 1740 of the fan 1722 can be selected to enable the fan blades 1740 to guide the flow of air through the IPU 1700 rather than move against the direction of airflow. The instructions for rotational directional control can be executed by, for instance, the motor and/or rotor drive circuitry of the fan 1722. In some examples, the fan control circuitry 1750 additionally or alternatively controls rotational speed of the fan 1722 based on the airflow direction.

The fan control circuitry 1750 can monitor a performance of the fan 1722 over time. For example, based on the outputs of the fan operating parameter sensor(s) 1754 (e.g., the tachometer) and/or the temperature sensor(s) 1752, the fan control circuitry 1750 can detect a failure state or a potential failure state of the fan 1722 (e.g., if the blades 1740 of the fan 1722 re not rotating, or are rotating at a speed below a threshold speed, and if the temperature of the component(s) of the peripheral 1700 proximate to the fan 1722 is increasing when cooling by the fan 1722 is otherwise expected). To prevent the fan 1722 from hindering airflow when the fan 1722 is in a failed state or potential failed state, the fan control circuitry 1750 generates instructions to cause the fan 1722 (e.g., the fan motor) to stop operating. The fan control circuitry 1750 can also instruct the actuator 1742 to move the fan 1722 (e.g., translate the fan base 1800) to a location at which the fan 1722 interferes the least with the flow of ambient air into the IPU 1700. For example, the fan control circuitry 1750 can instruct the actuator 1742 to move the shuttle 1738 so that the fan 1722 is located proximate to one of the ends of the opening 1708 of the housing 1706 (rather than in the middle of the opening 1708) to maximize airflow through the opening 1708.

In some examples, if the fan control circuitry 1750 detects that the fan 1722 has failed or at risk of failing, the fan control circuitry 1750 can cause power and/or electrical connections provided to the fan tray 1720 to cease. As such, the electrical couplings between the fan tray 1720 and the IPU 1700 are disrupted and the fan tray 1720 can be removed from the IPU 1700 (e.g., slid out of the IPU 1700 via the slot 1724).

In examples which the fan control circuitry 1750 detects that the fan 1722 has failed or at risk of failing, the fan control circuitry 1750 can cause alert(s) (e.g., audio alerts, visual alerts) to be output to inform, for instance, a data center operator of the potential for fan maintenance. In some such examples, the fan control circuitry 1750 communicates with the electronic component(s) 1704 of the IPU (e.g., FPGA, the processor(s)) to cause power consumption by the IPU 1700 to be reduced or capped to lower the amount of heat generated by the component(s) 1704 until the fan 1722 is repaired or replaced. Thus, the IPU 1700 can continue to operate without the airflow augmentation provided by the fan 1722, which provides for substantially less disruption than if the IPU 1700 was powered down to address the failed fan 1722.

FIGS. 18 and 19 illustrate movement of the shuttle 1738 of the example fan tray 1720 of FIG. 17 and, thus, the fan 1722 carried by the shuttle 1738. For illustrative purposes, the IPU 1700 is not shown in FIG. 17. The fan 1722 is supported by the base 1800. The base 1800 can have a different shape and/or size than shown in FIGS. 18 and 19. As illustrated in FIGS. 18 and 19, the actuator 1742 causes the shuttle 1738 to move relative to (e.g., along a length of) the first frame 1726 of the fan tray 1720. For instance, in FIG. 18, the actuator 1742 has pushed the shuttle 1738 away from the second end 1734 of the first frame 1726 and toward the first end 1728 of the first frame 1726. In the example of FIG. 19, the actuator 1742 has pulled the shuttle 1738 toward to the second end 1734 of the first frame 1726 and away from the first end 1728 of the first frame 1726. As disclosed herein, in some examples, the shuttle 1738 slides along the rails or tracks of the first frame 1726.

FIGS. 20 and 21 are top views of the example IPU 1700 of FIG. 17 including the example fan assembly or tray 1720 of FIGS. 17-19 disposed therein. In particular, FIG. 20 illustrates the fan 1722 (e.g., the fan base 1800) of the fan assembly 1720 in a first position relative to the heat sink 1714. The first position of the fan 1722 can be selected by the fan control circuitry 1750 based on a location of a hot spot of the IPU 700, or an area of increased heat generated at the IPU 1700 due to performance of the electronic component(s) 1704 (e.g., the FPGA) of the IPU 1700 located at or proximate to the area.

FIG. 21 illustrates the fan 1722 (e.g., the fan base 1800) of the fan tray 1720 in a second position relative to the heat sink 1714 different than the first position shown in FIG. 20. The fan control circuitry 1750 can cause the fan 1722 to move from the first position of FIG. 20 to the second position of FIG. 21 based on changes in the temperature of various location in the IPU 1700 (e.g., changes in locations of hot spots at the IPU 1700). For example, the fan control circuitry 1750 can instruct the actuator 1742 to move the shuttle 1738 to cause the base 1800 (FIG. 18) of the fan 1722 to move from the first position of FIG. 20 to the second position of FIG. 21 in response to an increase in heat generated by the electronic component(s) 1704 of the IPU 1700 that are proximate to the location of fan 1722 in FIG. 21 as compared to the amount of heat generated by the electronic component(s) 1704 of the IPU 1700 that are proximate to the fan 1722 at the location of the fan 1722 in FIG. 20.

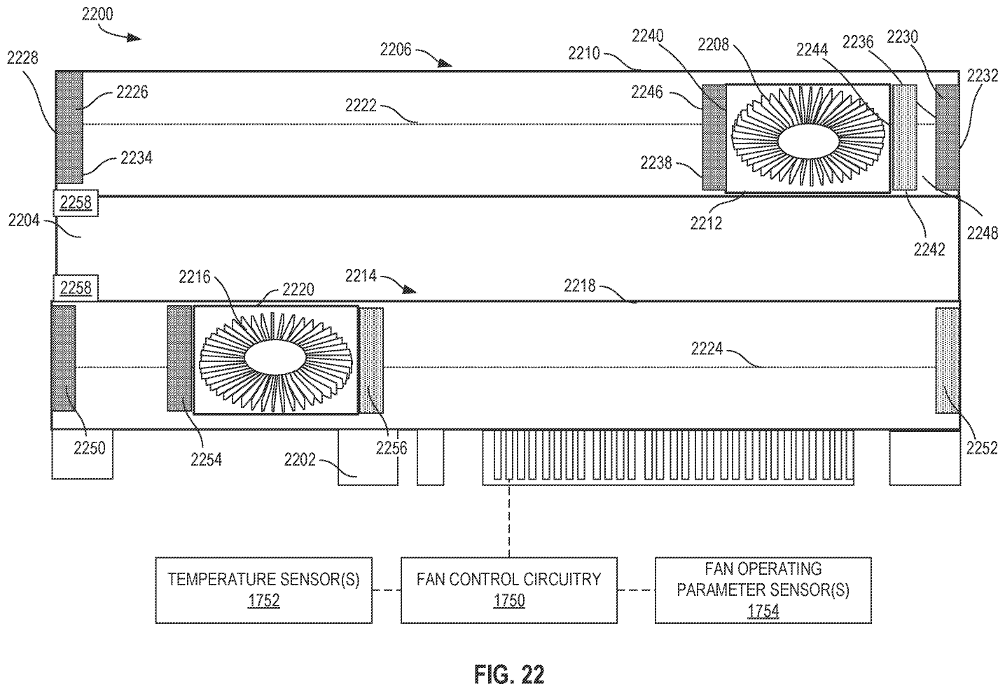

FIG. 22 illustrates another example peripheral 2200 including a field replaceable fan assembly in accordance with teachings of this disclosure. In the example of FIG. 22, the peripheral 2200 is a component interconnect express (PCIe) card that implements a graphics card including a graphics processing unit (GPU). In the foregoing discussion of FIG. 22, the PCIe card 2200 will be referred to as the graphics card 2200. Although the example of FIG. 22 is disclosed in connection with the graphic card 2200, the example of FIG. 22 could be used with other types of PCIe cards.

FIG. 22 is a top view of the graphics card 2200. For illustrative purposes, a housing of the graphics card 2200 (e.g., the housing 1706 of FIG. 17) is not shown in FIG. 22. The graphics card 2200 include a board 2202 that supports electronic components of the graphics card 2200 (e.g., the GPU). The electronic component(s) of the graphics card 2200 generate heat during operation of the component(s). The example graphics card 2200 includes a heat sink 2204 to absorb and dissipate the heat generated by the electronic component(s).

The example graphics card 2200 of FIG. 2 includes fans to augment airflow over the heat sink 2204 to increase cooling. A first fan tray 2206 (also referred to as a fan assembly 2206) is disposed over a first portion of the heat sink 2204. The first fan tray 2206 includes a fan 2208. The first fan tray 2206 includes a first frame 2210 and a second frame or shuttle 2212 moveable relative to the first frame 2210 of the first fan tray 2206. The first shuttle 2212 carries the first fan 2208 as substantially as disclosed in connection with FIG. 17. For instance, the first fan 2208 can be supported by the base 1800 (FIG. 18).

A second fan assembly or fan tray 2214 is disposed over a second portion of the heat sink 2204 different than the first portion over which the first fan tray 2206 is located. The second fan tray 2214 includes a fan 2216. The second fan tray 2214 includes a first frame 2218 and a second frame or shuttle 2220 moveable relative to the first frame 2218 of the second fan tray 2214. The first shuttle 2220 carries the fan 2216 as substantially as disclosed in connection with FIG. 17 (e.g., via the fan base 1800).

A location of the first fan tray 2206 and/or the second fan tray 2214 relative to the heat sink 2204 can differ from the example locations shown in FIG. 22. Also, although in the example of FIG. 22, the trays 2206, 2214 substantially extend a length of the heat sink 2204, in other example, a size and/or shape of the respective fan trays 2206, 2214 can differ from the example shown in FIG. 22. Also, a size and/or shape of the fans 2208, 2216 can differ from the examples shown in FIG. 22. The graphics card 2200 can include additional fan trays 2206, 2214 and/or fans 2208, 2216 than shown in FIG. 22 based on, for instance, a size of the heat sink 2204 of the graphics card 2200.

The fan trays 2206, 2214 can be removably coupled to the graphics card 2200 via opening(s) formed in a housing of graphics card 2200 (e.g., a slot formed in a side panel of the graphics card 2200 as disclosed in connection with the example of FIG. 17). The fan trays 2206, 2214 can include power pin sockets or connectors to mate with corresponding contacts (e.g., pogo pins) in the graphics card 2200. As such, electrical connections can be formed between the fan trays 2206, 2214 and the graphics card 2200 to provide, for instance, power to the fans 2208, 2216 substantially as disclosed in connection with the example of FIG. 17.

In the example of FIG. 22, the first tray 2206 includes a track 2222 and the second tray 2214 includes a second track 2224. The shuttle 2212 of the first fan tray 2206 is moveable along the track 2222 to translate the fan 2208 (e.g., move the fan base 1800) of the first fan tray 2206 relative to the heat sink 2204. Also, the shuttle 2220 of the second fan tray 2214 is moveable along the track 2224 of the second fan tray 2214 to translate the fan 2216 (e.g., move the fan base 1800) of the second fan tray 2214 relative to the heat sink 2204. In the example of FIG. 22, the respective shuttles 2212, 2220 move in response to instructions output by the fan control circuitry 1750 of the graphics card 2200. The fan control circuitry 1750 can communicate with the components of the fan trays 2206, 2214 via wireless or wired communication protocols.

In some examples, each of the tracks 2222, 2224 is a single rail and the corresponding shuttles 2212, 2220 are slidingly coupled to the rail (e.g., via rollers, via an extruded channel formed in a bottom of the fan shuttle 2212, 2220 that mates with the rail). In some examples, each of the tracks 2222, 2224 include two rails and the corresponding shuttles 2212, 2220 are slidingly coupled to the two rails. In some examples, the tracks 2222, 2224 (e.g., power rails) carry power to the fans 2208, 2216 and/or include cables to establish electrical connections between the fan control circuitry 1750 and the fans 2208, 2216 (e.g., motors of the fans 2208, 2216). In some examples, one or more portions of the tracks 2222, 2224 include openings or channels extending through the tracks 2222, 2224. The channels can help direct airflow generated by the fans 2208, 2216.

In the example of FIG. 22, the first frame 2210 of the first fan tray 2206 includes a first tray magnet 2226 coupled to a first interior end 2228 of the first frame 2210 and a second tray magnet 2230 coupled to a second interior end 2232 of the frame 2210 opposite the first interior end 2228. In the example of FIG. 22, the tray magnets 2226, 2230 are located on an interior surface of the first frame 2210 of the first tray 2206 such a surface 2234 of the first tray magnet 2226 faces the first fan 2208 and a surface 2236 of the second tray magnet 2230 each face the shuttle 2212 of the first fan tray 2206. The first and second tray magnets 2226, 2230 can include electromagnets.

Also, the shuttle 2212 of the first fan tray 2206 includes a first shuttle magnet 2238 coupled to a first end 2240 of the shuttle 2212 and a second shuttle magnet 2242 coupled to a second end 2244 of the shuttle 2212 opposite the first end 2240. A surface 2246 of the first shuttle magnet 2238 faces the surface 2234 of the first tray magnet 2226. The surface 2246 of the first shuttle magnet 2238 is associated with a first polarity. A surface 2248 of the second shuttle magnet 2242 faces the surface 2236 of the second tray magnet 2230. The surface 2248 of the second shuttle magnet 2242 is associated with a second polarity opposite the first polarity of the surface 2246 of the first shuttle magnet 2238.

The first frame of the second fan tray 2214 includes a first tray magnet 2250 and a second tray magnet 2252 as disclosed above in connection with the first fan tray 2206. The first and second tray magnets 2250, 2252 can include electromagnets. Also, the shuttle 2220 of the second fan tray 2214 includes a first shuttle management 2254 and a second shuttle magnet 2256 as disclosed above in connection with the first fan tray 2206.

In the example of FIG. 22, the fan control circuitry 1750 of the graphics card 2200 controls a polarity of the respective tray magnets 2226, 2230 of the first fan tray 2206 to cause the shuttle 2212 and, thus, the first fan 2208, to translate or move along the first track 2222 based on attractive or repelling magnetic forces between the respective tray magnets 2226, 2230 of the first frame 2210 and the corresponding shuttle magnets 2238, 2242. Also, the fan control circuitry 1750 controls a polarity of the respective tray magnets 2250, 2252 of the second fan tray 2214 to cause the shuttle 2220 to translate or move the second fan 2216 along the second track 2224 based on attractive or repelling magnetic forces between the respective tray magnets 2250, 2254 of the first frame 2218 of the second fan tray 2214 and the corresponding shuttle magnets 2254, 2256. Put another way, in the example of FIG. 22, the tray magnets 2226, 2230, 2250, 2252 serve as actuators to cause the shuttles 2212, 2220 to move.

The graphics card 2200 include the temperature sensors 1752 to measure the temperature of the graphics card 2200 at different locations in the graphics card 2200. The fan control circuitry 1750 analyzes the temperature data corresponding to the outputs of the temperature sensors 1752 to identify hot spots at the graphics card 2200. For example, the fan control circuitry 1750 can determine, based on the temperature sensor data, that an electronic component of the graphics card 2200 proximate to the second end 2232 of the first frame 2210 of the first fan tray 2206 is generating an increased amount of heat relative to other electronic components associated with the portion of the heat sink 2204 over which the first fan tray 2206 extends. As such, the fan control circuitry 1750 outputs instructions to cause the shuttle 2212 to move to the second end 2232 of the first frame 2210 so that the first fan 2208 can increase airflow over the portion of the heat sink 2204 proximate to the second end 2232 of the first frame 2212.

In particular, in the example of FIG. 22, the fan control circuitry 1750 causes the second tray magnet 2230 of the first fan tray 2206 to have a polarity that is opposite a polarity of the second shuttle magnet 2242 of the shuttle 2212 (e.g., by affecting a direction of a current provided to the second magnet 2230). Due to the opposing polarities, the second shuttle magnet 2242 of the shuttle 2212 is attracted to the second tray magnet 2230. The shuttle 2212 including the first fan 2208 is pulled along the first track 2222 toward the second tray magnet 2230 due to attracting magnetic forces between the tray and shuttle magnets 2230, 2242. As a result, the second shuttle magnet 2242 couples with the second tray magnet 2230 and the first fan 2208 is located proximate to the hot spot.

In some examples, when the second shuttle magnet 2242 is coupled with the second tray magnet 2230, the fan control circuitry 1750 determines, based on temperature sensors 1752 of the graphics card 2200 that an electronic component proximate to the first end 2228 of the first frame 2210 of the first fan tray 2206 is generating an increased amount of heat relative to other electronic components over which the heat sink 2204 extends. In this example, the fan control circuitry 1750 can cause a polarity of the first tray magnet 2226 of the first frame 2210 to have a polarity that is opposite the polarity of the first shuttle magnet 2238 of the shuttle 2212 (e.g., by affecting a direction of current flowing through the first tray magnet 2226). Also, the fan control circuitry 1750 can cause a polarity of the second tray magnet 2230 of the first frame 2210 of the first fan tray 2206 to have a polarity that is the same as the polarity of the second shuttle magnet 2242 of the shuttle 2212. As a result, the second tray magnet 2230 and the second shuttle magnet 2242 repel each other. Thus, the second shuttle magnet 2242 uncouples from the second tray magnet 2230. Put another way, the second end 2244 of the first shuttle 2212 is pushed away from the second tray magnet 2230 along the track 2222 due to repelling magnetic forces. Also, the first end 2240 of the shuttle 2212 including the first shuttle magnet 2238 is pulled along the track 2222 toward the first tray magnet 2226 by the attracting magnetic forces between the first tray and first shuttle magnets 2226, 2238. The first shuttle magnet 2238 couples with the first tray magnet 2226 and the first fan 2208 is located proximate to the first end 2228 of the first frame 2210 to provide for increased cooling.

In some examples, the fan control circuitry 1750 causes current to the second tray magnet 2230 to turn off, rather than change polarity. When the second tray magnet 2230 is turned off, the second tray magnet 2230 no longer generates the magnetic field. As a result, the second shuttle magnet 2242 uncouples from the second tray magnet 2230 and the shuttle 2212 can be pulled toward the second tray magnet 2226.

Thus, in the example of FIG. 22, the fan control circuitry 1750 causes the first fan 2208 to be moved proximate to area(s) of the graphics card 2200 associated with increased heat (i.e., hot spots) by controlling attracting or repelling magnetic forces between the respective ones of the tray magnets 2226, 2230 and corresponding ones of the shuttle magnets 2238, 2230. The shuttle 2212 and, thus, the first fan 2208 of the first fan tray 2206 is selectively pushed and/or pulled along the track 2222 due to the magnetic forces.

In some examples, the first fan 2208 (e.g., the fan base 1800) can be positioned along intermediate positions of the track 2222 between the first and second ends 2228, 2232 of the first frame 2210. For example, the fan control circuitry 1750 can adjust a polarity of the first and second tray magnets 2226, 2230 of the first fan tray 2206 such that (a) the first tray magnet 2226 and the first shuttle magnet 2238 of the shuttle 2212 are opposite polarities and (b) the second tray magnet 2230 and the second shuttle magnet 2242 of the shuttle 2212 are opposite polarities. The fan control circuitry 1750 can adjust a strength of the current flowing through the tray magnets 2226, 2230 and, thus, a strength of the magnetic forces generated by the magnets 2226, 2230. As a result of (a) the opposing magnetic forces between the first tray magnet 2226 and the first shuttle magnet 2238 and (b) the opposing magnetic forces between the second tray magnet 2230 and the second shuttle magnet 2242, the shuttle 2212 and, thus, the fan 2208, can be held by the magnetic forces at a particular intermediate position along the track 2222.

In some examples, the track 2222 of the first fan tray 2206 includes electromagnets disposed along a length of the track 2222. The fan control circuitry 1750 can cause the electromagnets to be selectively activated or deactivated to cause the shuttle 2212 to move along the track 2222 and be held at certain intermediate positions along the track 2222 based on the locations of the hot spots of the graphics card 2200. In some such examples, the shuttle 2212 can include magnets disposed along a surface of the shuttle 2212 that faces the track 2222 and are attracted or repelled from the track magnets.

The shuttle 2220 carrying the second fan 2216 can move along the second track 2224 of the second fan tray 2214 in the same or substantially the same manner as disclosed above in connection with the shuttle 2212 of the first fan tray 2206 based on control of magnetic forces between the tray magnets 2250, 2252 and corresponding ones of the shuttle magnets 22254, 2256. For example, when the fan control circuitry 1750 determines that a hot spot is located at the portion of the graphics card 2200 over which the second fan tray 2214 is located, the fan control circuitry 1750 can cause the shuttle 2220 of the second fan tray 2214 to move along the second track 22224 to provide increased airflow over the heat sink 2204 at the hot spot location.

Thus, the locations of the first and second fans 2208, 2216 can be selected to maximize or substantially maximize airflow over the heat sink 2204 to target hot spots at the graphics card 2200. In some examples, the fan control circuitry 1750 causes the first fan 2208 to move relative to the second fan 2216 or vice versa. The fan control circuitry 1750 monitors changes in the temperature of the graphics card 2200 due to heat generated by the electronic components of the graphics card 2200 over time to identify changes in the locations of the hot spots and to cause the first fan 2208 and/or the second fan 2216 to translate (e.g., move the respective fan bases 1800) to provide for increased cooling at the identified locations. In some examples, the fan control circuitry 1750 causes the fans 2208, 2216 to move based on a duration of time for which the fans 2208, 2216 have been at a particular location relative to the heat sink 2204 to provide for dynamic increases in cooling provided by the fans 2208, 2216 across the heat sink 2204 during operation of the graphics card 2200. In some examples, the fan control circuitry 1750 causes the shuttles 2212, 2220 of the respective fan trays 2206, 2214 to move at the same time or substantially the same time. In some examples, the fan control circuitry 1750 causes the shuttles 2212, 2220 to move at different times.

In some examples, when the first fan 2208 is located proximate to, for instance, the first end 2228 of the first frame 2210 of the first fan tray 2206 (e.g., the first tray magnet 2226 is coupled to the first shuttle magnet 2238), the fan control circuitry 1750 generates instructions to cause the shuttle 2220 of the second fan tray 2214 to move the second fan 2216 (e.g., the fan base 1800) to the end of the second tray 2214 that is opposite the end at which the first fan 2208 is located in the first fan tray 2206 (i.e., cause the second tray magnet 2252 of the second fan tray 2214 to couple with the second shuttle magnet 2256 of the shuttle 2220). In such examples, the first fan 2208 and the second fan 2216 are located diagonally or substantially diagonally across the heat sink 2204. As a result of the opposite locations of the fans 2208, 2216, relative to the heat sink 2204, airflow over the heat sink 2204 is increased across an area of the heat sink 2204 as compared to if both fans 2208, 2216, were located on the same side of the heat sink 2204. The fan control circuitry 1750 can identify or track the locations of the fans 2208, 2216 based on outputs from the fan operating parameters sensor(s) 1754 (e.g., position sensors).

The fan control circuitry 1750 can generate instructions to control a rotational speed of blades of each of the fans 2208, 2216 and communicate the instructions to, for instance, drive circuitry and/or a motor of the respective fans 2208, 2216. The fan control circuitry 1750 can detect when the rotational speed of the blades of the respective fans 2208, 2216, is below a threshold based on outputs of the fan operating parameter sensor(s) 1754, which can indicate a failure state of one or more of the fans 2208, 2216 (e.g., in some instance, in connection with increase in temperature at the peripheral 1700). In such examples, the fan control circuitry 1750 can cause an alert (e.g., an audio alert, a visual alert) to be output to notify, for instance, a data center operator that the fan(s) 2208, 2216 may need to be repaired or replaced. For example, each of the fan trays 2206, 2214 can include a light emitting diode (LED) 2258 and the fan control circuitry 1750 can cause the LED to be activated when the fan 2208, 2216 of a particular tray 2206, 2214, is rotating below a threshold RPM speed to provide a visual alert as to the operational status of the fan 2208, 2216.

The fan control circuitry 1750 can generate instructions to control a rotational direction of the blades of each of the fans 2208, 2216 and communicate the instructions to, for instance, drive circuitry and/or a motor of the respective fans 2208, 2216. In some examples, the fan control circuitry 1750 instructs the blades of the first fan 2208 to rotate in a first direction and the blades of the second fan 2216 to rotate in a second or counter direction. As a result, the first fan 2208 can, for instance, pull cool air from the ambient environment into the graphics card 2200 and the second fan 2216 can push hot air generated in the graphics card 2200 out of the graphics card 2200. Thus, temperature gradients across the graphics card 2200 (e.g., across the heat sink 2204) are minimized. In other examples, the fan control circuitry 1750 can cause both fans 2208, 2216 to rotate in the same direction.

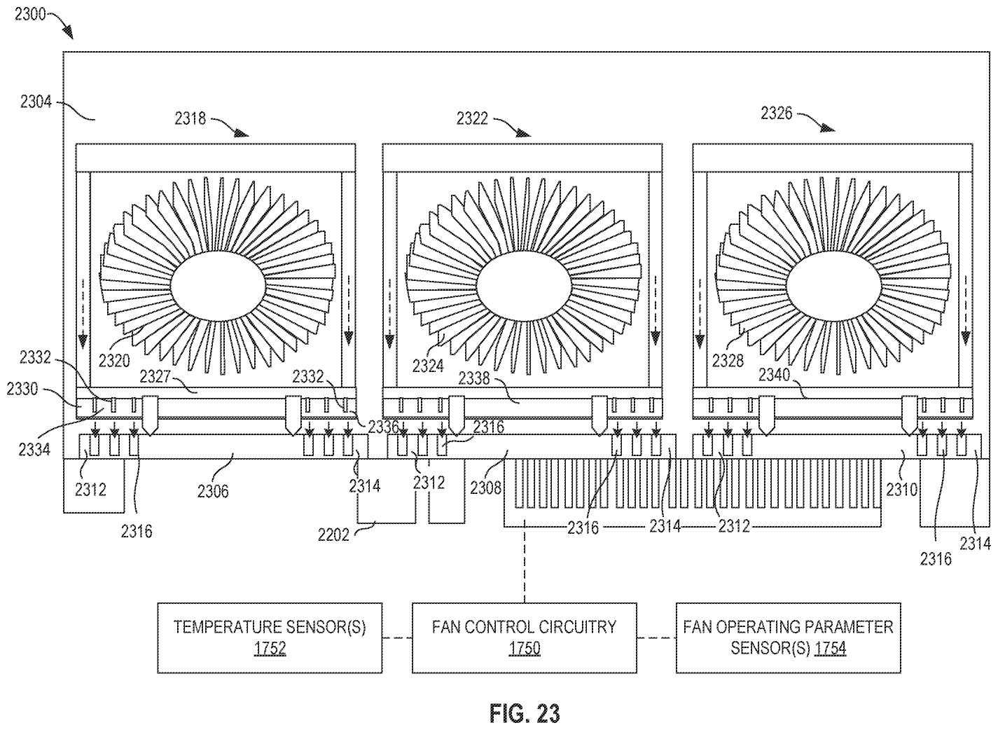

FIG. 23 illustrates another example peripheral 2300 including a field replaceable fan assembly in accordance with teachings of this disclosure. In the example of FIG. 23, the peripheral 2300 is a component interconnect express PCIe card that implements a graphics card including a graphics processing unit (GPU). In the foregoing discussion of FIG. 23, the PCIe card 2300 will be referred to as the graphics card 2300. Although the example of FIG. 23 is disclosed in connection with the graphic card 2300, the example of FIG. 23 could be used with other types of PCIe cards.

FIG. 23 is a top view of the graphics card 2300. For illustrative purposes, a housing of the graphics card 2300 (e.g., the housing 1706 of FIG. 17) is not shown in FIG. 23. The graphics card 2300 include a board 2302 that supports electronic components of the graphics card 2300 (e.g., the GPU). The electronic component(s) of the graphics card 2300 generate heat during operation of the component(s). The example graphics card 2300 includes a heat sink 2304 to absorb and dissipate the heat generated by the electronic component(s).

The graphics card 2300 includes a first card magnet 2306, a second card magnet 2308, and a third card magnet 23010. The card magnets 2306, 2308, 2310 can be supported by, for instance, the board 2302, an interior surface of the housing of the graphics card 2300 (e.g., an interior surface of a sidewall defining the housing), etc. The card magnets 2306, 2308, 2310 can include pole bar magnets, where each card magnet 2306, 2308, 2310 has a first pole 2312 having a first polarity and a second pole 2314 having a second polarity opposite the first polarity. In some examples, the card magnets 2306, 2308, 2310 include electromagnets.

As shown in FIG. 23, the card magnets 2306, 2308, 2310 are located proximate to an edge of the heat sink 2304. As disclosed herein, the card magnets 2306, 2308, 2310 are positioned in the graphics card 2300 relative to the heat sink 2304 such that a tray including a fan can be slid over the heat sink 2304 and coupled to one of the card magnets 2306, 2308, 2310 to provide for increased airflow over the heat sink 2304.

In the example of FIG. 23, each of the card magnets 2306, 2308, 2310 include one or more power supply pins 2316. For example, in FIG. 23, each of the card magnets 2306, 2308, 2310 includes six power supply pins 2316. However, the card magnets 2306, 2308, 2310 could include additional or fewer power supply pins 2316. Also, a shape and/or size of the card magnets 2306, 2308, 2310 can differ from the examples shown in FIG.

23.

In the example of FIG. 23, each of the magnets 2306, 2308, 2310 provide means for aligning a tray including a fan in the graphics card 2300. As shown in FIG. 23, a first fan assembly or tray 2318 includes a first fan 2320. A second fan assembly of tray 2322 includes a second fan 2324. A third fan assembly or tray 2326 includes a third fan 2328. The trays 2318, 2322, 2326 and/or the fans 2320, 2324, 2328 can have different sizes and/or shapes than the examples of FIG. 23. The fans 2320, 2324, 2328 can be supported in the trays 2318, 2322, 2326 by respective bases (e.g., the base 1800 of FIG. 18) as disclosed in connection with FIGS. 17-22. The example graphics card 2300 can include additional or fewer fan trays 2318, 2322, 2326 and corresponding card magnets 2306, 2308, 2310 to support the trays in the graphics card 2300.

The first fan tray 2318 will be disclosed in detail with the understanding that the second fan tray 2322 and the third fan tray 2326 are the same or substantially the same as the first fan tray 2318. An exterior surface 2327 of the first fan tray 2318 includes a tray magnet 2330 coupled thereto. The tray magnet 2330 includes power pin sockets 2332 to receive corresponding ones of the power supply pins 2316 of any of the first card magnet 2306, the second card magnet 2308, or the third card magnet 2310 of graphics card 2300.

The tray magnet 2330 includes a first pole 2334 having a first polarity and a second pole 2336 having a second polarity opposite the first polarity. In particular, the first polarity of the first pole 2334 is opposite the first polarity of the first pole 2312 of the respective ones of the card magnets 2306, 2308, 2310. The second polarity of the second pole 2336 is opposite the second polarity of the second pole 2314 of the respective ones of the card magnets 2306, 2308, 2310. The first fan tray 2318 can be slid into the graphics card 2300 over the heat sink 2304 (e.g., via an opening in a sidewall of the housing such as the slot 1724 of FIG. 17). For instance, the first fan tray 2318 can be slid over a first portion of the heat sink 2304 proximate to the first card magnet 2306. When the first fan tray 2318 is inserted into the graphics card 2300 and slid over the heat sink 2304, the first pole 2334 of the first tray magnet 2330 is attracted to the first pole 2312 of the first card magnet 2306 (due the opposing polarities). Also, the second pole 2336 of the first tray magnet 2330 is attracted to the second pole 2314 of the first card magnet 2306 (due the opposing polarities). The first pole 2312 of the first tray magnet 2330 couples to the first pole 2312 of the first card magnet 2306. Also, the second pole 2336 of the first tray magnet 2330 couples to the second pole 2314 of the first card magnet 2306. Thus, the first card magnet 2306 facilitates alignment of the first fan tray 2318 in the graphics card 2300 based on magnetic forces between the first card magnet 2306 and the first tray magnet 2330.

When the first tray magnet 2330 and the first card magnet 2306 couple to one another, the power supply pins 2316 of the first card magnet 2306 are received in corresponding ones of the power pin sockets 2332 of the first tray magnet 2330. As a result, power is supplied to the first fan 2320 by the graphics card 2300 (e.g., via electrical cables carried by the first fan tray 2318 to a motor of the first fan 2320). When the first fan 230 is operating, the first fan 2320 provides for increased airflow over the first portion of the heat sink 2304 to increase cooling of electronic components of the heat sink 2304 proximate to the first portion of the heat sink 2304.

The second fan tray 2322 can be inserted into the graphics card 2300 and coupled to the second card magnet 2308 via a second tray magnet 2338 to provide for increased airflow over a second portion of the heat sink 2304 as disclosed in connection with the first fan tray 2318. Also, the third fan tray 2326 can be inserted into the graphics card 2300 and coupled to the third card magnet 2310 via a third tray magnet 2340 to provide for increased airflow over a third portion of the heat sink 2304 as disclosed in connection with the first fan tray 2318. Thus, when the first, second, and third fans 2320, 2324, 2328 are disposed in the graphics card 2300, the fans 2320, 2324, 2328 provide for increased airflow over or substantially over an area of the heat sink 2304.

In the example of FIG. 23, the speed and/or rotational direction of blades of the fans 2320, 2324, 2328 of the respective fan trays 2318, 2322, 2326 is controlled by the fan control circuitry 1750 based on outputs of the fan operating parameter sensors 1754 substantially as disclosed in connection with FIGS. 17 and 22. For instance, the speed of the blades of the fans 2320, 2324, 2328 can be adjusted in response to the fan control circuitry 1750 identifying hot spots at the graphics card 2300 based on analysis of temperature data for the card. The locations of the hot spots can be identified based on outputs of the temperature sensors 1752 substantially as disclosed in connection with FIGS. 17 and 22. The fan control circuitry 1750 can also monitor a performance of the fans 2320, 2324, 2328 and generate alerts when, for instance, the speed (e.g., RPM) of one or more of the fans 2320, 2324, 2328 falls below a threshold and the temperature of the peripheral 2300 is increasing at location(s) proximate to the fan(s) 2320, 2324, 2328. For instance, each of the fan trays 2318, 2322, 2326 can include a light emitting diode (LED) (e.g., the LED 2258 of FIG. 22). When the fan control circuitry 1750 determines that one of the fans 2320, 2324, 2328 is not operating at the threshold fan speed, the fan control circuitry 1750 can output instructions to cause the LED of the corresponding fan tray 2318, 2322, 2326 to activate to alert, for instance, a data center operator. In some examples, if one of the fans 2320, 2324, 2328 is not operating at an expected performance speed due to maintenance issues, the fan control circuitry 1750 can generate instructions to cause a rotational speed of the other fans 2320, 2324, 2328 to be adjusted (e.g., increased) compensate for the fan 2320, 2324, 2328 that is experiencing maintenance issues. The instructions from the fan control circuitry 1750 can be transmitted to, for instance, drive circuitry and/or a motor of the respective fans 2320, 2324, 2328 via wired or wireless communication protocols.

In the example of FIG. 23, the magnetic coupling between the tray magnets 2330, 2338, 2340 of the respective fan trays 2318, 2322, 2326 and the corresponding card magnets 2306, 2308, 2310 enables each of the fan trays 2318, 2322, 2326 to be selectively removed from the graphics card 2300 to undergo maintenance or to be replaced without affecting operation of the graphics card 2300 or the other ones of the fans 2320, 2324, 2328. For instance, if the fan control circuitry 1750 determines that the second fan 2324 should be repaired or replaced, the fan control circuitry 1750 can affect (e.g., disrupt) the magnetic coupling between the second card magnet 2308 and the second tray magnet 2338. In some examples, the fan control circuitry 1750 can cause a current flowing through the second card magnet 2308 to be adjusted to adjust a polarity of the poles 2312, 2314 of the second tray magnet 2308 such that the second card magnet 2308 repels rather than attracts the second tray magnet 2338. As result, the second fan tray 2322 can be removed from the graphics card 2300. In some examples, the second fan tray 2322 can be removed from the graphics card 2300 via mechanical actuation. For example, a housing of the graphics card 2300 can include a spring that is loaded when the second fan tray 2322 is inserted into the housing and a button that, when pressed by a user, causes the spring to release to eject the second fan tray 2322.

Thus, the second fan tray 2322 including the second fan 2324 can be removed from the graphics card 2300 while the graphics card 2300 remains plugged into a slot of, for instance, a server, and while the first fan 2320 and the third fan 2328 continue to operate to provide airflow over the heat sink 2304. Therefore, the removable coupling of the individual trays 2318, 2322, 2326 to the card magnets 2306, 2308, 2310 minimizes disruption to the operation of the graphics card 2300. The individual fan trays 2318, 2322, 2326 can be removed (e.g., field replaceable or hot swapped) during operation of the graphics card 2300 without powering down the graphics card 2300. Also, the isolated nature of each fan 2320, 2324, 2328 in a respective tray 2318, 2322, 2326 enables the fans 2320, 2324, 2328 to be individually removed from the graphics card 2300 without affecting operation of the other fans 2320, 2324, 2328. As a result, the fans 2320, 2324, 2328 continue to provide for increased cooling of the electronic components of the graphics card 2300 while one (or more) of the fans 2320, 2324, 2328 is removed from the graphics card 2300 for maintenance or replacement.

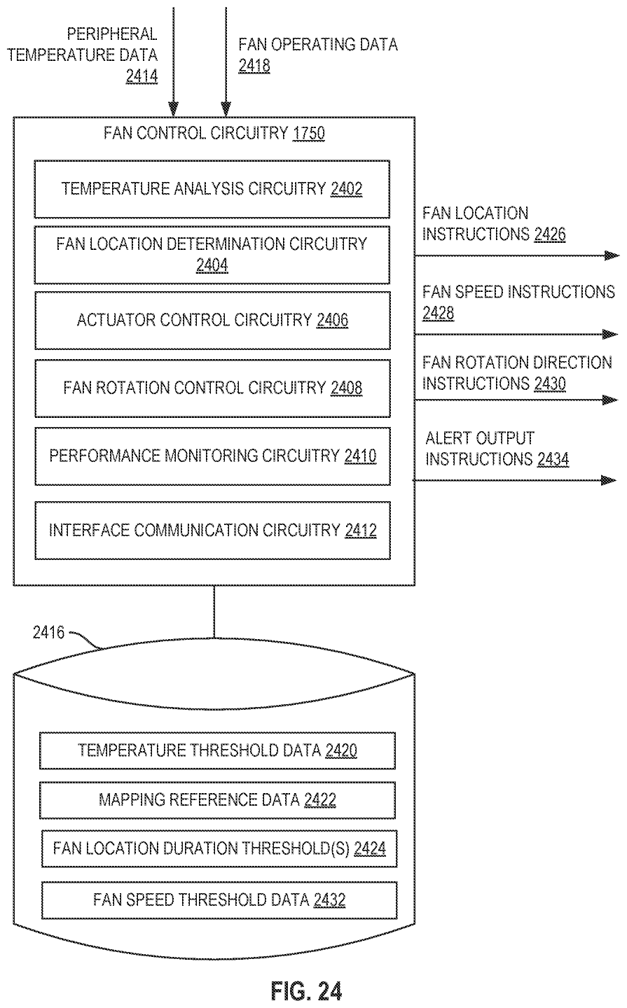

FIG. 24 is a block diagram of the example fan control circuitry 1750 of FIGS. 17, 22, and/or 23 to control one or more parameters (e.g., location, rotational speed, rotational direction) of the example fans 1722, 2208, 2216, 2320, 2324, 2328 disclosed in connection with FIGS. 17-23. The fan control circuitry 1750 of FIG. 24 may be instantiated (e.g., creating an instance of, bring into being for any length of time, materialize, implement, etc.) by processor circuitry such as a central processing unit executing instructions. Additionally or alternatively, the fan control circuitry 1750 of FIG. 24 may be instantiated (e.g., creating an instance of, bring into being for any length of time, materialize, implement, etc.) by an ASIC or an FPGA structured to perform operations corresponding to the instructions. It should be understood that some or all of the circuitry of FIG. 24 may, thus, be instantiated at the same or different times. Some or all of the circuitry may be instantiated, for example, in one or more threads executing concurrently on hardware and/or in series on hardware. Moreover, in some examples, some or all of the circuitry of FIG. 24 may be implemented by microprocessor circuitry executing instructions to implement one or more virtual machines and/or containers.

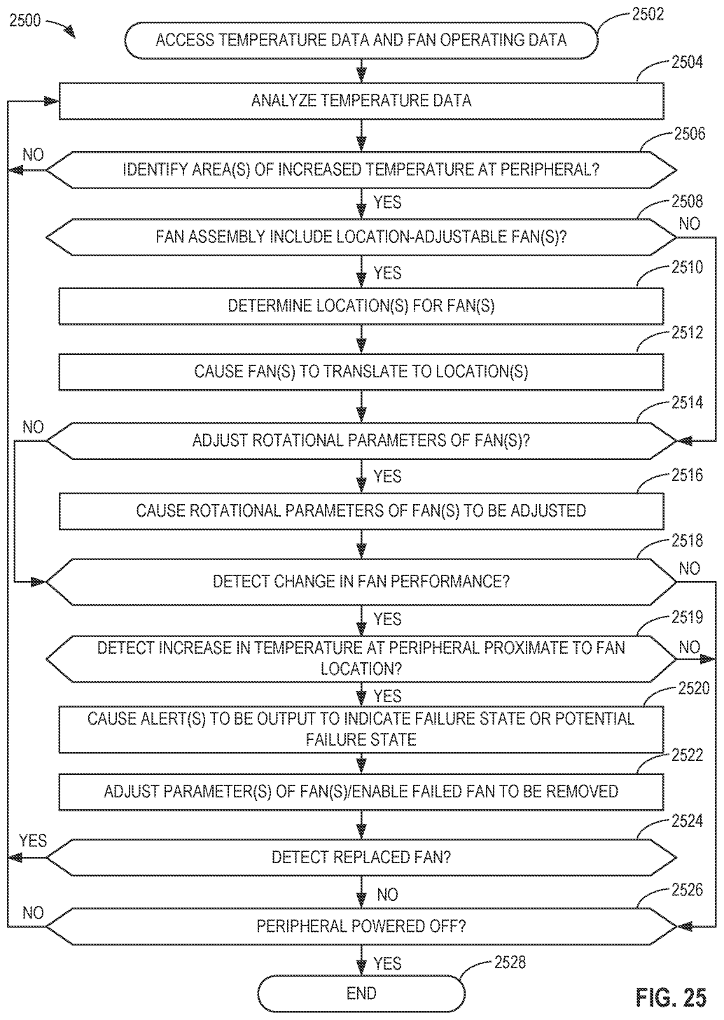

The example fan control circuitry 1750 of FIG. 24 includes temperature analysis circuitry 2402, fan location determination circuitry 2404, actuator control circuitry 2406, fan rotation control circuitry 2408, performance monitoring circuitry 2410, and interface communication circuitry 2412. In some examples, the temperature analysis circuitry 2402 is instantiated by processor circuitry executing temperature analysis instructions and/or configured to perform operations such as those represented by the flowchart of FIG. 25. In some examples, the fan location determination circuitry 2404 is instantiated by processor circuitry executing fan location determination instructions and/or configured to perform operations such as those represented by the flowchart of FIG. 25. In some examples, the actuator control circuitry 2406 is instantiated by processor circuitry executing actuator control instructions and/or configured to perform operations such as those represented by the flowchart of FIG. 25. In some examples, the fan rotation control circuitry 2408 is instantiated by processor circuitry executing fan rotation control instructions and/or configured to perform operations such as those represented by the flowchart of FIG. 25. In some examples, the performance monitoring circuitry 2410 is instantiated by processor circuitry executing performance monitoring instructions and/or configured to perform operations such as those represented by the flowchart of FIG. 25. In some examples, the interface communication circuitry 2412 is instantiated by processor circuitry executing interface communication instructions and/or configured to perform operations such as those represented by the flowchart of FIG. 25.

In the example of FIG. 24, the fan control circuitry 1750 accesses peripheral temperature data 2414 corresponding to signals output by the temperature sensors 1752 of the PCIe card(s) 1700, 2220, 2300. The temperature data 2414 can include temperatures of the PCIe card and/or the electronic components thereof at different locations on the card 1700, 2200, 2300 based on the locations of the temperature sensors 1752. The temperature data 2414 can be stored in a memory 2416. In some examples, the fan control circuitry 1750 includes the memory 2416. In some examples, the memory 2416 is located external to the fan control circuitry 2406 in a location accessible to the fan control circuitry 1750 as shown in FIG. 24.

In the example of FIG. 24, the fan control circuitry 1750 accesses fan operating data 2418. The fan operating data 2418 can include properties of operating parameters of the fans 1722, 2208, 2216, 2320, 2324, 2328, such as a power state, a rotational speed, a rotational direction, and/or a location of the fans 1722, 2208, 2216, 2320, 2324, 2328. The fan operating data 2418 can correspond to signals output by, for instance, the fan operating parameter sensor(s) 1754 (e.g., position sensor(s), tachometer(s)). The fan operating data 2418 can be stored in the memory 2416.

The temperature analysis circuitry 2402 analyzes the peripheral temperature data 2414 to identify areas of the PCIe card 1700, 2200, 2300 including electronic components (e.g., FPGA, processor circuitry) generating increased amounts of heat relative to other electronic components of the card 1700, 2200, 2300. For instance, the temperature analysis circuitry 2402 can generate temperature gradients for the PCIe card 1700, 2200, 2300 and identify areas of increased temperature or hot spots at a given time based on the temperature gradient. In some examples, the temperature analysis circuitry 2402 compares the temperature data 2414 to temperature threshold data 2420 stored in the memory 2416. The temperature threshold data 2420 can include user defined temperature classifications identifying temperatures or ranges of temperatures that are indicative of hot spots.

The fan location determination circuitry 2404 of the fan control circuitry uses the locations of the hot spots identified by the temperature analysis circuitry 2402 to determine a location (e.g., an optimal location) of the fan(s) 1722, 2208, 2216, 2320, 2324, 2328 (e.g., the fan base(s) 1800) relative to the heat sink 1714, 2204, 2304 of the PCIe card 1700, 2200, 2300 to provide for increased airflow over the area(s) of the heat sink 1714, 2204, 2304 that are proximate to the hot spots. For example, the fan location determination circuitry 2404 can use mapping reference data 2422 stored in the memory 2416 to identify a current location of the fan(s) 1722, 2208, 2216, 2320, 2324, 2328 relative to the hot spots. The mapping reference data 2422 can identify the locations of the electronic components on the PCIe card 1700, 2200, 2300. The fan location determination circuitry 2404 can determine a location to which the fan(s) 1722, 2208, 2216, 2320, 2324, 2328 (e.g., the fan base(s) 1800) should be moved to locate the fan(s) 1722, 2208, 2216, 2320, 2324, 2328 proximate to the portion of the heat sink 1714, 2204, 2304 associated with the hot spot(s).

In some examples, the fan location determination circuitry 2404 determines that the fan(s) 1722, 2208, 2216 of the example fan assemblies 1720, 2206, 2214 of FIGS. 17-22 should be translated if the fan(s) 1722, 2208, 2216 have been at a particular location relative to the heat sink 1714, 2204, 2304 for a particular duration of time. For example, fan location duration threshold data 2424 stored in the memory 2416 can indicate a duration of time for which the fan(s) 1722, 2208, 2216 should remain at particular locations relative to the heat sink 1714, 2204. The fan location duration threshold data 2424 can be defined based on user inputs and, for instance, expected cooling times for the electronic components of the PCIe card 1700, 2200 based on temperature, fan speed, operational characteristics of the electronic components, etc.

In some examples, if the fan location determination circuitry 2404 determines that the fan(s) 1722, 2208, 2216 should be translated to address hot spots on the PCIe card 1700, 2200, the actuator control circuitry 2406 generates fan location instruction(s) 2426 to cause the actuators 1742, 2226, 2230, 2250, 2252 to translate the fan(s) 1722, 2208, 2216 (e.g., the fan shuttle(s) 1738, 2212, 2220) to the location(s) identified by the fan location determination circuitry 2404. In some examples, the fan location instruction(s) 2426 cause the linear actuator 1742 of the fan tray 1720 of FIG. 23 to move the shuttle 1738 to a particular location in the IPU 1700. In some examples, the fan instruction(s) 2426 cause a current flowing through the tray magnets 2226, 2230, 2250, 2252 of the respective fan trays 2206, 2214 of FIG. 22 to be adjusted (e.g., reversed) to affect a polarity of the tray magnets 2226, 2230, 2250, 2252. As disclosed in connection with FIG. 22, the polarity of the tray magnets 2226, 2230, 2250, 2252 can cause the shuttle 2212, 2220 of FIG. 22 to move along the track 2222, 2224 as a result of pushing or pulling forces due to attraction or repelling between the tray magnets 2226, 2230, 2250, 2252 and the corresponding shuttle magnets 2238, 2242, 2254, 2256.

The fan rotation control circuitry 2408 monitors a speed of the blades 1740 of the fan(s) 1722, 2208, 2216, 2320, 2324, 2328 of the fan assemblies 1720, 2206, 2214, 2318, 2322, 2326 of FIGS. 17-23 based on the fan operating data 2418. In some examples, the fan rotation control circuitry 2408 generates fan speed instruction(s) 2428 to cause a rotational speed (e.g., RPMs) of the blades 1740 of the fan(s) 1722, 2208, 2216, 2320, 2324, 2328 to be adjusted based on the temperature(s) of the hot spot(s) identified by the temperature analysis circuitry 2402.

In some examples, the fan rotation control circuitry 2408 determines a direction in which the blades 1740 of the fan(s) 1722, 2208, 2216, 2320, 2324, 2328 should rotate to affect a direction of airflow through the PCIe card 1700, 2200, 2300. In some examples, the fan rotation control circuitry 2408 determines the direction of airflow through the PCIe card 1700, 2200, 2300 based on the temperature gradient generated by the temperature analysis circuitry 2402, where cooler temperatures can indicate that air from the ambient environment is entering the PCIe card 1700, 2200, 2300 proximate to the temperature sensors 1752 detecting the cooler temperatures. The fan rotation control circuitry 2408 can generate fan rotation direction instruction(s) 2430 to cause the blades 1740 of the fan(s) 1722, 2208, 2216, 2320, 2324, 2328 to rotate in a particular direction to facilitate air flow through the PCIe card 1700, 2200, 2300. In some examples, the fan rotation control circuitry 2408 instructs the blades 1740 of a first fan 1722, 2208, 2216, 2320, 2324, 2328 to rotate in a first direction and the blades 1740 of a second fan 1722, 2208, 2216, 2320, 2324, 2328 to rotate in a second direction to pull cool air into the card 1700, 2200, 2300 and push hot air out.

The performance monitoring circuitry 2410 monitors the fan(s) 1722, 2208, 2216, 2320, 2324, 2328 to detect potential failure states of the fan(s) 1722, 2208, 2216, 2320, 2324, 2328 or other indicators that the fan(s) 1722, 2208, 2216, 2320, 2324, 2328 may need to be repaired or replaced. The performance monitoring circuitry 2410 compares the rotational blade speed of the fan(s) 1722, 2208, 2216, 2320, 2324, 2328 to fan speed threshold data 2432 stored in the memory 2416. The fan speed threshold data 2432 can define minimum rotational speeds and/or ranges of speeds for which the blades 1740 of the fan(s) 1722, 2208, 2216, 2320, 2324, 2328 should be rotating. The performance monitoring circuitry 2410 and/or the temperature analysis circuitry 2402 can also analyze the temperature data 2414 in response to the change in fan performance to confirm that the change is due to, for instance, decreased workloads at the PCIe card 1700, 2200, 2300 that cause less heat to be generated by the PCIe card components, and not because of a failed fan 1722, 2208, 2216, 2320, 2324, 2328 that should otherwise be satisfying performance thresholds for cooling. For instance, if the performance monitoring circuitry 2410 determines that the temperature of the components of the PCIe card 1700, 2200, 2300 proximate to the location(s) of the fan(s) 1722, 2208, 2216, 2320, 2324, 2328 are increasing in response to the change in fan performance, the performance monitoring circuitry 2410 can determine that the fan(s) 1722, 2208, 2216, 2320, 2324, 2328 may have failed or are failing. If the performance monitoring circuitry 2408 determines that the fan(s) 1722, 2208, 2216, 2320, 2324, 2328 do not satisfy the fan speed threshold data 2432 and that temperature of the PCIe card 1700, 2200, 2300 is increasing when cooling is expected, the performance monitoring circuitry 2410 generates alert output instruction(s) 2434 to cause alert(s) to be presented to inform a user (e.g., a data center operator) of the failed state or potential failed state of the fan(s). For instance, the alert output instruction(s) 2434 can cause an LED on a tray 1720, 2206, 2214, 2318, 2322, 2326 to be activated to provide a visual alert.

In some examples, if the performance monitoring circuitry 2410 detects a failed fan state, the performance monitoring circuitry 2410 communicates with, for instance, the fan location determination circuitry 2404 and/or the fan rotation control circuitry 2408 to determine if adjustments should be made to compensate for the failed fan state. For instance, the fan location determination circuitry 2404 can determine that the fan 1722 of FIG. 17 (e.g., the fan base 1800) should be moved an end of the tray 1720 to prevent the failed fan 1722 from interfering with airflow into the PCIe card 1700. In some examples, the fan rotation control circuitry 2408 generates fan speed instruction(s) 2428 to cause a rotational speed (e.g., RPMs) of the blades 1740 of the fan(s) 1722, 2208, 2216, 2320, 2324, 2328 to be adjusted if one or more of the fans 1722, 2208, 2216, 2320, 2324, 2328 have been removed from the PCIe card 2200, 2300 for maintenance.

The interface communication circuitry 2412 outputs the fan location instruction(s) 2426, the fan speed instruction(s) 2428, the fan rotation direction instruction(s) 2430, and/or the alert output instruction(s) 2434 to cause the instructions to be implemented by, for instance, the fan(s) 1722, 2208, 2216, 2320, 2324, 2328, the actuator(s) 1742, 2226, 2230, 2250, 2252, etc. of the example fan assemblies of FIGS. 17-23.

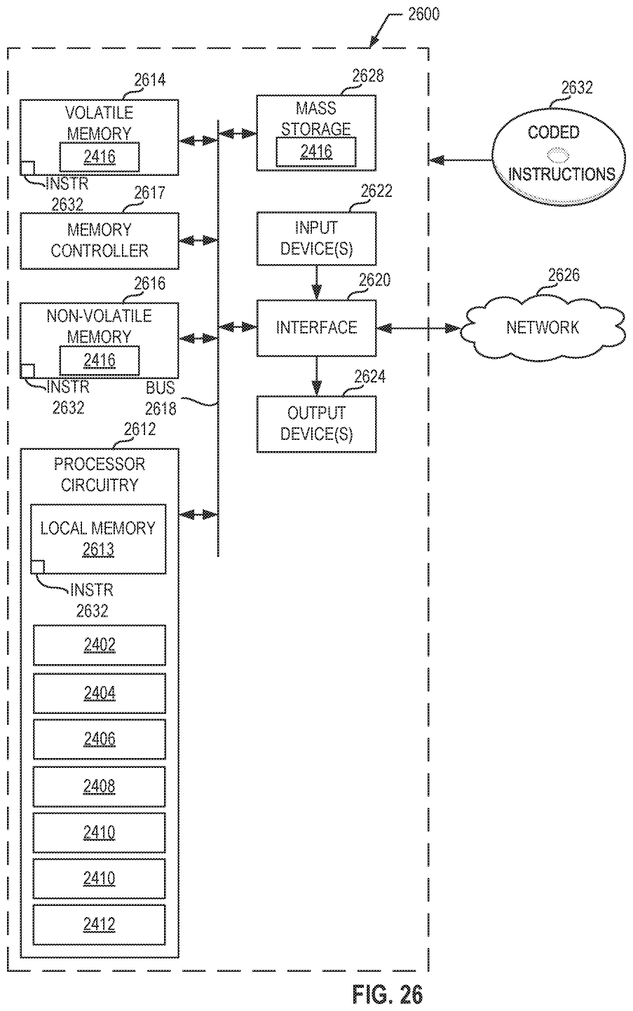

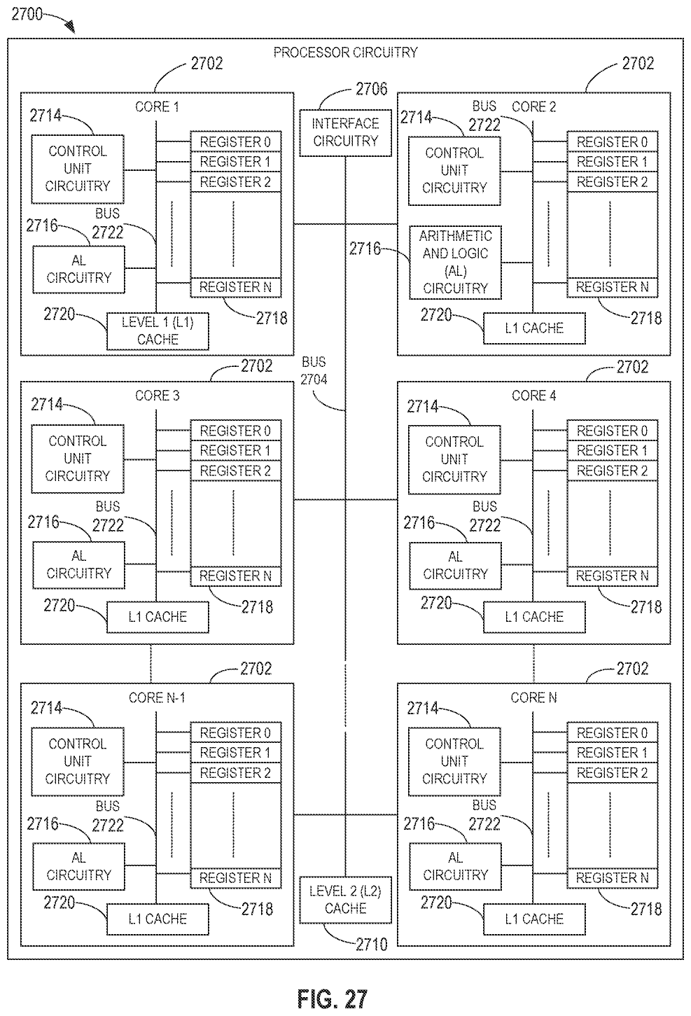

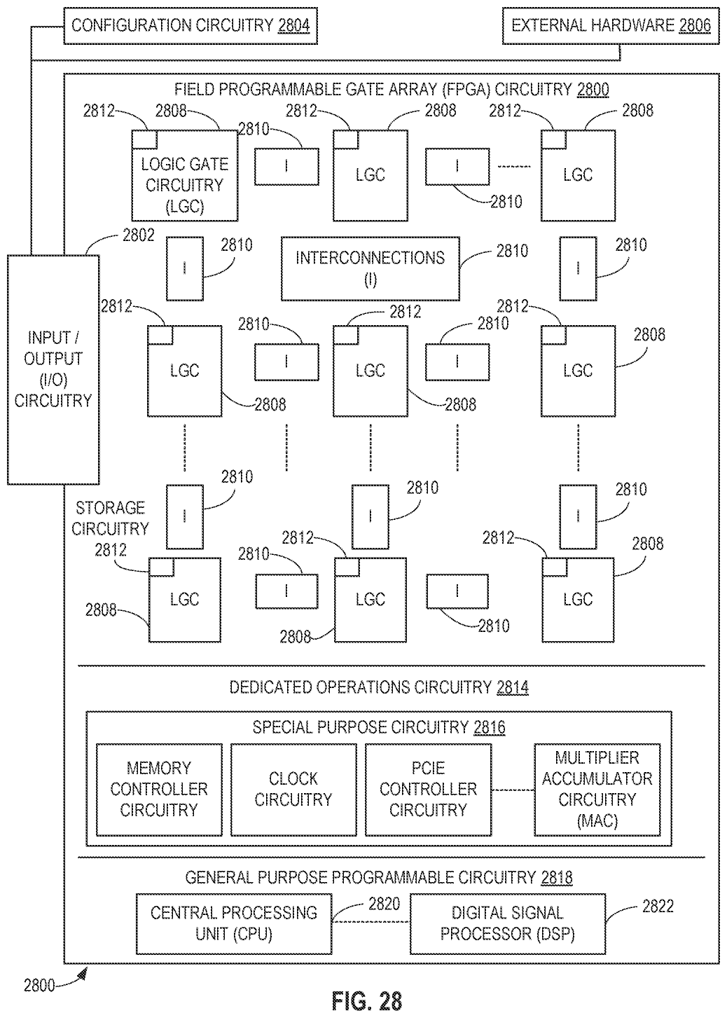

In some examples, the fan control circuitry 1750 includes means for analyzing temperature. For example, the means for analyzing temperature may be implemented by the temperature analysis circuitry 2402. In some examples, the temperature analysis circuitry 2402 may be instantiated by processor circuitry such as the example processor circuitry 2612 of FIG. 26. For instance, the temperature analysis circuitry 2402 may be instantiated by the example microprocessor 2700 of FIG. 27 executing machine executable instructions such as those implemented by at least blocks 2504, 2506 of FIG. 25. In some examples, the temperature analysis circuitry 2402 may be instantiated by hardware logic circuitry, which may be implemented by an ASIC, XPU, or the FPGA circuitry 2800 of FIG. 28 structured to perform operations corresponding to the machine readable instructions. Additionally or alternatively, the temperature analysis circuitry 2402 may be instantiated by any other combination of hardware, software, and/or firmware. For example, the temperature analysis circuitry 2402 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the fan control circuitry 1750 includes means for determining a fan location. For example, the means for determining a fan location may be implemented by the fan location determination circuitry 2404. In some examples, the fan location determination circuitry 2404 may be instantiated by processor circuitry such as the example processor circuitry 2612 of FIG. 26. For instance, the fan location determination circuitry 2404 may be instantiated by the example microprocessor 2700 of FIG. 27 executing machine executable instructions such as those implemented by at least blocks 2508, 2510, 2522, 2524 of FIG. 25. In some examples, the fan location determination circuitry 2404 may be instantiated by hardware logic circuitry, which may be implemented by an ASIC, XPU, or the FPGA circuitry 2800 of FIG. 28 structured to perform operations corresponding to the machine readable instructions. Additionally or alternatively, the fan location determination circuitry 2404 may be instantiated by any other combination of hardware, software, and/or firmware. For example, the fan location determination circuitry 2404 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the fan control circuitry 1750 includes means for controlling an actuator. For example, the means for controlling an actuator may be implemented by the actuator control circuitry 2406. In some examples, the actuator control circuitry 2406 may be instantiated by processor circuitry such as the example processor circuitry 2612 of FIG. 26. For instance, the actuator control circuitry 2406 may be instantiated by the example microprocessor 2700 of FIG. 27 executing machine executable instructions such as those implemented by at least blocks 2512 of FIG. 25. In some examples, the actuator control circuitry 2406 may be instantiated by hardware logic circuitry, which may be implemented by an ASIC, XPU, or the FPGA circuitry 2800 of FIG. 28 structured to perform operations corresponding to the machine readable instructions. Additionally or alternatively, the actuator control circuitry 2406 may be instantiated by any other combination of hardware, software, and/or firmware. For example, the actuator control circuitry 2406 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the fan control circuitry 1750 includes means for controlling rotation of a fan. For example, the means for controlling rotation of a fan may be implemented by the fan rotation control circuitry 2408. In some examples, the fan rotation control circuitry 2408 may be instantiated by processor circuitry such as the example processor circuitry 2612 of FIG. 26. For instance, the fan rotation control circuitry 2408 may be instantiated by the example microprocessor 2700 of FIG. 27 executing machine executable instructions such as those implemented by at least blocks 2514, 2516, 2522, 2524 of FIG. 25. In some examples, the fan rotation control circuitry 2408 may be instantiated by hardware logic circuitry, which may be implemented by an ASIC, XPU, or the FPGA circuitry 2800 of FIG. 28 structured to perform operations corresponding to the machine readable instructions. Additionally or alternatively, the fan rotation control circuitry 2408 may be instantiated by any other combination of hardware, software, and/or firmware. For example, the fan rotation control circuitry 2408 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the fan control circuitry 1750 includes means for monitoring performance. For example, the means for monitoring performance may be implemented by the performance monitoring circuitry 2410. In some examples, the performance monitoring circuitry 2410 may be instantiated by processor circuitry such as the example processor circuitry 2612 of FIG. 26. For instance, the performance monitoring circuitry 2410 may be instantiated by the example microprocessor 2700 of FIG. 27 executing machine executable instructions such as those implemented by at least blocks 2518, 2520 of FIG. 25. In some examples, the performance monitoring circuitry 2410 may be instantiated by hardware logic circuitry, which may be implemented by an ASIC, XPU, or the FPGA circuitry 2800 of FIG. 28 structured to perform operations corresponding to the machine readable instructions. Additionally or alternatively, the performance monitoring circuitry 2410 may be instantiated by any other combination of hardware, software, and/or firmware. For example, the performance monitoring circuitry 2410 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the fan control circuitry 1750 includes means for interfacing. For example, the means for interfacing may be implemented by the interface communication circuitry 2412. In some examples, the interface communication circuitry 2412 may be instantiated by processor circuitry such as the example processor circuitry 2602 of FIG. 26. For instance, the interface communication circuitry 2412 may be instantiated by the example microprocessor 2700 of FIG. 27 executing machine executable instructions such as those implemented by at least blocks 2518, 2520 of FIG. 25. In some examples, the interface communication circuitry 2412 may be instantiated by hardware logic circuitry, which may be implemented by an ASIC, XPU, or the FPGA circuitry 2800 of FIG. 28 structured to perform operations corresponding to the machine readable instructions. Additionally or alternatively, the interface communication circuitry 2412 may be instantiated by any other combination of hardware, software, and/or firmware. For example, the interface communication circuitry 2412 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

While an example manner of implementing the fan control circuitry 1750 of FIGS. 17, 22, and/or 23 is illustrated in FIG. 24, one or more of the elements, processes, and/or devices illustrated in FIG. 24 may be combined, divided, re-arranged, omitted, eliminated, and/or implemented in any other way. Further, the example temperature analysis circuitry 2402, the example fan location determination circuitry 2404, the example actuator control circuitry 2406, the example fan rotation control circuitry 2408, the example performance monitoring circuitry 2410, the example interface communication circuitry 2412, and/or, more generally, the example fan control circuitry 1750 of FIG. 24, may be implemented by hardware alone or by hardware in combination with software and/or firmware. Thus, for example, any of the example temperature analysis circuitry 2402, the example fan location determination circuitry 2404, the example actuator control circuitry 2406, the example fan rotation control circuitry 2408, the example performance monitoring circuitry 2410, the example interface communication circuitry 2412, and/or, more generally, the example fan control circuitry 1750, could be implemented by processor circuitry, analog circuit(s), digital circuit(s), logic circuit(s), programmable processor(s), programmable microcontroller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). Further still, the example fan control circuitry 1750 of FIGS. 17, 22, and/or 23 may include one or more elements, processes, and/or devices in addition to, or instead of, those illustrated in FIG. 24, and/or may include more than one of any or all of the illustrated elements, processes, and devices.

A flowchart representative of example machine readable instructions, which may be executed to configure processor circuitry to implement the fan control circuitry 1750 of FIG. 24, is shown in FIG. 25. The machine readable instructions may be one or more executable programs or portion(s) of an executable program for execution by processor circuitry, such as the processor circuitry 2612 shown in the example processor platform 2600 discussed below in connection with FIG. 26 and/or the example processor circuitry discussed below in connection with FIGS. 27 and/or 28. The program may be embodied in software stored on one or more non-transitory computer readable storage media such as a compact disk (CD), a floppy disk, a hard disk drive (HDD), a solid-state drive (SSD), a digital versatile disk (DVD), a Blu-ray disk, a volatile memory (e.g., Random Access Memory (RAM) of any type, etc.), or a non-volatile memory (e.g., electrically erasable programmable read-only memory (EEPROM), FLASH memory, an HDD, an SSD, etc.) associated with processor circuitry located in one or more hardware devices, but the entire program and/or parts thereof could alternatively be executed by one or more hardware devices other than the processor circuitry and/or embodied in firmware or dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a user) or an intermediate client hardware device (e.g., a radio access network (RAN)) gateway that may facilitate communication between a server and an endpoint client hardware device). Similarly, the non-transitory computer readable storage media may include one or more mediums located in one or more hardware devices. Further, although the example program is described with reference to the flowchart illustrated in FIG. 25, many other methods of implementing the example fan control circuitry 1750 may alternatively be used. For example, the order of execution of the blocks may be changed, and/or some of the blocks described may be changed, eliminated, or combined. Additionally or alternatively, any or all of the blocks may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The processor circuitry may be distributed in different network locations and/or local to one or more hardware devices (e.g., a single-core processor (e.g., a single core central processor unit (CPU)), a multi-core processor (e.g., a multi-core CPU, an XPU, etc.) in a single machine, multiple processors distributed across multiple servers of a server rack, multiple processors distributed across one or more server racks, a CPU and/or a FPGA located in the same package (e.g., the same integrated circuit (IC) package or in two or more separate housings, etc.).

The machine readable instructions described herein may be stored in one or more of a compressed format, an encrypted format, a fragmented format, a compiled format, an executable format, a packaged format, etc. Machine readable instructions as described herein may be stored as data or a data structure (e.g., as portions of instructions, code, representations of code, etc.) that may be utilized to create, manufacture, and/or produce machine executable instructions. For example, the machine readable instructions may be fragmented and stored on one or more storage devices and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of machine executable instructions that implement one or more operations that may together form a program such as that described herein.

In another example, the machine readable instructions may be stored in a state in which they may be read by processor circuitry, but require addition of a library (e.g., a dynamic link library (DLL)), a software development kit (SDK), an application programming interface (API), etc., in order to execute the machine readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable media, as used herein, may include machine readable instructions and/or program(s) regardless of the particular format or state of the machine readable instructions and/or program(s) when stored or otherwise at rest or in transit.

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 25 may be implemented using executable instructions (e.g., computer and/or machine readable instructions) stored on one or more non-transitory computer and/or machine readable media such as optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms non-transitory computer readable medium, non-transitory computer readable storage medium, non-transitory machine readable medium, and non-transitory machine readable storage medium are expressly defined to include any type of computer readable storage device and/or storage disk and to exclude propagating signals and to exclude transmission media. As used herein, the terms “computer readable storage device” and “machine readable storage device” are defined to include any physical (mechanical and/or electrical) structure to store information, but to exclude propagating signals and to exclude transmission media. Examples of computer readable storage devices and machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer readable instructions, machine readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 25 is a flowchart representative of example machine readable instructions and/or example operations 2500 that may be executed and/or instantiated by processor circuitry to control one or more parameter(s) (e.g., location, rotational speed, rotational direction) of the fan(s) 1722, 2208, 2216, 2320, 2324, 2328 of a peripheral 1700, 2200, 2300 (e.g., a PCIe card). The machine readable instructions and/or the operations 2500 of FIG. 25 begin at block 2502, at which the interface communication circuitry 2412 of the fan control circuitry 1750 accesses peripheral temperature data 2414 and fan operating data 2418 from, for instance, the temperature sensors 1752 and the fan operating parameter sensor(s) 1754 of the peripheral 1700, 2200, 2300.

At block 2504, the temperature analysis circuitry 2402 analyzes the temperature data 2414 to identify areas of the peripheral 1700, 2200, 2300 that are associated with increased temperature relative to other areas of the peripheral 1700, 2200, 2300, thereby indicating that increased amount of heat is being generated by the electronic components of the peripheral 1700, 2200, 2300 at those areas. If, at block 2506, the temperature analysis circuitry 2402 identifies areas of increased temperature (i.e., hot spots) at the peripheral 1700, 2200, 2300, then the fan control circuitry 1750 generates instructions to provide for increased airflow over the heat sink 1714, 2204, 2304 at portions of the heat sink 1714, 2204, 2304 corresponding to the areas of increased temperature.

If the fan assembly 1720, 2206, 2214 includes location-adjustable fans 1722, 2208, 2216 as disclosed in connection with FIGS. 17-22 (block 2508), then at block 2510, the fan location determination circuitry 2404 determines a location to which the fan(s) 1722, 2208, 2216 (e.g., the fan base(s) 1800) should be moved based on the locations of the hot spots. At block 2512, the actuator control circuitry 2406 generates fan location instruction(s) 2426 for transmission by the interface communication circuitry 2412 to cause the actuator(s) 1742, 2226, 2230, 2250, 2252, to translate or move the fan(s) 1722, 2208, 2216 (e.g., the fan base(s) 1800) via, for instance, the fan shuttles 1738, 2212, 2220 to the identified locations. In some examples, the fan location instruction(s) 2426 cause the linear actuator 1742 to move the shuttle 1738 including the fan 1722 supported by the base 1800 as disclosed in connection with FIG. 17. In some examples, the fan location instruction(s) 2426 cause a polarity of the tray magnets 2226, 2230, 2250, 2252 to be adjusted (e.g., reversed, turned on) to cause the shuttle 2212, 2220 to be pushed and/or pulled along the track 2222, 2224 to particular locations relative to the heat sink 2204 as disclosed in connection with FIG. 22.

At block 2514, the fan rotation control circuitry 2408 determines if rotational parameters of the blades 1740 of the fan(s) 1722, 2208, 2216, 2320, 2324, 2328, such as rotational blade speed and/or rotational blade direction, should be adjusted based on, for instance, the temperature of the hot spots, the direction of airflow through the peripheral 1700, 2200, 2300, the direction of rotation of the blades 1740 of the other fan(s) 1722, 2208, 2216, 2320, 2324, 2328, etc. At block 2516, the fan rotation control circuitry 2408 generates fan speed instruction(s) 2428 and/or fan rotation direction instruction(s) 2430 for transmission by the interface communication circuitry 2412 to cause the rotational parameter(s) of the blades 1740 of the fan(s) 1722, 2208, 2216, 2320, 2324, 2328 to be adjusted (e.g., by the fan motor).

At block 2518, the performance monitoring circuitry 2410 detects if changes in fan performance such as rotational blade speed (e.g., reduced RPMs or no rotation). In some examples, the rotational parameters of the fan(s) 1722, 2208, 2216, 2320, 2324, 2328 may change (e.g., reduce RPMs, stop rotation) in view of, for instance, decreased workloads by the component(s) of the peripheral 1700, 2200, 2300 and, thus, less heat generated over time, acoustic considerations, etc. Thus, to verify whether the change in fan performance is indicative of a failed state of the fan(s) 1722, 2208, 2216, 2320, 2324, 2328 or a potential failed state (e.g., rotational speed below a threshold), at block 2519, the performance monitoring circuitry 2410 determines whether the temperature of the peripheral 1700, 2200, 2300 is increasing proximate to the location(s) of the fan(s) 1722, 2208, 2216, 2320, 2324, 2328 (e.g., based on the temperature data 2414). The increase in temperature proximate to the fan location can indicate that the fan 1722, 2208, 2216, 2320, 2324, 2328 is failing to operate as expected to cool the component(s). If the performance monitoring circuitry 2410 detects the change in fan performance as well as an increase in temperature of the peripheral 100, 2200, 2300 proximate to at the location(s) of the fan(s) 1722, 2208, 2216, 2320, 2324, 2328, at block 2520, the performance monitoring circuitry 2410 generates alert output instruction(s) 2434 for transmission by the interface communication circuitry 2410 to cause alert(s) to be output to inform a user of the failed fan state (e.g., activation of an LED at the fan tray 1720, 2206, 2214, 2318, 2322, 2326).

In some examples, at block 2522, the fan location determination circuitry 2404 and/or the fan rotation control circuitry 2408 adjust the location(s) and/or rotational parameters of the fan(s) 1722, 2208, 2216, 2320, 2324, 2328 to compensate for the failed fan 1722, 2208, 2216, 2320, 2324, 2328 (e.g., to cause the failed fan 1722, 2208, 2216, 2320, 2324, 2328 to move to prevent interference with airflow, to cause a rotational speed of the other fan(s) 1722, 2208, 2216, 2320, 2324, 2328 to increase). In some examples, the actuator control circuitry 2406 generates instructions to enable the tray 1720, 2206, 2214, 2318, 2322, 2326 including the failed fan 1722, 2208, 2216, 2320, 2324, 2328 to be removed from the peripheral 1700, 2200, 2300 (e.g., by reversing polarity of the magnets 2226, 2230, 2250, 2252, 2306, 2308, 2310 to uncouple fan assembly 1720, 2206, 2214, 2318, 2322, 2326 from the PCIe card 1700, 2200, 2300).

In some examples, at block 2524, the fan location determination circuitry 2404 and/or the fan rotation control circuitry 2408 detects a replaced fan based on, for instance, the fan operating data 2418.

The example instructions 2500 continue to monitor the fan operating data 2418 and/or the temperature data 2414 to determine if the parameter(s) (e.g., location, rotational speed, rotational direction) of the fan(s) 1722, 2208, 2216, 2320, 2324, 2328 should be adjusted. The example instructions 2500 end when the peripheral 1700, 2200, 2300 is powered off (blocks 2526, 2528).

FIG. 26 is a block diagram of an example processor platform 2600 structured to execute and/or instantiate the machine readable instructions and/or the operations of FIG. 25 to implement the fan control circuitry 1750 of FIG. 24. The processor platform 2600 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, or any other type of computing device.

The processor platform 2600 of the illustrated example includes processor circuitry 2612. The processor circuitry 2612 of the illustrated example is hardware. For example, the processor circuitry 2612 can be implemented by one or more integrated circuits, logic circuits, FPGAs, microprocessors, CPUs, GPUs, DSPs, and/or microcontrollers from any desired family or manufacturer. The processor circuitry 2612 may be implemented by one or more semiconductor based (e.g., silicon based) devices. In this example, the processor circuitry 2612 implements the example temperature analysis circuitry 2402, the example fan location determination circuitry 2404, the example actuator control circuitry 2406, the example fan rotation control circuitry 2408, the example performance monitoring circuitry 2410, the example interface communication circuitry 2412, and/or, more generally, the example fan control circuitry 1750.

The processor circuitry 2612 of the illustrated example includes a local memory 2613 (e.g., a cache, registers, etc.). The processor circuitry 2612 of the illustrated example is in communication with a main memory including a volatile memory 2614 and a non-volatile memory 2616 by a bus 2618. The volatile memory 2614 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 2616 may be implemented by flash memory and/or any other desired type of memory device. Access to the main memory 2614, 2616 of the illustrated example is controlled by a memory controller 2617.

The processor platform 2600 of the illustrated example also includes interface circuitry 2620. The interface circuitry 2620 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 2622 are connected to the interface circuitry 2620. The input device(s) 422 permit(s) a user to enter data and/or commands into the processor circuitry 2612. The input device(s) 2622 can be implemented by, for example, an audio sensor, a microphone, a camera (still or video), a keyboard, a button, a mouse, a touchscreen, a track-pad, a trackball, an isopoint device, and/or a voice recognition system.

One or more output devices 2624 are also connected to the interface circuitry 2620 of the illustrated example. The output device(s) 424 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 2620 of the illustrated example, thus, typically includes a graphics driver card, a graphics driver chip, and/or graphics processor circuitry such as a GPU.

The interface circuitry 2620 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 2626. The communication can be by, for example, an Ethernet connection, a digital subscriber line (DSL) connection, a telephone line connection, a coaxial cable system, a satellite system, a line-of-site wireless system, a cellular telephone system, an optical connection, etc.

The processor platform 2600 of the illustrated example also includes one or more mass storage devices 2628 to store software and/or data. Examples of such mass storage devices 2628 include magnetic storage devices, optical storage devices, floppy disk drives, HDDs, CDs, Blu-ray disk drives, redundant array of independent disks (RAID) systems, solid state storage devices such as flash memory devices and/or SSDs, and DVD drives.

The machine readable instructions 2632, which may be implemented by the machine readable instructions of FIG. 25, may be stored in the mass storage device 2628, in the volatile memory 2614, in the non-volatile memory 2616, and/or on a removable non-transitory computer readable storage medium such as a CD or DVD.

FIG. 27 is a block diagram of an example implementation of the processor circuitry 2612 of FIG. 26. In this example, the processor circuitry 2612 of FIG. 26 is implemented by a microprocessor 2700. For example, the microprocessor 2700 may be a general purpose microprocessor (e.g., general purpose microprocessor circuitry). The microprocessor 2700 executes some or all of the machine readable instructions of the flowchart of FIG. 25 to effectively instantiate the circuitry of FIG. 24 as logic circuits to perform the operations corresponding to those machine readable instructions. In some such examples, the circuitry of FIG. 24 is instantiated by the hardware circuits of the microprocessor 2700 in combination with the instructions. For example, the microprocessor 2700 may be implemented by multi-core hardware circuitry such as a CPU, a DSP, a GPU, an XPU, etc. Although it may include any number of example cores 2702 (e.g., 1 core), the microprocessor 2700 of this example is a multi-core semiconductor device including N cores. The cores 2702 of the microprocessor 2700 may operate independently or may cooperate to execute machine readable instructions. For example, machine code corresponding to a firmware program, an embedded software program, or a software program may be executed by one of the cores 2702 or may be executed by multiple ones of the cores 2702 at the same or different times. In some examples, the machine code corresponding to the firmware program, the embedded software program, or the software program is split into threads and executed in parallel by two or more of the cores 2702. The software program may correspond to a portion or all of the machine readable instructions and/or operations represented by the flowchart of FIG. 25.

The cores 2702 may communicate by a first example bus 2704. In some examples, the first bus 2704 may be implemented by a communication bus to effectuate communication associated with one(s) of the cores 2702. For example, the first bus 2704 may be implemented by at least one of an Inter-Integrated Circuit (I2C) bus, a Serial Peripheral Interface (SPI) bus, a PCI bus, or a PCIe bus. Additionally or alternatively, the first bus 2704 may be implemented by any other type of computing or electrical bus. The cores 2702 may obtain data, instructions, and/or signals from one or more external devices by example interface circuitry 2706. The cores 2702 may output data, instructions, and/or signals to the one or more external devices by the interface circuitry 2706. Although the cores 2702 of this example include example local memory 2720 (e.g., Level 1 (L1) cache that may be split into an L1 data cache and an L1 instruction cache), the microprocessor 2700 also includes example shared memory 2710 that may be shared by the cores (e.g., Level 2 (L2 cache)) for high-speed access to data and/or instructions. Data and/or instructions may be transferred (e.g., shared) by writing to and/or reading from the shared memory 2710. The local memory 2720 of each of the cores 2702 and the shared memory 2710 may be part of a hierarchy of storage devices including multiple levels of cache memory and the main memory (e.g., the main memory 2614, 2616 of FIG. 26). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 2702 may be referred to as a CPU, DSP, GPU, etc., or any other type of hardware circuitry. Each core 2702 includes control unit circuitry 2714, arithmetic and logic (AL) circuitry (sometimes referred to as an ALU) 2716, a plurality of registers 2718, the local memory 2720, and a second example bus 2722. Other structures may be present. For example, each core 2702 may include vector unit circuitry, single instruction multiple data (SIMD) unit circuitry, load/store unit (LSU) circuitry, branch/jump unit circuitry, floating-point unit (FPU) circuitry, etc. The control unit circuitry 2714 includes semiconductor-based circuits structured to control (e.g., coordinate) data movement within the corresponding core 2702. The AL circuitry 2716 includes semiconductor-based circuits structured to perform one or more mathematic and/or logic operations on the data within the corresponding core 2702. The AL circuitry 2716 of some examples performs integer based operations. In other examples, the AL circuitry 2716 also performs floating point operations. In yet other examples, the AL circuitry 2716 may include first AL circuitry that performs integer based operations and second AL circuitry that performs floating point operations. In some examples, the AL circuitry 2716 may be referred to as an Arithmetic Logic Unit (ALU). The registers 2718 are semiconductor-based structures to store data and/or instructions such as results of one or more of the operations performed by the AL circuitry 2716 of the corresponding core 2702. For example, the registers 2718 may include vector register(s), SIMD register(s), general purpose register(s), flag register(s), segment register(s), machine specific register(s), instruction pointer register(s), control register(s), debug register(s), memory management register(s), machine check register(s), etc. The registers 2718 may be arranged in a bank as shown in FIG. 27. Alternatively, the registers 2718 may be organized in any other arrangement, format, or structure including distributed throughout the core 2702 to shorten access time. The second bus 2722 may be implemented by at least one of an I2C bus, a SPI bus, a PCI bus, or a PCIe bus

Each core 2702 and/or, more generally, the microprocessor 2700 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 2700 is a semiconductor device fabricated to include many transistors interconnected to implement the structures described above in one or more integrated circuits (ICs) contained in one or more packages. The processor circuitry may include and/or cooperate with one or more accelerators. In some examples, accelerators are implemented by logic circuitry to perform certain tasks more quickly and/or efficiently than can be done by a general purpose processor. Examples of accelerators include ASICs and FPGAs such as those discussed herein. A GPU or other programmable device can also be an accelerator. Accelerators may be on-board the processor circuitry, in the same chip package as the processor circuitry and/or in one or more separate packages from the processor circuitry.

FIG. 28 is a block diagram of another example implementation of the processor circuitry 2612 of FIG. 26. In this example, the processor circuitry 2612 is implemented by FPGA circuitry 2800. For example, the FPGA circuitry 2800 may be implemented by an FPGA. The FPGA circuitry 2800 can be used, for example, to perform operations that could otherwise be performed by the example microprocessor 2700 of FIG. 27 executing corresponding machine readable instructions. However, once configured, the FPGA circuitry 2800 instantiates the machine readable instructions in hardware and, thus, can often execute the operations faster than they could be performed by a general purpose microprocessor executing the corresponding software.

More specifically, in contrast to the microprocessor 2700 of FIG. 27 described above (which is a general purpose device that may be programmed to execute some or all of the machine readable instructions represented by the flowchart of FIG. 25 but whose interconnections and logic circuitry are fixed once fabricated), the FPGA circuitry 2800 of the example of FIG. 28 includes interconnections and logic circuitry that may be configured and/or interconnected in different ways after fabrication to instantiate, for example, some or all of the machine readable instructions represented by the flowchart of FIG. 25. In particular, the FPGA circuitry 2800 may be thought of as an array of logic gates, interconnections, and switches. The switches can be programmed to change how the logic gates are interconnected by the interconnections, effectively forming one or more dedicated logic circuits (unless and until the FPGA circuitry 2800 is reprogrammed). The configured logic circuits enable the logic gates to cooperate in different ways to perform different operations on data received by input circuitry. Those operations may correspond to some or all of the software represented by the flowchart of FIG. 25. As such, the FPGA circuitry 2800 may be structured to effectively instantiate some or all of the machine readable instructions of the flowchart of FIG. 25 as dedicated logic circuits to perform the operations corresponding to those software instructions in a dedicated manner analogous to an ASIC. Therefore, the FPGA circuitry 2800 may perform the operations corresponding to the some or all of the machine readable instructions of FIG. 25 faster than the general purpose microprocessor can execute the same.

In the example of FIG. 28, the FPGA circuitry 2800 is structured to be programmed (and/or reprogrammed one or more times) by an end user by a hardware description language (HDL) such as Verilog. The FPGA circuitry 2800 of FIG. 28, includes example input/output (I/O) circuitry 2802 to obtain and/or output data to/from example configuration circuitry 2804 and/or external hardware 2806. For example, the configuration circuitry 2804 may be implemented by interface circuitry that may obtain machine readable instructions to configure the FPGA circuitry 2800, or portion(s) thereof. In some such examples, the configuration circuitry 2804 may obtain the machine readable instructions from a user, a machine (e.g., hardware circuitry (e.g., programmed or dedicated circuitry) that may implement an Artificial Intelligence/Machine Learning (AI/ML) model to generate the instructions), etc. In some examples, the external hardware 2806 may be implemented by external hardware circuitry. For example, the external hardware 2806 may be implemented by the microprocessor 2700 of FIG. 27. The FPGA circuitry 2800 also includes an array of example logic gate circuitry 2808, a plurality of example configurable interconnections 2810, and example storage circuitry 2812. The logic gate circuitry 2808 and the configurable interconnections 2810 are configurable to instantiate one or more operations that may correspond to at least some of the machine readable instructions of FIG. 25 and/or other desired operations. The logic gate circuitry 2808 shown in FIG. 28 is fabricated in groups or blocks. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 2808 to enable configuration of the electrical structures and/or the logic gates to form circuits to perform desired operations. The logic gate circuitry 2808 may include other electrical structures such as look-up tables (LUTs), registers (e.g., flip-flops or latches), multiplexers, etc.

The configurable interconnections 2810 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 2808 to program desired logic circuits.

The storage circuitry 2812 of the illustrated example is structured to store result(s) of the one or more of the operations performed by corresponding logic gates. The storage circuitry 2812 may be implemented by registers or the like. In the illustrated example, the storage circuitry 2812 is distributed amongst the logic gate circuitry 2808 to facilitate access and increase execution speed.

The example FPGA circuitry 2800 of FIG. 28 also includes example Dedicated Operations Circuitry 2814. In this example, the Dedicated Operations Circuitry 2814 includes special purpose circuitry 2816 that may be invoked to implement commonly used functions to avoid the need to program those functions in the field. Examples of such special purpose circuitry 2816 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 2800 may also include example general purpose programmable circuitry 2818 such as an example CPU 2820 and/or an example DSP 2822. Other general purpose programmable circuitry 2818 may additionally or alternatively be present such as a GPU, an XPU, etc., that can be programmed to perform other operations.

Although FIGS. 27 and 28 illustrate two example implementations of the processor circuitry 2612 of FIG. 26, many other approaches are contemplated. For example, as mentioned above, modern FPGA circuitry may include an on-board CPU, such as one or more of the example CPU 2820 of FIG. 28. Therefore, the processor circuitry 2612 of FIG. 26 may additionally be implemented by combining the example microprocessor 2700 of FIG. 27 and the example FPGA circuitry 2800 of FIG. 28. In some such hybrid examples, a first portion of the machine readable instructions represented by the flowchart of FIG. 25 may be executed by one or more of the cores 2702 of FIG. 27, a second portion of the machine readable instructions represented by the flowchart of FIG. 25 may be executed by the FPGA circuitry 2800 of FIG. 28, and/or a third portion of the machine readable instructions represented by the flowchart of FIG. 25 may be executed by an ASIC. It should be understood that some or all of the circuitry of FIG. 24 may, thus, be instantiated at the same or different times. Some or all of the circuitry may be instantiated, for example, in one or more threads executing concurrently and/or in series. Moreover, in some examples, some or all of the circuitry of FIG. 24 may be implemented within one or more virtual machines and/or containers executing on the microprocessor.

In some examples, the processor circuitry 2612 of FIG. 26 may be in one or more packages. For example, the microprocessor 2700 of FIG. 27 and/or the FPGA circuitry 2800 of FIG. 28 may be in one or more packages. In some examples, an XPU may be implemented by the processor circuitry 2612 of FIG. 26, which may be in one or more packages. For example, the XPU may include a CPU in one package, a DSP in another package, a GPU in yet another package, and an FPGA in still yet another package.

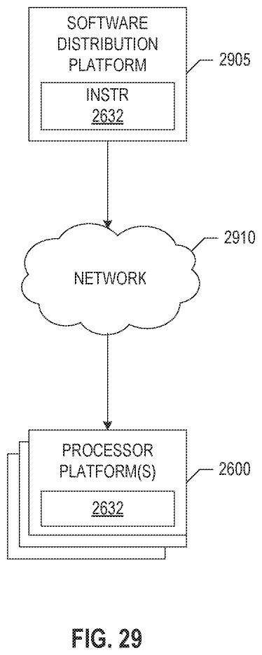

A block diagram illustrating an example software distribution platform 2905 to distribute software such as the example machine readable instructions 2632 of FIG. 26 to hardware devices owned and/or operated by third parties is illustrated in FIG. 29. The example software distribution platform 2905 may be implemented by any computer server, data facility, cloud service, etc., capable of storing and transmitting software to other computing devices. The third parties may be customers of the entity owning and/or operating the software distribution platform 2905. For example, the entity that owns and/or operates the software distribution platform 2905 may be a developer, a seller, and/or a licensor of software such as the example machine readable instructions 2632 of FIG. 26. The third parties may be consumers, users, retailers, OEMs, etc., who purchase and/or license the software for use and/or re-sale and/or sub-licensing. In the illustrated example, the software distribution platform 2905 includes one or more servers and one or more storage devices. The storage devices store the machine readable instructions 2632, which may correspond to the example machine readable instructions 2500 of FIG. 25, as described above. The one or more servers of the example software distribution platform 2905 are in communication with an example network 2910, which may correspond to any one or more of the Internet and/or any of the example networks 2626 described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 2632 from the software distribution platform 2905. For example, the software, which may correspond to the example machine readable instructions 2500 of FIG. 25, may be downloaded to the example processor platform 400, which is to execute the machine readable instructions 2632 to implement the fan control circuitry 1750. In some examples, one or more servers of the software distribution platform 2905 periodically offer, transmit, and/or force updates to the software (e.g., the example machine readable instructions 2632 of FIG. 26) to ensure improvements, patches, updates, etc., are distributed and applied to the software at the end user devices.

From the foregoing, it will be appreciated that example systems, methods, apparatus, and articles of manufacture have been disclosed that provide for field replaceable fan(s) to augment cooling at a peripheral (e.g., a peripheral processing unit such as a PCIe card) while enabling the fan(s) to be removed from the peripheral compute device (e.g., for maintenance) without disrupting or substantially interrupting operation of the device. Some example fan assemblies disclosed herein include fan(s) that can be moved relative to a heat sink (e.g., a heat sink on which the fan assembly is disposed). Example disclosed herein dynamically adjust the location(s) of (e.g., move) the fan(s) based on the identification of hot spots, or areas of increased temperature in the peripheral due to performance of the electronic components. Some examples disclosed herein dynamically adjust and/or monitor rotational parameters of the fan(s), such as fan speed, to optimize fan performance and, thus, performance of the electronic components through cooling.

Example field replaceable fan assemblies for peripheral processing units and related systems and methods are disclosed herein. Further examples and combinations thereof include the following:

Example 1 includes an apparatus comprising a temperature sensor; a heat sink; a fan having a base; at least one memory; machine readable instructions; and processor circuitry to execute operations corresponding to the machine readable instructions to determine a first temperature based on an output of the temperature sensor; and cause the base of the fan to move relative to the heat sink based on the first temperature

Example 2 includes the apparatus of example 1, further including a heat sink, the base of the fan moveable relative to the heat sink.

Example 3 includes the apparatus of examples 1 or 2, wherein the temperature sensor is in communication with the heat sink.

Example 4 includes the apparatus of any of examples 1-3, further including a tray to support the fan, the tray including a first frame; and a second frame, the second frame to carry the first frame, the first frame moveable relative to the second frame.

Example 5 includes the apparatus of any of examples 1-4, further including an actuator, the processor circuitry to cause the actuator to move the first frame.

Example 6 includes the apparatus of any of examples 1-5, wherein the first frame includes a first magnet and the second frame includes a second magnet, the second magnet to couple with the first magnet when the base of the fan is at a first location relative to the heat sink.

Example 7 includes the apparatus of any of examples 1-6, wherein the processor circuitry is to cause a polarity of the first magnet to be adjusted to cause the second frame to move.

Example 8 includes the apparatus of any of examples 1-7, wherein the fan is a first fan and further including a second fan, the second fan having a base that is moveable relative to the first fan.

Example 9 includes the apparatus of any of examples 1-8, wherein the processor circuitry is to cause blades of the first fan to rotate in a first direction and blades of a second fan to rotate in a second direction, the first direction opposite the second direction.

Example 10 includes the apparatus of any of examples 1-9, wherein the processor circuitry is to determine a rotational speed of the fan blades; and cause an alert to be output based on the rotational speed.

Example 11 includes an electronic peripheral comprising a housing; a heat sink to dissipate heat generated by the peripheral; a frame proximate the heat sink; and a fan supported by the frame, the housing to cover the heat sink and the frame, the frame from the housing via translation.

Example 12 includes the electronic peripheral of example 11, wherein the fan is translatable relative to the heat sink.

Example 13 includes the electronic peripheral of examples 11 or 12, further including a track supported by the frame, the fan to translate via the track.

Example 14 includes the electronic peripheral of any of examples 11-13, wherein the frame is a first frame and further including a second frame, the second frame to move relative to the first frame.

Example 15 includes the electronic peripheral of any of examples 11-14, further including a socket carried by the frame, the socket to couple to a power source to provide power to the fan.

Example 16 includes the electronic peripheral of any of examples 11-15, wherein the frame is a first frame, the fan is a first fan, and further including a second frame and a second fan, the second fan supported by the second frame.

Example 17 includes the electronic peripheral of any of examples 11-16, wherein the first fan is translatable relative to the first frame and the second fan is translatable relative to the second frame.

Example 18 includes the peripheral processing unit of any of examples 11-17, further including a first magnet and a second magnet, the second magnet carried by the frame, the first magnet to couple with the second magnet.

Example 19 includes a non-transitory machine readable storage medium comprising instructions to cause processor circuitry to at least detect a first temperature associated with a first portion of peripheral card; detect a second temperature associated with a second portion of the peripheral card; perform a comparison of the first temperature and the second temperature; and cause a fan to move from a first location to a second location of the peripheral card based on the comparison.

Example 20 includes the non-transitory machine readable storage medium of example 19, wherein the instructions cause the processor circuitry to cause a linear actuator to move the fan from the first location to the second location.

Example 21 includes the non-transitory machine readable storage medium of examples 19 or 20, wherein the instructions cause the processor circuitry to cause an electromagnet to activate to move the fan.

Example 22 includes the non-transitory machine readable storage medium of any of examples 19-21, wherein the instructions cause the processor circuitry to cause a rotational speed of blades of the fan to be adjusted based on the comparison.

Example 23 includes the non-transitory machine readable storage medium of any of examples 19-22, wherein the fan is a first fan, the peripheral card includes a second fan, and the instructions cause the processor circuitry to cause the blades the first fan to rotate in a first direction and blades of the second fan to rotate in a second direction, the first direction opposite the second direction.

Example 24 includes the non-transitory machine readable storage medium of any of examples 19-23, wherein the instructions cause the processor circuitry to compare a value representative of a rotational speed of blades of the fan to a threshold; and cause an alert to be output based on the comparison.

Example 25 includes the non-transitory machine readable storage medium of any of examples 19-24, wherein the instructions cause the processor circuitry to determine a temperature gradient for the peripheral card; and select a rotational directional for blades of the fan based on the temperature gradient.

Example 26 includes the apparatus of example 19, wherein the peripheral card is a peripheral component interconnect express (PCIe) card.

Example 27 includes an apparatus comprising means for detecting a temperature associated with a peripheral; means for circulating air; and means for controlling an actuator, the actuator controlling means to cause the air circulating means to translate based on the temperature.

Example 28 includes the apparatus of example 27, further including means for performance monitoring to detect a failure state of the air circulating means.

Example 29 includes the apparatus of examples 27 or 28, further including means for transporting, the actuator controlling means to cause the transporting means to move the air circulating means.

Example 30 includes the apparatus of any of examples 27-29, wherein the air circulating means is separately removable from the peripheral.

Example 31 includes an apparatus comprising interface circuitry to access temperature data for a peripheral; and processor circuitry including one or more of at least one of a central processor unit, a graphics processor unit, or a digital signal processor, the at least one of the central processor unit, the graphics processor unit, or the digital signal processor having control circuitry to control data movement within the processor circuitry, arithmetic and logic circuitry to perform one or more first operations corresponding to instructions, and one or more registers to store a result of the one or more first operations, the instructions in the apparatus; a Field Programmable Gate Array (FPGA), the FPGA including logic gate circuitry, a plurality of configurable interconnections, and storage circuitry, the logic gate circuitry and the plurality of the configurable interconnections to perform one or more second operations, the storage circuitry to store a result of the one or more second operations; or Application Specific Integrated Circuitry (ASIC) including logic gate circuitry to perform one or more third operations; the processor circuitry to perform at least one of the first operations, the second operations, or the third operations to instantiate temperature analysis circuitry to identify a hot spot at the peripheral; fan location determination circuitry to determine a location to which a fan of the peripheral should move relative to a heat sink to cool the hot spot; and actuator control circuitry to cause a base of the fan to move to the location.

Example 32 includes the apparatus of example 31, wherein the peripheral is a peripheral component interconnect express (PCIe) card.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

1. An apparatus comprising:
a temperature sensor;
a fan having a base;
at least one memory;
machine readable instructions; and
processor circuitry to execute operations corresponding to the machine readable instructions to:
determine a first temperature based on an output of the temperature sensor; and
cause the base of the fan to move based on the first temperature.

2. The apparatus of claim 1, further including a heat sink, the base of the fan moveable relative to the heat sink.

3. The apparatus of claim 2, wherein the temperature sensor is in communication with the heat sink.

4. The apparatus of claim 1, further including a tray to support the fan, the tray including:
a first frame; and
a second frame, the second frame to carry the first frame, the first frame moveable relative to the second frame.

5. The apparatus of claim 4, further including an actuator, the processor circuitry to cause the actuator to move the first frame.

6. The apparatus of claim 4, wherein the first frame includes a first magnet and the second frame includes a second magnet, the second magnet to couple with the first magnet when the base of the fan is at a first location relative to the heat sink.

7. The apparatus of claim 6, wherein the processor circuitry is to cause a polarity of the first magnet to be adjusted to cause the second frame to move.

8. The apparatus of claim 1, wherein the fan is a first fan and further including a second fan, the second fan having a base that is moveable relative to the first fan.

9. The apparatus of claim 1, wherein the processor circuitry is to cause blades of the first fan to rotate in a first direction and blades of a second fan to rotate in a second direction, the first direction opposite the second direction.

10. The apparatus of claim 1, wherein the processor circuitry is to:
determine a rotational speed of the fan blades; and
cause an alert to be output based on the rotational speed.

11. An electronic peripheral comprising:
a housing;
a heat sink to dissipate heat generated by the peripheral;
a frame proximate the heat sink; and
a fan supported by the frame, the housing to cover the heat sink and the frame, the frame from the housing via translation.

12. The electronic peripheral of claim 11, wherein the fan is translatable relative to the heat sink.

13. The electronic peripheral of claim 12, further including a track supported by the frame, the fan to translate via the track.

14. The electronic peripheral of claim 12, wherein the frame is a first frame and further including a second frame, the second frame to move relative to the first frame.

15. The electronic peripheral of claim 11, further including a socket carried by the frame, the socket to couple to a power source to provide power to the fan.

16. The electronic peripheral of claim 11, wherein the frame is a first frame, the fan is a first fan, and further including a second frame and a second fan, the second fan supported by the second frame.

17. The electronic peripheral of claim 16, wherein the first fan is translatable relative to the first frame and the second fan is translatable relative to the second frame.

18. The peripheral processing unit of claim 11, further including a first magnet and a second magnet, the second magnet carried by the frame, the first magnet to couple with the second magnet.

19. A non-transitory machine readable storage medium comprising instructions to cause processor circuitry to at least:
detect a first temperature associated with a first portion of peripheral card;
detect a second temperature associated with a second portion of the peripheral card;
perform a comparison of the first temperature and the second temperature; and
cause a fan to move from a first location to a second location of the peripheral card based on the comparison.

20. The non-transitory machine readable storage medium of claim 19, wherein the instructions cause the processor circuitry to cause a linear actuator to move the fan from the first location to the second location.

21. The non-transitory machine readable storage medium of claim 19, wherein the instructions cause the processor circuitry to cause an electromagnet to activate to move the fan.

22. The non-transitory machine readable storage medium of claim 19, wherein the instructions cause the processor circuitry to cause a rotational speed of blades of the fan to be adjusted based on the comparison.

23. The non-transitory machine readable storage medium of claim 19, wherein the fan is a first fan, the peripheral card includes a second fan, and the instructions cause the processor circuitry to cause the blades the first fan to rotate in a first direction and blades of the second fan to rotate in a second direction, the first direction opposite the second direction.

24. The non-transitory machine readable storage medium of claim 19, wherein the instructions cause the processor circuitry to:
compare a value representative of a rotational speed of blades of the fan to a threshold; and
cause an alert to be output based on the comparison.

25. The non-transitory machine readable storage medium of claim 19, wherein the instructions cause the processor circuitry to:
determine a temperature gradient for the peripheral card; and
select a rotational directional for blades of the fan based on the temperature gradient.

26. The apparatus of claim 19, wherein the peripheral card is a peripheral component interconnect express (PCIe) card.

27. An apparatus comprising:
means for detecting a temperature associated with a peripheral;
means for circulating air; and
means for controlling an actuator, the actuator controlling means to cause the air circulating means to translate based on the temperature.

28. The apparatus of claim 27, further including means for performance monitoring to detect a failure state of the air circulating means.

29. The apparatus of claim 28, further including means for transporting, the actuator controlling means to cause the transporting means to move the air circulating means.

30. The apparatus of claim 27, wherein the air circulating means is separately removable from the peripheral.

31. (canceled)

32. (canceled)
